(19) United States
(12) Patent Application Publication
(10) Pub. No.: US 2025/0374541 A1
(43) Pub. Date: Dec. 4, 2025

(54) NON-VOLATILE MEMORY CELL AND NON-VOLATILE SEMICONDUCTOR STORAGE DEVICE

(71) Applicant: FLOADIA CORPORATION, Tokyo (JP)

(72) Inventors: Yasuhiro TANIGUCHI, Tokyo (JP); Kosuke OKUYAMA, Tokyo (JP); Riichiro SHIROTA, Tokyo (JP)

(21) Appl. No.: 18/870,185

(22) PCT Filed: Dec. 28, 2022
(86) PCT No.: PCT/JP2022/048613

§ 371 Date: Nov. 27, 2024

(30) Foreign Application Priority Data
May 31, 2022 (JP) 2022-088177

(51) Int. Cl. H10B 43/20; H10B 43/10; H10B 43/35

(52) U.S. Cl. CPC H10B 43/20; H10B 43/10; H10B 43/35

(57) ABSTRACT

A non-volatile memory cell includes: a drain diffusion layer extending in a plane direction of a surface of a substrate; a source diffusion layer extending in the plane direction in parallel with the drain diffusion layer; a memory gate electrode having a pillar shape provided in a region between the drain diffusion layer and the source diffusion layer; a drain-side select gate electrode having a pillar shape provided in a region between the drain diffusion layer and the memory gate electrode; a source-side select gate electrode having a pillar shape provided in a region between the source diffusion layer and the memory gate electrode; and a multilayer insulating layer that is provided in contact with the memory gate electrode and that includes: a first memory gate insulating layer, a charge storage layer, and a second memory gate insulating layer.

### TECHNICAL FIELD

The present invention relates to a non-volatile memory cell and a non-volatile semiconductor memory device.

### BACKGROUND ART

Non-Patent Literature 1 discloses a semiconductor memory device in which a plurality of non-volatile memory cells sharing a circular pillar-shaped gate electrode and an annular multilayer insulating layer including a charge storage layer provided over one circumference along a circumferential direction on a side surface of the gate electrode are formed at predetermined intervals along an axial direction of the gate electrode. In Non-Patent Literature 1, non-volatile memory cells are three-dimensionally structured by providing polycrystalline silicon layers around a gate insulating layer at predetermined intervals along the axial direction of the gate electrode, and connecting source lines and bit lines running in parallel in a direction orthogonal to the axial direction of the gate electrode in the polycrystalline silicon layer at each level.

### CITATION LIST

### Non-Patent Literature

Non-Patent Literature 1: Yoohyun Noh et al., Synaptic Devices Based on 3-D AND Flash Memory Architecture for Neuromorphic Computing, in IEEE 11th International Memory Workshop (IMW) (2019)

### SUMMARY OF THE INVENTION

### Technical Problem

As described above, in recent years, it has been desired that the non-volatile memory cells are three-dimensionally structured and are integrated and downsized without being restricted by two-dimensional scaling.

The present invention has been made in view of the above points. An object of the present invention is to provide a non-volatile memory cell and a non-volatile semiconductor memory device that can be integrated and downsized.

### Solution to Problem

A non-volatile memory cell of the present invention including: a drain diffusion layer that extends in a plane direction of a surface of a substrate and to which a bit line is electrically connected; a source diffusion layer that extends in the plane direction in parallel with the drain diffusion layer and to which a source line is electrically connected; one or a plurality of memory gate electrodes each having a pillar shape that is disposed on the substrate with an insulating layer interposed therebetween and is provided in a region between the drain diffusion layer and the source diffusion layer running in parallel; a drain-side select gate electrode having a pillar shape, the drain-side select gate electrode being disposed on the substrate with an insulating layer interposed therebetween and provided in a region between the drain diffusion layer and the memory gate electrode; a source-side select gate electrode having a pillar shape, the source-side select gate electrode being disposed on substrate an the with insulating layer interposed therebetween and provided in a region between the source diffusion layer and the memory gate electrode; a multilayer insulating layer provided in contact with the memory gate electrode; a drain-side select gate insulating layer provided in contact with the drain-side select gate electrode; a source-side select gate insulating layer provided in contact with the source-side select gate electrode; and a semiconductor layer that is provided in a region between the drain diffusion layer and the source diffusion layer running in parallel, and is in contact with each of the drain-side select gate insulating layer, the source-side select gate insulating layer, the multilayer insulating layer, the drain diffusion layer, and the source diffusion layer, wherein the multilayer insulating layer includes: a first memory gate insulating layer in contact with the memory gate electrode, a charge storage layer in contact with the first memory gate insulating layer, and a second memory gate insulating layer in contact with the charge storage layer and the semiconductor layer.

In addition, a non-volatile semiconductor memory device oft present invention is a non-volatile semiconductor memory device in which a plurality of non-volatile memory cells arranged in a matrix in a plane direction of a surface of a substrate are hierarchically arranged along a vertical direction orthogonal to the plane direction, and the non-volatile memory cells are the above-described non-volatile memory cells.

### Advantageous Effects of the Invention

According to the present invention, since the non-volatile memory cells are three-dimensionally structured, it is possible to achieve integration and miniaturization without being restricted by two-dimensional scaling.

### BRIEF DESCRIPTION OF DRAWINGS

FIG. 1 is a circuit diagram that illustrates a configuration of an equivalent circuit of a non-volatile semiconductor memory device according to a first embodiment.

FIG. 2A is a circuit diagram that illustrates a configuration of an equivalent circuit of a non-volatile memory cell, and FIG. 2B is a schematic diagram that illustrates a cross-sectional configuration of the non-volatile memory cell in plan view.

FIG. 3 is a cross-sectional view of a cross-sectional configuration of a memory array in plan view.

FIG. 4 is a cross-sectional view that illustrates a cross-sectional configuration of an A-A′ portion in FIG. 3.

FIG. 5 is a cross-sectional view that illustrates a cross-sectional configuration of a B-B′ portion in FIG. 3.

FIG. 6 is a cross-sectional view of a cross-sectional configuration of a non-volatile memory cell according to another embodiment of the first embodiment.

FIG. 7A is a circuit diagram that illustrates voltages of parts of the non-volatile memory cell at a program operation, and FIG. 7B is a schematic diagram for explaining an operation of the non-volatile memory cell at the program operation.

FIG. 8A is a circuit diagram for explaining a memory array at a program operation, and FIG. 8B is a table that illustrates voltages of parts of the memory array at the program operation.

FIG. 9A is a circuit diagram that illustrates voltages of the parts of the non-volatile memory cell at an erase operation, and FIG. 9B is a schematic diagram for explaining an operation of the non-volatile memory cell at the erase operation.

FIG. 10A is a circuit diagram for explaining the memory array at an erase operation, and FIG. 10B is a table that illustrates voltages of the parts of the memory array at the erase operation.

FIG. 11A is a circuit diagram for explaining the memory array at a read operation, FIG. 11B is a table that illustrates voltages of the parts of the memory array at the read operation, and FIG. 11C is a table that illustrates other voltages of the parts at the read operation.

FIG. 12 is a schematic diagram that illustrates positions of cross-sectional used portions for describing manufacturing steps.

FIGS. 13A to 13C are schematic diagrams that illustrate a manufacturing step (1) of the memory array, FIG. 13A is a cross-sectional view of a cross-sectional configuration of an E-E′ portion in FIG. 12, FIG. 13B is a cross-sectional view of a cross-sectional configuration of an F-F′ portion in FIG. 12, and FIG. 13C is a cross-sectional view of a cross-sectional configuration of a G-G′ portion in FIG. 12.

FIGS. 14A to 14C are schematic diagrams that illustrate a manufacturing step (2) of the memory array, FIG. 14A is a cross-sectional view of a cross-sectional configuration of the E-E′ portion in FIG. 12, FIG. 14B is a cross-sectional view of a cross-sectional configuration of the F-F′ portion in FIG. 12, and FIG. 14C is a cross-sectional view of a cross-sectional configuration of the G-G′ portion in FIG. 12.

FIGS. 15A to 15C are schematic diagrams that illustrate a manufacturing step (3) of the memory array, FIG. 15A is a cross-sectional view of a cross-sectional configuration of the E-E′ portion in FIG. 12, FIG. 15B is a cross-sectional view of a cross-sectional configuration of the F-F′ portion in FIG. 12, and FIG. 15C is a cross-sectional view of a cross-sectional configuration of the G-G′ portion in FIG. 12.

FIGS. 16A to 16C are schematic diagrams that illustrate a manufacturing step (4) of the memory array, FIG. 16A is a cross-sectional view of a cross-sectional configuration of the E-E′ portion in FIG. 12, FIG. 16B is a cross-sectional view of a cross-sectional configuration of the F-F′ portion in FIG. 12, and FIG. 16C is a cross-sectional view of a cross-sectional configuration of the G-G′ portion in FIG. 12.

FIGS. 17A to 17C are schematic diagrams that illustrate a manufacturing step (5) of the memory array, FIG. 17A is a cross-sectional view of a cross-sectional configuration of the E-E′ portion in FIG. 12, FIG. 17B is a cross-sectional view of a cross-sectional configuration of the F-F′ portion in FIG. 12, and FIG. 17C is a cross-sectional view of a cross-sectional configuration of the G-G′ portion in FIG. 12.

FIGS. 18A to 18C are schematic diagrams that illustrate a manufacturing step (6) of the memory array, FIG. 18A is a cross-sectional view of a cross-sectional configuration of the E-E′ portion in FIG. 12, FIG. 18B is a cross-sectional view of a cross-sectional configuration of the F-F′ portion in FIG. 12, and FIG. 18C is a cross-sectional view of a cross-sectional configuration of the G-G′ portion in FIG. 12.

FIGS. 19A to 19C are schematic diagrams that illustrate a manufacturing step (7) of the memory array, FIG. 19A is a cross-sectional view of a cross-sectional configuration of the E-E′ portion in FIG. 12, FIG. 19B is a cross-sectional view of a cross-sectional configuration of the F-F′ portion in FIG. 12, and FIG. 19C is a cross-sectional view of a cross-sectional configuration of the G-G′ portion in FIG. 12.

FIGS. 20A to 20C are schematic diagrams that illustrate a manufacturing step (8) of the memory array, FIG. 20A is a cross-sectional view of a cross-sectional configuration of the E-E′ portion in FIG. 12, FIG. 20B is a cross-sectional view of a cross-sectional configuration of an H-H′ portion in FIG. 12, and FIG. 20C is a cross-sectional view of a cross-sectional configuration of the G-G′ portion in FIG. 12.

FIGS. 21A to 21C are schematic diagrams that illustrate a manufacturing step (9) of the memory array, FIG. 21A is a cross-sectional view of a cross-sectional configuration of the E-E′ portion in FIG. 12, FIG. 21B is a cross-sectional view of a cross-sectional configuration of the H-H′ portion in FIG. 12, and FIG. 21C is a cross-sectional view of a cross-sectional configuration of the G-G′ portion in FIG. 12.

FIGS. 22A to 22C are schematic diagrams that illustrate a manufacturing step (10) of the memory array, FIG. 22A is a cross-sectional view of a cross-sectional configuration of the E-E′ portion in FIG. 12, FIG. 22B is a cross-sectional view of a cross-sectional configuration of the H-H′ portion in FIG. 12, and FIG. 22C is a cross-sectional view of a cross-sectional configuration of the G-G′ portion in FIG. 12.

FIG. 23 is a circuit diagram that illustrates a configuration of an equivalent circuit of a non-volatile semiconductor memory device according to another embodiment of the first embodiment.

FIG. 24 is a circuit diagram that illustrates a configuration of an equivalent circuit of a memory array provided in a non-volatile semiconductor memory device according to a second embodiment.

FIG. 25A is a circuit diagram that illustrates a configuration of an equivalent circuit of a non-volatile memory cell, and FIG. 25B is a schematic view of a cross-sectional configuration of the non-volatile memory cell in plan view.

FIG. 26 is a cross-sectional view of a cross-sectional configuration of the memory array in plan view.

FIG. 27A is a cross-sectional view of a cross-sectional configuration of a J-J′ portion of FIG. 26, and FIG. 27B is a cross-sectional view of a cross-sectional configuration of a K-K′ portion of FIG. 26.

FIG. 28 is a cross-sectional view of a memory cell according to another embodiment of the second embodiment in plan view.

FIG. 29A is a circuit diagram for explaining a memory array at a program operation, and FIG. 29B is a table that illustrates voltages of parts of the memory array at the program operation.

FIG. 30A is a circuit diagram for explaining the memory array at an erase operation, FIG. 30B is a table that illustrates voltages of the parts of the memory array at the erase operation, and FIG. 30C is a table that illustrates other voltages of the parts at the erase operation.

FIG. 31A is a circuit diagram for explaining the memory array at a read operation, FIG. 31B is a table that illustrates voltages of the parts of the memory array at the read operation, and FIG. 31C is a table that illustrates other voltages of the parts at the read operation.

FIG. 32 is a circuit diagram that illustrates a configuration of an equivalent circuit of a memory array provided in a non-volatile semiconductor memory device according to a third embodiment.

FIG. 33A is a circuit diagram that illustrates a configuration of an equivalent circuit of a non-volatile memory cell, and FIG. 33B is a schematic diagram that illustrates a cross-sectional configuration of the non-volatile memory cell in plan view.

FIG. 34A is a circuit diagram for explaining a memory array at a program operation, and FIG. 34B is a table that illustrates voltages of parts of the memory array at the program operation.

FIG. 35A is a circuit diagram for explaining the memory array at an erase operation, FIG. 35B is a table that illustrates voltages of the parts of the memory array at the erase operation, and FIG. 35C is a table that illustrates other voltages of the parts at the erase operation.

FIG. 36A is a circuit diagram for explaining the memory array at a read operation, FIG. 36B is a table that illustrates voltages of the parts of the memory array at the read operation, and FIG. 36C is a table that illustrates other voltages of the parts at the read operation.

FIG. 37 is a schematic diagram that illustrates a manufacturing step (1) of the memory array.

FIGS. 38A and 38B are schematic diagrams that illustrate a manufacturing step (2) of the memory array, FIG. 38A is a schematic view of a configuration in plan view, and FIG. 38B is a cross-sectional view of a cross-sectional configuration of an M-M′ portion of FIG. 38A.

FIGS. 39A and 39B are schematic diagrams that illustrate a manufacturing step (3) of the memory array, FIG. 39A is a cross-sectional view of a cross-sectional configuration in a next step in the M-M′ portion of FIG. 38A, and FIG. 39B is a cross-sectional view of a cross-sectional configuration in a next step in the M-M′ portion of FIG. 38A.

FIGS. 40A and 40B are schematic diagrams that illustrate a manufacturing step (4) of the memory array, FIG. 40A is a cross-sectional view of a cross-sectional configuration in a next step in the M-M′ portion of FIG. 38A, and FIG. 40B is a cross-sectional view of a cross-sectional configuration in a next step in the M-M′ portion of FIG. 38A.

FIGS. 41A and 41B are schematic diagrams that illustrate a manufacturing step (5) of the memory array, FIG. 41A is a schematic view of a configuration in plan view, and FIG. 41B is a cross-sectional view of a cross-sectional configuration of the M-M′ portion of FIG. 41A.

FIGS. 42A to 42C are schematic diagrams that illustrate a manufacturing step (6) of the memory array, FIG. 42A is a schematic view of a configuration in plan view, FIG. 42B is a cross-sectional view of a cross-sectional configuration of an N-N′ portion of FIG. 42A, and FIG. 42C is a cross-sectional view of a cross-sectional configuration in a next step in the N-N′ portion of FIG. 42A.

FIGS. 43A and 43B are schematic diagrams that illustrate a manufacturing step (7) of the memory array, FIG. 43A is a schematic view of a configuration in plan view, and FIG. 43B is a cross-sectional view of a cross-sectional configuration of an O-O′ portion of FIG. 43A.

FIGS. 44A and 44B are schematic diagrams that illustrate a step (8) of manufacturing the memory array, FIG. 44A is illustrating a cross-sectional a cross-sectional view configuration in a next step in an O-O′ portion of FIG. 43A, and FIG. 44B is a cross-sectional view illustrating a cross-sectional configuration in a next step in an O-O′ portion of FIG. 43A.

FIG. 45 is a schematic diagram that illustrates a manufacturing step (9) of the memory array, which is a cross-sectional view of a cross-sectional configuration in a next step in the O-O′ portion of FIG. 43A.

FIG. 46 is a schematic diagram that illustrates a manufacturing step (10) of the memory array, which is a schematic view of a configuration in plan view.

FIG. 47 is a schematic diagram that illustrates a manufacturing step (11) of the memory array, which is a cross-sectional view of a cross-sectional configuration of the memory array.

FIG. 48 is a schematic diagram that illustrates a cross-sectional configuration of a non-volatile memory cell according to a fourth embodiment in plan view.

FIG. 49 is a schematic view of a cross-sectional configuration of a memory array according to the fourth embodiment in plan view.

FIG. 50 is a cross-sectional view of a cross-sectional configuration of a portion R-R′ in FIG. 49.

FIG. 51 is a schematic diagram that illustrates a manufacturing step (1) of the memory array according to the fourth embodiment.

FIGS. 52A and 52B are schematic diagrams that illustrate a manufacturing step (2) of the memory array according to the fourth embodiment, FIG. 52A is a schematic view of a configuration in plan view, and FIG. 52B is a cross-sectional view of a cross-sectional configuration of an S-S′ portion of FIG. 52A.

FIGS. 53A and 53B are schematic diagrams that illustrate a manufacturing step (3) of the memory array according to the fourth embodiment, FIG. 53A is a schematic view of a cross-sectional configuration in plan view, and FIG. 53B is a cross-sectional view of a cross-sectional configuration of the S-S′ portion of FIG. 53A.

FIGS. 54A and 54B are schematic diagrams that illustrate a manufacturing step (4) of the memory array according to the fourth embodiment, FIG. 54A is a schematic view of a cross-sectional configuration in plan view, and FIG. 54B is a cross-sectional view of a cross-sectional configuration of the S-S′ portion of FIG. 54A.

FIGS. 55A and 55B are schematic diagrams that illustrate a manufacturing step (5) of the memory array according to the fourth embodiment, FIG. 55A is a cross-sectional view of a cross-sectional configuration in a next step in the S-S′ portion of FIG. 54A, and FIG. 55B is a cross-sectional view of a cross-sectional configuration of the S-S′ portion in a next step of the step illustrated in FIG. 55A.

FIGS. 56A and 56B are schematic diagrams that illustrate a manufacturing step (6) of the memory array according to the fourth embodiment, FIG. 56A is a schematic view of a configuration in plan view at a height position of a T-T′ portion in FIG. 55B, and FIG. 56B is a cross-sectional view of a cross-sectional configuration of a U-U′ portion of FIG. 56A.

FIGS. 57A and 57B are schematic diagrams that illustrate a manufacturing step (7) of the memory array according to the fourth embodiment, FIG. 57A is a cross-sectional view of a cross-sectional configuration in a next step in the U-U′ portion of FIG. 56A, and FIG. 57B is a cross-sectional view of a cross-sectional configuration of the U-U′ portion in a next step of the step illustrated in FIG. 56A.

### DESCRIPTION OF EMBODIMENTS

Hereinafter, preferred embodiments of the present invention will be described in detail with reference to the accompanying drawings. In the present specification and the drawings, components having substantially the same functions are denoted by the same reference numerals, and redundant description thereof is omitted.

### (1) First Embodiment

### (1-1) Configuration of Equivalent Circuit of Non-Volatile Semiconductor Memory Device According to First Embodiment

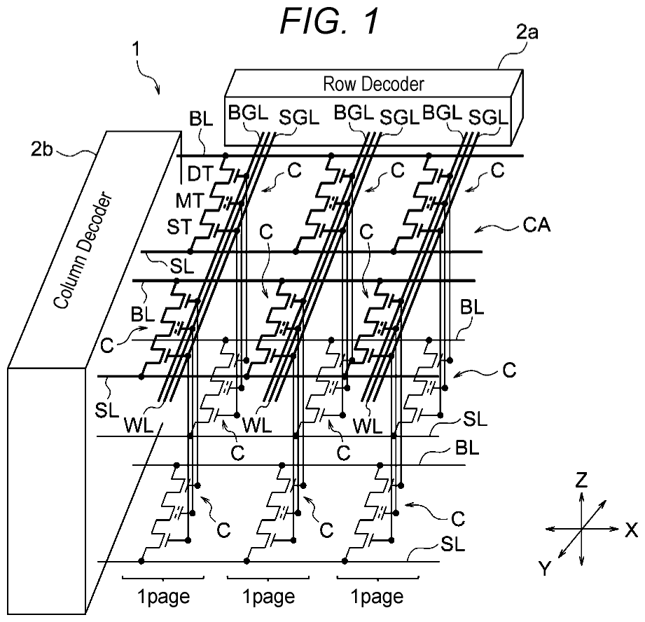

Referring to FIG. 1, a non-volatile semiconductor memory device 1 includes a row decoder 2a, a column decoder 2b, a memory array CA, a plurality of bit lines BL, a plurality of source lines SL, a plurality of drain-side select gate lines BGL, a plurality of source-side select gate lines SGL, and a plurality of word lines WL. In the present embodiment, an X direction in which the bit lines BL and the source lines SL extend will be referred to as column direction (hereinafter, also referred to as column direction X), a Y direction in which the drain-side select gate lines BGL, the source-side select gate line SGL, and the plurality of word lines WL orthogonal to these bit line BL and source line SL extend will be referred to as row direction (hereinafter, also referred to as row direction Y), and a Z direction orthogonal to a direction along a plane including both the X direction and the Y direction (hereinafter, referred to as plane direction) will be referred to as vertical direction (hereinafter, also referred to as vertical direction Z).

The memory array CA has a configuration in which a plurality of non-volatile memory cells (hereinafter, simply referred to as memory cells) C is arranged in a matrix in a plane direction, and the plurality of memory cells C arranged in a matrix in the plane direction is hierarchically arranged along the vertical direction Z orthogonal to the plane direction. FIG. 1 illustrates an example of the memory array CA in which the plurality of memory cells C is arranged in three rows and two columns in the plane direction, and the plurality of memory cells C arranged in three rows and two columns is provided at two levels of an upper layer and a lower layer.

The bit line BL extends in the column direction X at each level of the memory array CA, and is connected to the plurality of memory cells C arranged in the same column at each level. The source line SL runs in parallel with the bit lines BL and extends in the column direction X at each level of the memory array CA, and is connected to the memory cells C in the same column at each level. That is, one bit line BL and one source line SL are shared by the plurality of memory cells C arranged in the column direction X at each level.

The drain-side select gate line BGL, the source-side select gate line SGL, and the word line WL are provided in each row (page), and are connected to the plurality of memory cells C arranged in the same row (in the same page) including the different levels. That is, one drain-side select gate line BGL, one source-side select gate line SGL, and one word line WL are shared by the memory cells C in the page arranged in the row direction Y including the different levels.

In the memory array CA according to the present embodiment, the drain-side select gate lines BGL, the source-side select gate lines SGL, and the word lines WL do not extend in the row direction Y at the second level that is the lower layer, but extend in the row direction Y only at the first level that is the upper layer, and the drain-side select gate lines BGL, the source-side select gate lines SGL, and the word lines WL provided in the upper layer are electrically connected to each of the memory cells C arranged in the lower layer.

In the following description, in a case of distinguishing the individual memory cells C, assuming that i, j, and k are 1, 2, 3, . . . , respectively, the memory cells in the i-th row, the j-th column, and the k-th level will be described as memory cells Cᵢⱼₖ. In a case of distinguishing the bit lines BL and the source lines SL by a specific column and level, the bit line BL and the source line SL in the j-th column and the k-th level will be described as bit line BLⱼₖ and source line SLⱼₖ. In a case of distinguishing the drain-side select gate lines BGL, the source-side select gate lines SGL, and the word lines WL by a specific row, the drain-side select gate line BGL, the source-side select gate line SGL, and the word line WL in the i-th row will be described as drain-side select gate line BGLᵢ, source-side select gate line SGLᵢ, and word line WLᵢ. In this case, the memory cells Cᵢⱼₖ in the i-th row, the j-th column, and the k-th level are connected to the bit line BLⱼₖ, the source line SLⱼₖ, the drain-side select gate line BGLᵢ, the source-side select gate line SGLᵢ, and the word line WLᵢ, respectively. In a case of not distinguishing the levels, the notation of “k” indicating the k-th level will be omitted, and the foregoing cell and lines will be described as memory cell Cᵢⱼ, bit line BLⱼ, and source line SLⱼ.

In a case of distinguishing a memory cell C to be a target of data programming, erasing, and reading from a memory cell C not to be a target, the former will be referred to as “selected memory cell C”, and the latter will be referred to as “unselected memory cell C”.

In the memory array CA according to the present embodiment, the plurality of memory cells C arranged in a matrix at each level is identical in arrangement configuration. Thus, when: it is not necessary to distinguish by level, the following description will be mainly given focusing on the arrangement configuration of the plurality of memory cells C arranged at the first level that is the upper layer.

The memory cells C are identical in configuration, and each include a drain-side select transistor DT, a memory transistor MT, and a source-side select transistor ST. The drain-side select transistor DT, the memory transistor MT, and the source-side select transistor ST are connected in series. Details of the configuration of the memory cell C will be described later.

In this case, the bit lines BL are connected to the ends of the drain-side select transistors DT of the memory cells C in the corresponding columns, and the source lines SL are connected to the ends of the source-side select transistors ST of the memory cells C in the corresponding columns. The drain-side select gate line BGL is connected to the drain-side select transistors DT of the memory cells C in the corresponding row, the source-side select gate line SGL is connected to the source-side select transistor ST of the memory cells C in the corresponding row, and the word line WL is connected to the memory transistors MT of the memory cells C in the corresponding row.

The drain-side select gate lines BGL, the source-side select gate lines SGL, and the word lines WL are connected to the row decoder 2a, and the bit lines BL and the source lines SL are connected to the column decoder 2b. In each memory cells C, the voltages of the connected bit line BL, source line SL, drain-side select gate line BGL, source-side select gate line SGL, and word line WL are controlled by the row decoder 2a and the column decoder 2b, so that programming of data, erasing of data, and reading of data are performed on the memory transistor MT.

The configuration of the plurality of memory cells C arranged in one row direction Y (vertical plane direction (normal direction in the plane direction) extending in the row direction Y orthogonal to the plane direction) including the plurality of memory cells C arranged at different levels and different columns will be referred to as one page (“1 page” in FIG. 1). The example of the memory array CA illustrated in FIG. 1 has three pages since the memory cells C are arranged in three rows.

For convenience of description, when programming data, a page including memory cells C to which data is to be programed will be referred to as “program selected page”, and a page including only the memory cells C to which data is not to be programed will be referred to as “program unselected page”. When erasing data, a page including memory cells C from which data is to be erased will be referred to as “erase selected page”, and a page including only the memory cells C from which data is not to be erased will be referred to as an “erase unselected page”. When reading data, a page including the memory cells C from which data is to be read will be referred to as “read selected page”, and a page including only the memory cells C from which data is not to be read will be referred to as “read unselected page”.

Details of the data program operation, the erase operation, and the read operation in the non-volatile semiconductor memory device 1 will be described later. In this case, since drain-side select gate line BGL and source-side select gate line SGL are independently wired in each page, reading of data from the memory cells C and programming of data to the memory cell C can be selectively performed in each page. However, the erase of data from the memory cells C is performed in units of n pages.

### (1-2) Configuration of Memory Cell

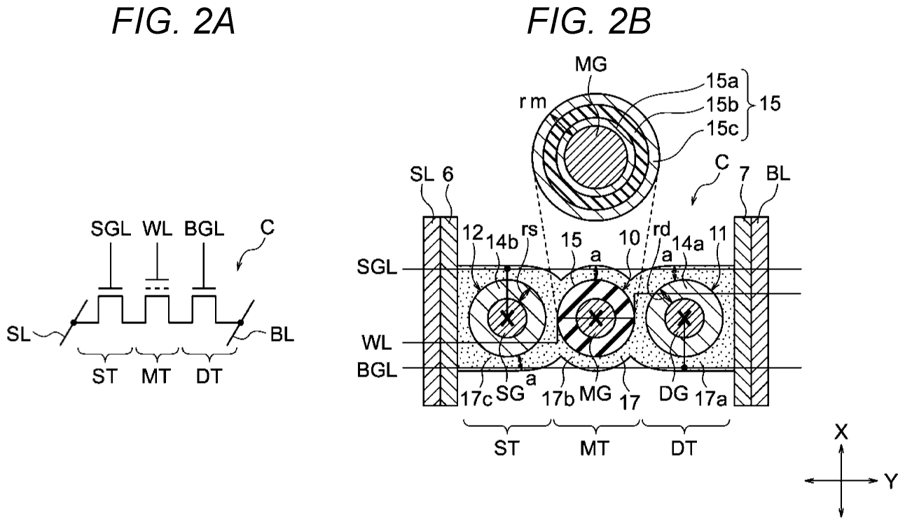

Next, the configuration of the memory cell C will be described. FIG. 2A is a circuit diagram illustrating a configuration of an equivalent circuit of the memory cell C. As illustrated in FIG. 2A, in the memory cell C, one end of the drain-side select transistor DT is connected to one end of the memory transistor MT having a charge storage layer to be described later, and one end of the source-side select transistor ST is connected to the other end of the memory transistor MT.

The bit line BL is connected to the other end of the drain-side select transistor DT, and the source line SL is connected to the other end of the source-side select transistor ST. The drain-side select gate line BGL is connected to the drain-side select gate electrode DG (described later with reference to FIG. 2B) of the drain-side select transistor DT, the source-side select gate line SGL is connected to the source-side select gate electrode SG of the source-side select transistor ST, and the word line WL is connected to the memory gate electrode MG of the memory transistor MT.

FIG. 2B illustrates an example of a cross-sectional configuration of the memory cell C illustrated in FIG. 2A in plan view. The memory cell C is formed in a region between the bit line BL and the source line SL extending in parallel in the column direction X. The memory cell C includes a drain diffusion layer 7 extending in the column direction X in contact with the bit line BL and a source diffusion layer 6 extending in the column direction X in contact with the source line SL. The source diffusion layer 6 and the drain diffusion layer 7 are n⁺-type diffusion layers made of polycrystalline silicon or the like and having a high impurity concentration, for example.

In the memory cell C, a semiconductor layer 17 made of polycrystalline silicon or the like is provided in a region between the drain diffusion layer 7 and the source diffusion layer 6 running in parallel. The semiconductor layer 17 is in contact with a side surface of the drain diffusion layer 7 and a side surface of the source diffusion layer 6. The semiconductor layer 17 provided between the drain diffusion layer 7 and the source diffusion layer 6 running in parallel includes a memory gate structure 10, a drain-side select gate structure 11, and a source-side select gate structure 12 so as to penetrate the semiconductor layer 17.

The memory gate structure 10, the drain-side select gate structure 11, and the source-side select gate structure 12 according to the present embodiment are each formed in a pillar shape with a circular cross section. The memory gate structure 10 is arranged between the drain-side select gate structure 11 and the source-side select gate structure 12, so that the memory gate structure 10, the drain-side select gate structure 11, and the source-side select gate structure 12 are linearly arranged.

In addition, here, the memory gate structure 10, the drain-side select gate structure 11, and the source-side select gate structure 12 are selected to have the same diameter in the circular cross section. The space between the memory gate structure 10 and the drain-side select gate structure 11 and the space between the memory gate structure 10 and the source-side select gate structure 12 are selected to be equal. However, the present invention is not limited to this. The memory gate structure 10, the drain-side select gate structure 11, and the source-side select gate structure 12 may be selected to have different diameters in the circular cross section, or the space between the memory gate structure 10 and the drain-side select gate structure 11 and the space between the memory gate structure 10 and the source-side select gate structure 12 may be selected to be different.

The memory gate structure 10 includes a circular pillar-shaped memory gate electrode MG and an annular multilayer insulating layer 15 provided over one circumference of the side surface of the memory gate electrode MG along the circumferential direction. The multilayer insulating layer 15 includes an annular first memory gate insulating layer 15a provided over one circumference of the side surface of the memory gate electrode MG along the circumferential direction, an annular charge storage layer 15b provided so as to be in contact with the outer periphery of the first memory gate insulating layer 15a, and an annular second memory gate insulating layer 15c provided so as to be in contact with the outer periphery of the charge storage layer 15b. The first memory gate insulating layer 15a and the second memory gate insulating layer 15c are formed of silicon oxide (SiO₂) or the like, and the charge storage layer 15b is formed of silicon nitride (Si₃N₄), silicon oxynitride (SiON), alumina (Al₂O₃), hafnium oxide (HfO₂), or the like.

In the memory gate structure 10 according to the present embodiment, the diameter of the memory gate electrode MG is preferably 20 to 70 nm at the uppermost portion from the viewpoint of a manufacturing process margin. In plan view, a distance rm from the inner surface (inner periphery) to the outer surface (outer periphery) of the multilayer insulating layer 15 in the plane direction (hereinafter, referred to as distance in the plane direction of the multilayer insulating layer 15) is preferably 12 to 22 nm from the viewpoint of reliability. In plan view, the distance from the inner surface to the outer surface of the first memory gate insulating layer 15a in the plane direction (hereinafter, referred to as distance in the plane direction of the first memory gate insulating layer 15a) is desirably 3 to 10 nm. In plan view, the distance from the inner surface to the outer surface of the charge storage layer 15b in the plane direction (hereinafter, referred to as distance in the plane direction of the charge storage layer 15b) is desirably 5 to 10 nm. In plan view, the distance from the inner surface to the outer surface of the second memory gate insulating layer 15c in the plane direction (hereinafter, referred to as distance in the plane direction of the second memory gate insulating layer 15c) is desirably 3 to 10 nm.

The drain-side select gate structure 11 includes a drain-side select gate electrode DG having a circular pillar shape, and an annular drain-side select gate insulating layer 14a provided over one circumference of the side surface of the drain-side select gate electrode DG along the circumferential direction. The source-side select gate structure 12 includes a source-side select gate electrode SG having a circular pillar shape, and an annular source-side select gate insulating layer 14b provided over one circumference of a side surface of the source-side select gate electrode SG along the circumferential direction.

In the memory cell C according to the present embodiment, the distance in the plane direction of the drain-side select gate insulating layer 14a and the distance in the plane direction of the source-side select gate insulating layer 14b are selected to have the same distance. However, the present invention is not limited to this, and the distance in the plane direction of the drain-side select gate insulating layer 14a and the distance in the plane direction of the source-side select gate insulating layer 14b may be selected to have different distances.

The drain-side select gate line BGL connected to the drain-side select gate electrode DG, the source-side select gate line SGL connected to the source-side select gate electrode SG, and the word line WL connected to the memory gate electrode MG are extended in the row direction Y orthogonal to the bit line BL, the source line SL, the drain diffusion layer 7, and the source diffusion layer 6, respectively.

In addition to this configuration, the semiconductor layer 17 according to the present embodiment is provided around the memory gate structure 10, the drain-side select gate structure 11, and the source-side select gate structure 12 along the outline shapes of these structures, and is formed so as to surround the memory gate structure 10, the drain-side select gate structure 11, and the source-side select gate structure 12.

In this example, in the semiconductor layer 17, a region surrounding the periphery of the memory gate structure 10 will be referred to as memory peripheral region 17b, a region surrounding the periphery of the drain-side select gate structure 11 will be referred to as drain-side peripheral region 17a, and a region surrounding the periphery of the source-side select gate structure 12 will be referred to as source-side peripheral region 17c. The memory peripheral region the drain-side 17b, peripheral region 17a, and the source-side peripheral region 17c are integrally formed.

The drain-side peripheral region 17a of the semiconductor layer 17 maintains a predetermined distance a along the side surface of the drain-side select gate structure 11 in the plane direction, and its both side surfaces linearly extend to the drain diffusion layer 7 to form the outer contour shape in an inverted D shape, and its end surface is linearly in contact with the side surface of the drain diffusion layer 7 along the side surface of the drain diffusion layer 7. Similarly, the source-side peripheral region 17c of the semiconductor layer 17 maintains a predetermined distance a along the side surface of the source-side select gate structure 12 in the plane direction, and its both side surfaces linearly extend to the source diffusion layer 6 to form the outer contour shape in a D shape, and its end surface is linearly in contact with the side surface of the drain diffusion layer 7 along the side surface of the drain diffusion layer 7.

Here, if each distance a in the plane direction of the drain-side peripheral region 17a, the memory peripheral region 17b, and the source-side peripheral region 17c is 40 nm or more, when a gate voltage is applied to each of the memory gate electrode MG, the drain-side select gate electrode DG, and the source-side select gate electrode SG, it is difficult to control the memory transistor MT, the drain-side select transistor DT, and the source-side select transistor ST, and there is a possibility that a leakage current occurs at a data reading operation. Therefore, the distance a is desirably less than 40 nm in order to more accurately control the memory transistor MT, the drain-side select transistor DT, and the source-side select transistor ST and to suppress the generation of the leakage current at the data read operation.

In the present embodiment, the distance between the memory gate structure 10 and the drain-side select gate structure 11 is a, the memory peripheral region 17b and the drain-side peripheral region 17a of the semiconductor layer 17 are formed to overlap with each other, the distance between the memory gate structure 10 and the source-side select gate structure 12 is also a, and the memory peripheral region 17b and the source-side peripheral region 17c of the semiconductor layer 17 are formed to overlap with each other.

In the present embodiment, the semiconductor layer 17 is provided between the drain-side select gate insulating layer 14a and the drain diffusion layer 7, and the semiconductor layer 17 is also provided between the source-side select gate insulating layer 14b and the source diffusion layer 6. However, the present invention is not limited thereto. The drain-side select gate insulating layer 14a and the drain diffusion layer 7 may be in contact with each other without providing the semiconductor layer 17 between the drain-side select gate insulating layer 14a and the drain diffusion layer 7, or the source-side select gate insulating layer 14b and the source diffusion layer 6 may be in contact with each other without providing the semiconductor layer 17 between the source-side select gate insulating layer 14b and the source diffusion layer 6.

### (1-3) Configuration of Memory Array

Next, a cross-sectional configuration of the memory array CA in which the above-described memory cells C are arranged in a matrix will be described. Referring to FIG. 1, in order to briefly describe the configuration of the equivalent circuit of the memory array CA, the description has been given focusing on the configuration of the equivalent circuit without focusing on the physical arrangement position of each unit. Hereinafter, the description will be given focusing on the physical arrangement position of each unit in the memory cell C actually manufactured.

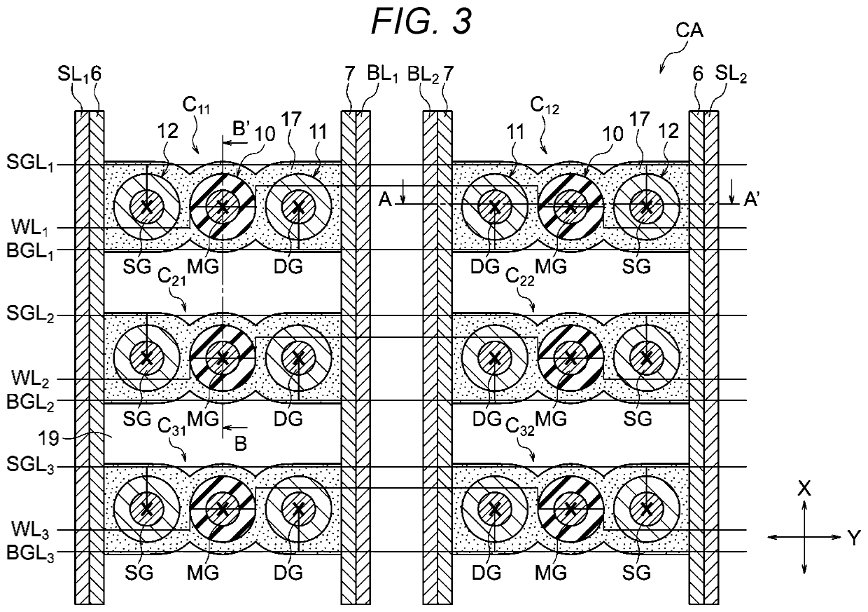

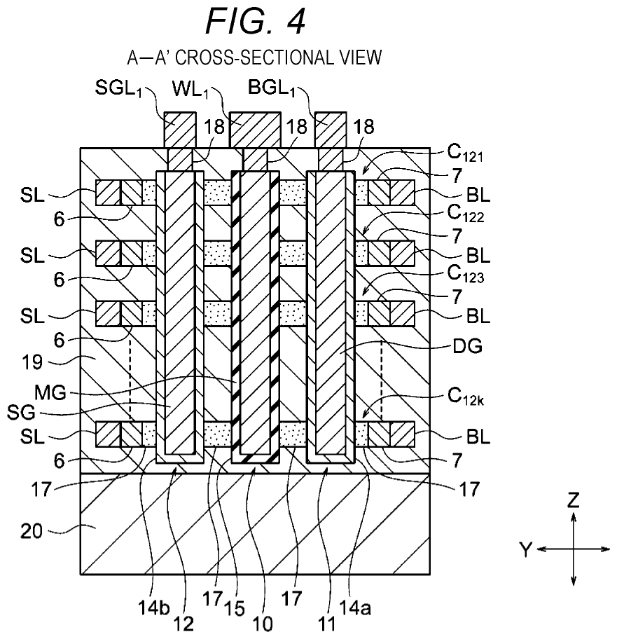

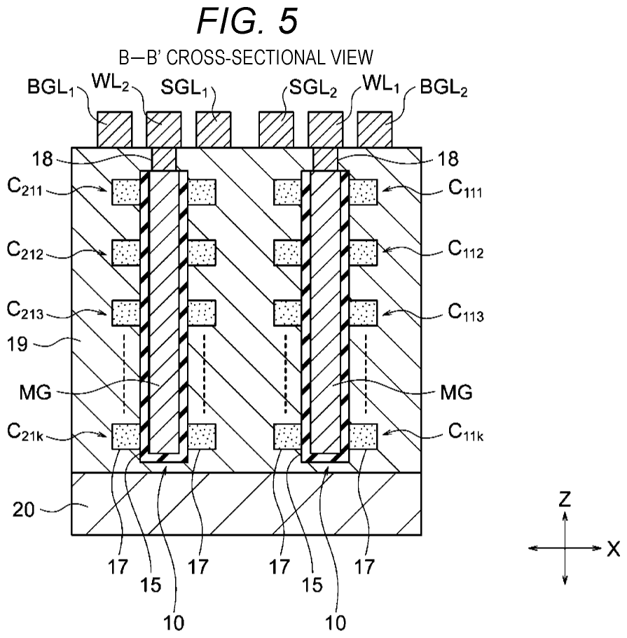

FIG. 3 is a cross-sectional view of a cross-sectional configuration of the memory array CA in plan view. FIG. 4 is a cross-sectional view that illustrates a cross-sectional configuration of an A-A′ portion in FIG. 3. FIG. 5 is a cross-sectional view that illustrates a cross-sectional configuration of a B-B portion′ in FIG. 3.

In FIG. 3, one direction indicates the column direction X in plan view, and the other direction orthogonal to the one direction indicates the row direction Y. For example, FIG. 3 illustrates a configuration in which the memory cells C are arranged in three rows and two columns at the first level. In FIG. 3, the memory cells C in the first row and first column, the second row and first column, and the third row and first column on the left side of the drawing will be referred to as memory cells C₁₁, C₂₁, and C₃₁, respectively, and the memory cells C in the first row and second column, the second row and second column, and the third row and second column on the right side of the drawing will be referred to as memory cells C₁₂, C₂₂, and C₃₂, respectively.

FIG. 1 is a circuit diagram focusing on a configuration of the equivalent circuit of the memory array CA, and FIG. 3 illustrates an example of arrangement of each unit of the memory array CA manufactured. In the memory array CA illustrated in FIG. 3, the memory cells C₁₁, C₂₁, and C₃₁ arranged in the first column and the memory cells C₁₂, C₂₂, and C₃₂ arranged in the second column are formed symmetrically, and a bit line BL₁ of the first column and a bit line BL₂ of the second column are arranged adjacent to each other.

Since the configuration in which the memory cells C₁₁, C₂₁, and C₃₁ in the first column are arranged and the configuration in which the memory cells C₁₂, C₂₂, and C₃₂ in the second column are arranged are the same except that they are formed to be bilaterally symmetrical, the description will be given mainly focusing on the memory cells in the first column. In this case, the bit line BL₁ and a source line SL₁ run and extend in parallel, the source diffusion layer 6 extends in contact with the side surface of the source line SL₁, and the drain diffusion layer 7 extends in contact with the side surface of the bit line BL₁.

The memory cells C₁₁, C₂₁, and C₃₁ are arranged along the column direction X in a region between the source diffusion layer 6 and the drain diffusion layer 7 running in parallel along the column direction X, and the side surfaces of the semiconductor layer 17 of the memory cells C₁₁, C₂₁, and C₃₁ are in contact with the side surfaces of the source diffusion layer 6 and the drain diffusion layer 7. Accordingly, the memory cells C₁₁, C₂₁, and C₃₁ in the same column share the source line SL₁, the bit line BL₁, the source diffusion layer 6, and the drain diffusion layer 7. An insulating layer 19 is provided between the memory cells C₁₁, C₂₁, and C₃₁ to insulate the memory cells C₁₁, C₂₁, and C₃₁ from each other.

A drain-side select gate line BGL₁ extending in the row direction Y is connected to the drain-side select gate electrodes DG of the memory cells C₁₁ and C₁₂ of the first column and the second column arranged in the same row. A source-side select gate line SGL₁ extending in the row direction Y is connected to the source-side select gate electrodes SG of the memory cells C₁₁ and C₁₂ of the first column and the second column arranged in the same row. A word line WL₁ extending in the row direction Y is connected to the memory gate electrodes MG of the memory cells C₁₁ and C₁₂ of the first column and the second column arranged in the same row.

Next, a cross-sectional configuration of an A-A′ portion in FIG. 3 illustrated in FIG. 4 will be described. FIG. 4 illustrates a longitudinal cross-sectional configuration in the vertical direction Z at positions where the memory gate structure 10, the drain-side select gate structure 11, and the source-side select gate structure 12 constituting the memory cells C are arranged.

In this case, the pillar-shaped memory gate structure 10, the pillar-shaped drain-side select gate structure 11, and the pillar-shaped source-side select gate structure 12 are disposed on a substrate 20 with the insulating layer 19 interposed therebetween. On the substrate 20, memory cells C₁₂₁, C₁₂₂, C₁₂₃, . . . and C₁₂ₖ of the first to k-th layers are formed at predetermined intervals in the vertical direction Z along the memory gate structure 10, the drain-side select gate structure 11, and the source-side select gate structure 12. In this manner, the memory gate structure 10, the drain-side select gate structure 11, and the source-side select gate structure 12 are shared among the plurality of memory cells C₁₂₁, C₁₂₂, C₁₂₃, . . . , and C₁₂ₖ arranged in the vertical direction Z.

In the memory gate structure 10, the pillar-shaped memory gate electrode MG is extended in the vertical direction Z to the surface of the substrate 20, and the multilayer insulating layer 15 is formed on the side surface and the bottom surface of the memory gate electrode MG. The word line WL₁ is connected to the upper end of the memory gate electrode MG with a contact 18 in between. As a result, the same voltage is uniformly applied to the memory gate electrodes MG of the plurality of memory cells C₁₂₁, C₁₂₂, C₁₂₃, . . . , and C₁₂ₖ arranged in the vertical direction Z.

In the drain-side select gate structure 11, the pillar-shaped drain-side select gate electrode DG is extended in the vertical direction Z with respect to the surface of the substrate 20, and the drain-side select gate insulating layer 14a is formed on the side surface and the bottom surface of the drain-side select gate electrode DG. The drain-side select gate line BGL₁ is connected to the upper end of the drain-side select gate electrode DG with a contact 18 in between. As a result, the same voltage is uniformly applied to the drain-side select gate electrodes DG of the plurality of memory cells C₁₂₁, C₁₂₂, C₁₂₃, . . . , and C₁₂ₖ arranged in the vertical direction Z.

In the source-side select gate structure 12, the pillar-shaped source-side select gate electrode SG extends in the vertical direction Z to the surface of the substrate 20, and the source-side select gate insulating layer 14b is formed on the side surface and the bottom surface of the source-side select gate electrode SG. The source-side select gate line SGL₁ is connected to the upper end of the source-side select gate electrode SG with a contact 18 in between. As a result, the same voltage is uniformly applied to the source-side select gate electrodes SG of the plurality of memory cells C₁₂₁, C₁₂₂, C₁₂₃, . . . , and C₁₂k arranged in the vertical direction Z.

In addition, on the substrate 20, a layer in which the source line SL, the source diffusion layer 6, the semiconductor layer 17, the drain diffusion layer 7, and the bit line BL are arranged and the insulating layer 19 are alternately arranged along the vertical direction Z, and the memory cells C₁₂₁, C₁₂₂, C₁₂₃, . . . , and C₁₂ₖ are formed in the layer in which the source line SL, the source diffusion layer 6, the semiconductor layer 17, the drain diffusion layer 7, and the bit line BL are arranged.

Next, a cross-sectional configuration of a B-B′ portion in FIG. 3 illustrated in FIG. 5 will be described. FIG. 5 illustrates a longitudinal cross-sectional configuration in the vertical direction Z at positions where the memory gate structure 10 shared among memory cells C₁₁₁, C₁₁₂, C₁₁₃, . . . , and C₁₁ₖ at the levels in the first row and the first column and the memory gate structure 10 shared among the memory cells C₂₁₁, C₂₁₂, C₂₁₃, . . . , and C₂₁ₖ at the corresponding levels in the second row and the first column are arranged.

In this case, the memory cells C₁₁₁, C₁₁₂, C₁₁₃, . . . , and C₁₁ₖ in the first row and the first column and the memory cells C₂₁₁, C₂₁₂, C₂₁₃, . . . , and C₂₁ₖ in the second row and the first column are insulated from each other by the insulating layer 19. The word line WL is connected to the upper end of the memory gate electrode MG shared among the memory cells C₁₁₁, C₁₁₂, C₁₁₃, . . . , and C₁₁ₖ at the corresponding levels in the first row and the first column. On the other hand, a word line WL₂ different from the word line WL₁ is connected to the upper end of the memory gate electrode MG shared among the memory cells C₂₁₁, C₂₁₂, C₂₁₃, . . . , and C₂₁ₖ at the corresponding levels in the second row and the first column. As a result, different voltages can be applied to the memory gate electrodes MG of the memory cells C₁₁₁, C₁₁₂, C₁₁₃, . . . , and C₁₁ₖ in the first row and the first column and the memory gate electrodes MG of the memory cells C₂₁₁, C₂₁₂, C₂₁₃, . . . , and C₂₁ₖ in the second row and the first column via the different word lines WL₁ and WL₂, respectively.

### (1-4) Configuration of Memory Cell According to Another Embodiment

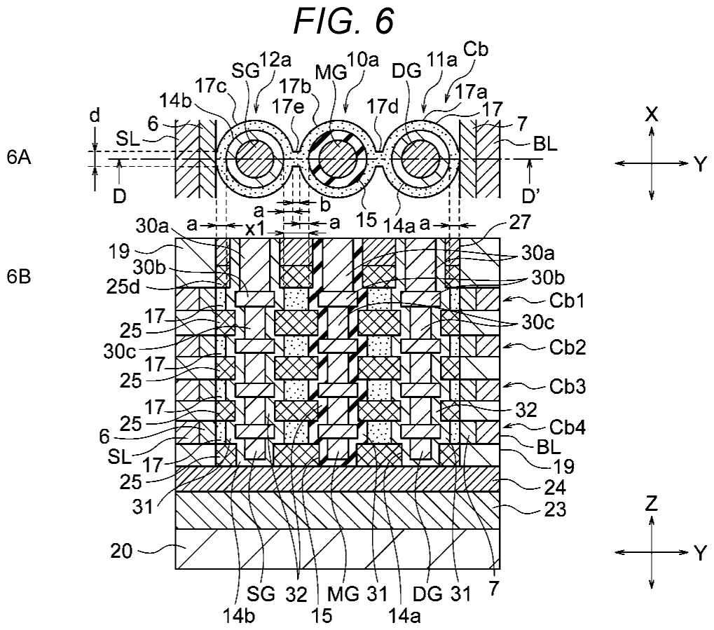

Next, a configuration of a memory cell according to another embodiment will be described. FIG. 6 illustrates a cross-sectional configuration of a memory cell Cb according to another embodiment. The memory cell Cb is different from the above-described memory cell C in the configuration of a memory gate structure 10a, a drain-side select gate structure 11a, and a source-side select gate structure 12a, and in the configuration in which a memory drain region connecting portion 17d and a memory source region connecting portion 17e are provided in a semiconductor layer 17.

In a case of distinguishing the individual memory cells Cb, assuming that k is 1, 2, 3, . . . , the memory cells at the k-th level will be described as memory cells Cbₖ. 6A of FIG. 6 illustrates an example of a cross-sectional configuration of the memory cell Cb in plan view, and 6B of FIG. 6 illustrates a longitudinal cross-sectional configuration in the vertical direction Z at a position where the memory gate structure 10a, the drain-side select gate structure 11a, and the source-side select gate structure 12a constituting the memory cell Cb are arranged.

As illustrated in 6A of FIG. 6, the memory cell Cb is formed in a region between the bit line BL and the source line SL extending in parallel in the column direction X. The memory cell C includes a drain diffusion layer 7 extending in the column direction X in contact with the bit line BL and a source diffusion layer 6 extending in the column direction X in contact with the source line SL. In the memory cell Cb, a semiconductor layer 17 made of polycrystalline silicon or the like is provided in a region between a drain diffusion layer 7 and a source diffusion layer 6 running in parallel. The side surfaces of semiconductor layer 17 are in contact with a side surface of the drain diffusion layer 7 and a side surface of the source diffusion layer 6. In the present embodiment, the side surfaces of semiconductor layer 17 are in contact with the side surface of the drain diffusion layer 7 and the side surface of the source diffusion layer 6 such that the contact width between the side surface of the source diffusion layer 6 and the side surface of the semiconductor layer 17 and the contact width between the side surface of the drain diffusion layer 7 and the side surface of the semiconductor layer 17 are set at a predetermined distance d in plan view.

The semiconductor layer 17 provided between the drain diffusion layer 7 and the source diffusion layer 6 running in parallel includes the memory gate structure 10a, the drain-side select gate structure 11a, and the source-side select gate structure 12a so as to penetrate the semiconductor layer 17. In the memory cell Cb, the semiconductor layer 17 is formed so as to surround the memory gate structure 10a, the drain-side select gate structure 11a, and the source-side select gate structure 12a. The semiconductor layer 17 includes a memory peripheral region 17b surrounding the periphery of the memory gate structure 10a, a drain-side peripheral region 17a surrounding the periphery of the drain-side select gate structure 11a, a source-side peripheral region 17c surrounding the periphery of the source-side select gate structure 12a, a memory drain region connecting portion 17d connecting the memory peripheral region 17b and the drain-side peripheral region 17a, and a memory source region connecting portion 17e connecting the memory peripheral region 17b and the source-side peripheral region 17c.

In this case, the memory peripheral region 17b is formed along the side surface of the memory gate structure 10a having a circular cross section in plan view, and is formed in an annular cross section in which the distance a from the side surface to the outer surface (outer periphery) of the memory gate structure 10a is selected to a predetermined distance. In addition, the drain-side peripheral region 17a is also formed along the side surface of the drain-side select gate structure 11a having a circular cross section in plan view, and is formed in an annular cross section in which the distance a from the side surface to the outer surface of the drain-side select gate structure 11a is selected to a predetermined distance. In addition, the source-side peripheral region 17c is also formed along the side surface of the source-side select gate structure 12a having a circular cross section in plan view, and is formed in an annular cross section in which the distance a from the side surface to the outer surface of the source-side select gate structure 12a is selected to a predetermined distance.

The memory drain region connecting portion 17d has a rectangular cross section in plan view, and a distance b from one end to the other end is selected to have a predetermined distance. One end of the memory drain region connecting portion 17d is connected to the outer periphery of the memory peripheral region 17b at the distance a from the side surface of the memory gate structure 10a, and the other end is connected to the outer periphery of the drain-side peripheral region 17a at the distance a from the side surface of the drain-side select gate structure 11a.

The memory source region connection portion 17e also has a rectangular cross section in plan view, and the distance b from one end to the other end is selected to have a predetermined distance. One end of the memory source region connecting portion 17e is connected to the outer periphery of the memory peripheral region 17b at the distance a from the side surface of the memory gate structure 10a, and the other end is connected to the outer periphery of the source-side peripheral region 17c at the distance a from the side surface of the source-side select gate structure 12a.

Here, if each distance a in the plane direction of the drain-side peripheral region 17a, the memory peripheral region 17b, and the source-side peripheral region 17c is 40 nm or more, when a gate voltage is applied to each of the memory gate electrode MG, the drain-side select gate electrode DG, and the source-side select gate electrode SG, it is difficult to control the memory transistor MT, the drain-side select transistor DT, and the source-side select transistor ST, and there is a possibility that a leakage current occurs at a data reading operation. Therefore, the distance a in the plane direction is desirably less than 40 nm in order to more accurately control the memory transistor MT, the drain-side select transistor DT, and the source-side select transistor ST and to suppress the generation of the leakage current at the data read operation.

In the memory cell Cb according to the present embodiment, the distance a of the memory peripheral region 17b, the distance a of the drain-side peripheral region 17a, and the distance a of the source-side peripheral region 17c are selected as the same distance a. However, the present invention is not limited to this, and all or any of the distance a of the memory peripheral region 17b, the distance a of the drain-side peripheral region 17a, and the distance a of the source-side peripheral region 17c may be selected as different distances.

In a case where the memory peripheral region 17b and the drain-side peripheral region 17a are directly connected without providing the memory drain region connecting portion 17d, in order to prevent the memory gate structure 10a and the drain-side select gate structure 11a from coming into contact with each other, when the memory gate structure 10a and the drain-side select gate structure 11a are formed to be separated from each other, if the memory peripheral region 17b and the drain-side peripheral region 17a formed around the memory gate structure 10a and the drain-side select gate structure 11a separated from each other are directly connected, the distances a in the plane direction of the memory peripheral region 17b and the drain-side peripheral region 17a also increase. Therefore, it may be difficult to reduce the distances a in the plane direction of the memory peripheral region 17b and the drain-side peripheral region 17a.

On the other hand, in the present embodiment, since the memory drain region connecting portion 17d that connects the memory peripheral region 17b and the drain-side peripheral region 17a is provided, even if the memory gate structure 10a and the drain-side select gate structure 11a are formed to be separated from each other, the memory peripheral region 17b and the drain-side peripheral region 17a can be reliably connected by the memory drain region connecting portion 17d while the distances a in the plane direction of the memory peripheral region 17b and the drain-side peripheral region 17a are reduced.

Similarly in the memory peripheral region 17b and the source-side peripheral region 17c, since the memory source region connecting portion 17e that connects the memory peripheral region 17b and the source-side peripheral region 17c is provided, even if the memory gate structure 10a and the source-side select gate structure 12a are formed to be separated from each other, the memory peripheral region 17b and the source-side peripheral region 17c can be reliably connected by the memory source region connecting portion 17e while reducing the distances a in the plane direction of the memory peripheral region 17b and the source-side peripheral region 17c.

As illustrated in 6B of FIG. 6, the memory gate structure 10a, the drain-side select gate structure 11a, and the source-side select gate structure 12a are formed in a pillar shape, and are disposed on the substrate 20 with an insulating layer 23 and an insulating layer 24 made of an insulating material of a type different from that of the insulating layer 23 sequentially interposed therebetween. For example, the substrate 20 is made of a member such as silicon, the insulating layer 23 is made of an insulating material such as a silicon oxide film or a silicon nitride film, and the insulating layer 24 is made of an insulating material such as Al₂O₃ or carbon or a semiconductor material such as silicon or SiC.

A circular pillar-shaped contact joint portion 30a to which a contact (not illustrated) is to be connected is provided at each of the upper ends of the memory gate electrode MG of the memory gate structure 10a, the drain-side select gate electrode DG of the drain-side select gate structure 11a, and the source-side select gate electrode SG of the source-side select gate structure 12a.

The memory gate electrode MG, the drain-side select gate electrode DG, and the source-side select gate electrode SG have an enlarged diameter portion 30b having a circular pillar shape and a reduced diameter portion 30c having a circular pillar shape smaller in diameter smaller than the enlarged diameter portion 30b, and have a configuration in which the enlarged diameter portion 30b and the reduced diameter portion 30c are alternately arranged along the axial direction below the contact joint portion 30a. The memory gate electrode MG, the drain-side select gate electrode DG, and the source-side select gate electrode SG are each formed in a pillar shape with the central axes of the contact joint portion 30a, the enlarged diameter portion 30b, and the reduced diameter portion 30c. In the present embodiment, the diameter of the contact joint portion 30a is formed to be larger than the diameter of the reduced diameter portion 30c and smaller than the diameter of the enlarged diameter portion 30b.

The contact joint portions 30a, the enlarged diameter portions 30b, and the reduced diameter portions 30c are formed at the same height positions of the memory gate electrode MG, the drain-side select gate electrode DG, and the source-side select gate electrode SG, respectively. That is, the enlarged diameter portions 30b of the drain-side select gate electrode DG and the source-side select gate electrode SG are arranged on the lateral sides of the enlarged diameter portion 30b of the memory gate electrode MG, and the reduced diameter portions 30c of the drain-side select gate electrode DG and the source-side select gate electrode SG are arranged on the lateral sides of the reduced diameter portion 30c of the memory gate electrode MG.

In the memory gate electrode MG, the multilayer insulating layer 15 is formed on the side surfaces of the contact joint portion 30a, the enlarged diameter portion 30b, and the reduced diameter portions 30c over the entire circumference along the circumferential direction, and the multilayer insulating layer 15 is also formed on the bottom surface. In this case, the multilayer insulating layer 15 has concave and convex portions formed on the side surfaces corresponding to the contact joint portion 30a, the enlarged diameter portion 30b, and the reduced diameter portion 30c of the memory gate electrode MG. A convex portion 31 is formed for the enlarged diameter portion 30b, and concave portions 32 are formed for the contact joint portion 30a and the reduced diameter portion 30c.

In the drain-side select gate electrode DG, the drain-side select gate insulating layer 14a is formed on the side surfaces of the contact joint portion 30a, the enlarged diameter portion 30b, and the reduced diameter portion 30c over the entire circumference along the circumferential direction, and the drain-side select gate insulating layer 14a is also formed on the bottom surface. Accordingly, the drain-side select gate insulating layer 14a has concave and convex portions formed on the side surfaces corresponding to the contact joint portion 30a, the enlarged diameter portion 30b, and the reduced diameter portion 30c of the drain-side select gate electrode DG. A convex portion 31 is formed for the enlarged diameter portion 30b, and concave portions 32 are formed for the contact joint portion 30a and the reduced diameter portion 30c.

In the source-side select gate electrode SG, the source-side select gate insulating layer 14b is formed on the side surfaces of the contact joint portion 30a, the enlarged diameter portion 30b, and the reduced diameter portion 30c over the entire circumference along the circumferential direction, and the source-side select gate insulating layer 14b is also formed on the bottom surface. Accordingly, the source-side select gate insulating layer 14b has concave and convex portions formed on the side surfaces corresponding to the contact joint portion 30a, the enlarged diameter portion 30b, and the reduced diameter portion 30c of the source-side select gate electrode SG. A convex portion 31 is formed for the enlarged diameter portion 30b, and concave portions 32 are formed for the contact joint portion 30a and the reduced diameter portion 30c.

On the insulating layer 24 provided on the substrate 20 with the insulating layer 23 in between, the bit line BL, the source line SL, the drain diffusion layer 7, and the source diffusion layer 6 extending in the column direction X are provided on a layer in which the enlarged diameter portions 30b of the memory gate structure 10a, the drain-side select gate structure 11a, and the source-side select gate structure 12a are formed. The layered semiconductor layer 17 is provided in a region between the source diffusion layer 6 and the enlarged diameter portion 30b of the source-side select gate structure 12a, a region between the enlarged diameter portion 30b of the source-side select gate structure 12a and the enlarged diameter portion 30b of the memory gate structure 10a, a region between the enlarged diameter portion 30b of the memory gate structure 10a and the enlarged diameter portion 30b of the drain-side select gate structure 11a, and a region between the enlarged diameter portion 30b of the drain-side select gate structure 11a and the drain diffusion layer 7.

The bit line BL is connected to the side surface of the semiconductor layer 17 provided on the side surface of the enlarged diameter portion 30b of the drain-side select gate structure 11a with the drain diffusion layer 7 interposed therein. The source line SL is connected to the side surface of the semiconductor layer 17 provided on the side surface of the enlarged diameter portion 30b of the source-side select gate structure 12a with the source diffusion layer 6 interposed therein.

On the other hand, the insulating layer 19 and the interlayer insulating layer 25 are formed in the layers of the memory gate structure 10a, the drain-side select gate structure 11a, and the source-side select gate structure 12a in which the reduced diameter portion 30c is formed. In this case, the interlayer insulating layer 25 is provided between the upper semiconductor layer 17 and the lower semiconductor layer 17, thereby to insulate the upper semiconductor layer 17 and the lower semiconductor layer 17 arranged in the vertical direction Z from each other. The insulating layer 19 is also provided between the upper bit line BL, source line SL, drain diffusion layer 7, and source diffusion layer 6 and the lower layer bit line BL, source line SL, drain diffusion layer 7, and source diffusion layer 6, thereby to insulate the upper and lower bit lines BL, the upper and lower source lines SL, the upper and lower drain diffusion layers 7, and the upper and lower source diffusion layers 6 arranged in the vertical direction Z from each other. A mask layer 27 is formed on an uppermost interlayer insulating layer 25d of the interlayer insulating layer 25, respectively.

As described above, the semiconductor layer 17, the bit line BL, the source line SL, the drain diffusion layer 7, and the source diffusion layer 6 are formed on a layer in which the enlarged diameter portions 30b of the memory gate electrode MG, the drain-side select gate electrode DG, and the source-side select gate electrode SG are arranged. The semiconductor layer 17 is formed so as to be in contact with the side surfaces of the convex portions 31 of the multilayer insulating layer 15, the drain-side select gate insulating layer 14a, and the source-side select gate insulating layer 14b formed on the side surfaces of the enlarged diameter portions 30b, the side surface of the drain diffusion layer 7, and the side surface of the source diffusion layer 6.

The memory cells Cb₁, Cb₂, Cb₃, and Cb₄ at different levels arranged along the vertical direction Z are formed at positions (layers) in the memory gate structure 10a, the drain-side select gate structure 11a, and the source-side select gate structure 12 where the semiconductor layers 17 are arranged, and can be insulated from each other by the interlayer insulating layer 25 between the upper and lower semiconductor layers 17 and the insulating layer 19 between the upper and lower bit lines BL, between the source lines SL, between the drain diffusion layers 7, and between the source diffusion layers 6.

A distance x1 in the plane direction of the semiconductor layer 17 formed between the multilayer insulating layer 15 and the drain-side select gate insulating layer 14a is a distance obtained by adding up the distance a in the plane direction of the memory peripheral region 17b, the distance a in the plane direction of the drain-side peripheral region 17a, and the distance b in the plane direction of the memory drain region connecting portion 17d. Similarly, a distance x1 in the plane direction of the semiconductor layer 17 formed between the multilayer insulating layer 15 and the source-side select gate insulating layer 14b is a distance obtained by adding up the distance a in the plane direction of the memory peripheral region 17b, the distance a in the plane direction of the source-side peripheral region 17c, and the distance b in the plane direction of the memory source region connecting portion 17e.

### (1-5) Data Program Operation

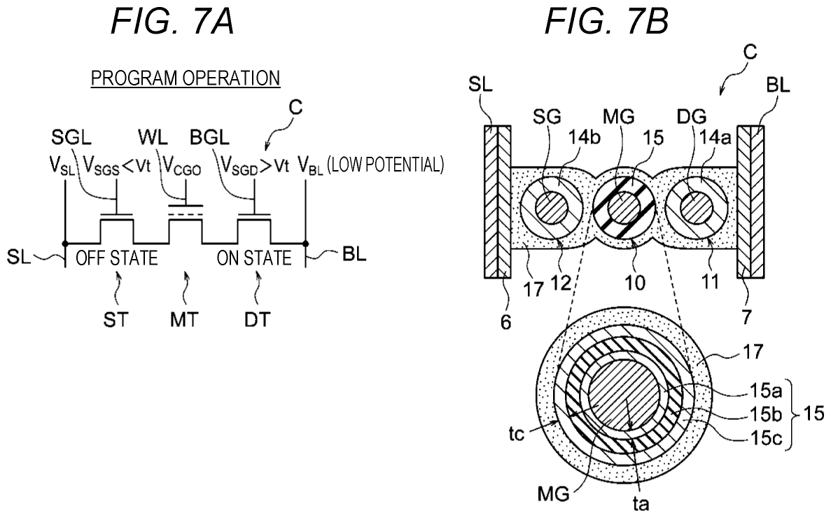

Next, a data program operation in the memory cell C illustrated in FIGS. 2A and 2B will be described. FIG. 7A is a circuit diagram illustrating a configuration of an equivalent circuit of the memory cell C. To program data to the memory cell C, for example, a source voltage V_{SL} of 1 V is applied to the source line SL, and a source-side gate voltage V_{SGS} smaller than a threshold voltage Vt of the source-side select transistor ST is applied to the source-side select gate electrode SG, thereby to turn off the source-side select transistor ST.

At this time, a program bit voltage V_{BL} of 0 V (hereinafter, also referred to as program selected bit voltage) is applied to the bit line BL, and a drain-side gate voltage V_{SGD} larger than the threshold voltage Vt of the drain-side select transistor DT is applied to the drain-side select gate electrode DG, thereby to turn on the drain-side select transistor DT.

Furthermore, for example, when a high voltage program memory gate voltage V_{CG0}) of 10 V (hereinafter, also referred to as program selection memory gate voltage) to the memory gate electrode MG, in the memory cell C, the semiconductor layer 17 in the vicinity of the outer periphery of the memory gate structure 10 has the same potential as the program selected bit voltage V_{BL0} as illustrated in FIG. 7B. As a result, in the memory cell C, electric charges move between the charge storage layer 15b included in the multilayer insulating layer 15 of the memory gate structure 10 and the semiconductor layer 17 and/or the memory gate electrode MG, so that data is programed.

In the multilayer insulating layer 15 including the charge storage layer 15b, when a distance ta in the plane direction of the first memory gate insulating layer 15a is longer than a distance tc in the plane direction of the second memory gate insulating layer 15c (that is, ta>tc), there occurs movement of electric charges between the semiconductor layer 17 and the charge storage layer 15b around the outer periphery of the second memory gate insulating layer 15c. On the other hand, when the distance ta in the plane direction of the first memory gate insulating layer 15a is shorter than the distance tc in the plane direction of the second memory gate insulating layer 15c (that is, ta<tc), there occurs movement of electric charges between the memory gate electrode MG and the charge storage layer 15b.

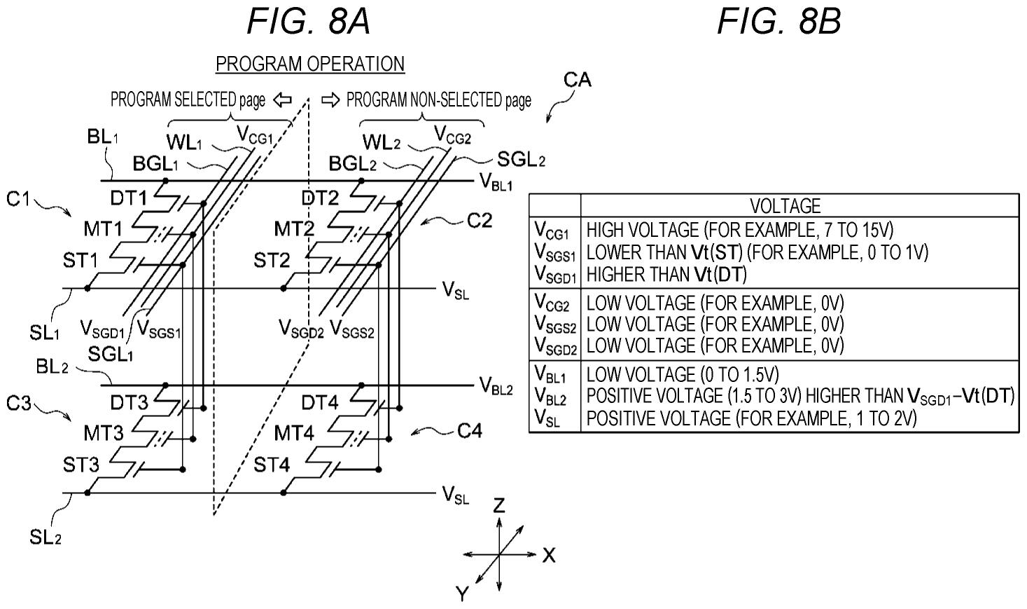

Next, as illustrated in FIG. 8A, the data program operation in the memory array CA will be described using, as an example, the memory array CA in which two memory cells C1 and C2 are arranged along the column direction X at the first level which is the first layer, two memory cells C3 and C4 are similarly arranged along the column direction X in the layer under the first level, one page is constituted by the memory cells C1 and C3 arranged in the vertical direction Z, and the other page is constituted by the memory cells C2 and C4 arranged in the vertical direction Z.

Here, a case where data is programed using the memory cell C1, among the memory cells C1, C2, C3, and C4, as the selected memory cell C1 will be described. In this case, the page including the selected memory cell C1 to which data is programed is set as a program selected page, and the page including only the unselected memory cells C2 and C4 to which data is not programed is set as a program unselected page.

In a case of not particularly distinguishing the memory transistors MT1, MT2, MT3, and MT4, the drain-side select transistors DT1, DT2, DT3, and DT4, and the source-side select transistors ST1, ST2, ST3, and ST4, they will be simply referred to as memory transistor MT, drain-side select transistor DT, and source-side select transistor ST.

FIG. 8B illustrates an example of voltages of components in the memory array CA in this case. In the memory array CA, a program selected bit voltage V_{BL1} (for example, a low voltage of 0 to 1.5 V) is applied to the bit line BL₁ to be the selected bit line connected to the selected memory cell C1. A program selected drain-side gate voltage V_{SGD1} higher than the threshold voltage Vt of the drain-side select transistor DT (preferably a positive voltage, also referred to as Vt(DT)) is applied to the drain-side select gate line BGL₁ connected to the selected memory cell C1. As a result, in the selected memory cell C1, the drain-side select transistor DT1 is turned on, and the program selected bit voltage V_{BL1} is transmitted to the memory transistor MT1.

In the memory array CA, a positive voltage (for example, 1 to 2 V) is uniformly applied to the source lines SL. A program selected gate voltage V_{SGS1} lower than the threshold voltage Vt of the source-side select transistor ST1 (preferably a positive voltage, also referred to as Vt(ST)) is applied to the source-side select gate line SGL₁ connected to the selected memory cell C1. As a result, in the selected memory cell C1, the source-side select transistor ST1 is turned off.

In addition, a program selected memory gate voltage V_{CG1} (for example, a high voltage of 10 V) is applied to the word line WL₁ connected to the selected memory cell C1. As a result, in the selected memory cell C1, the potential of the memory gate electrode MG becomes a high potential due to the program selected memory gate voltage V_{CG1} of the word line WL₁. For example, in a case of ta>tc, electrons are injected from the semiconductor layer 17 into the charge storage layer 15b, or holes are injected from the charge storage layer 15b into the semiconductor layer 17, so that data is programed. As a result, the threshold voltage of the memory transistor MT1 of the selected memory cell C1 increases. On the other hand, in a case of ta<tc, electrons escape from the charge storage layer 15b to the memory gate electrode MG, or holes are injected from the memory gate electrode MG to the charge storage layer 15b. As a result, the threshold voltage of the memory transistor MT1 of the selected memory cell C1 decreases. As described above, electric charges are transferred (injected) to the charge storage layer 15b due to the quantum tunnel effect, and data is programed.

At this time, a program unselected bit voltage V_{BL2} is applied to the other bit line BL₂ which is an unselected bit line not connected to the selected memory cell C1. The program unselected bit voltage V_{BL2} is preferably a positive voltage (for example, 1.5 to 3 V) and higher than (V_{SGD1}−Vt). V_{SGD1} is a program selected drain-side gate voltage applied to the drain-side select gate line BGL₁, and Vt here is a threshold voltage (desirably a positive value) of the drain-side select transistor DT, and is also referred to as Vt (DT).

As a result, in the unselected memory cell C3 in the program selected page in which data is not programed, the same voltage as that of the selected memory cell C1 is applied from the drain-side select gate line BGL₁ to the drain-side select gate electrode DG of the drain-side select transistor DT3, which is shared with the selected memory cell C1. However, the program unselected bit voltage V_{BL2} is applied to the bit line BL₂ to be the unselected bit line, so that the drain-side select transistor DT3 is turned off.

In the program selected page, the unselected memory cell C3 shares the drain-side select gate line BGL₁, the word line WL₁, and the source-side select gate line SGL₁ with the selected memory cell C1. However, the drain-side select transistor DT3 and the source-side select transistor ST3 of the unselected memory cell C3 are turned off. Accordingly, in the unselected memory cell C3, even when the program selection memory gate voltage V_{CG1} (for example, a high voltage of 7 to 10 V) is applied from the word line WL₁ to the memory gate electrode MG, the potential of the semiconductor layer 17 around the memory transistor MT3 increases, so that the potential difference from the program selection memory gate voltage V_{CG1} decreases. Therefore, in the unselected memory cell C3, the tunnel current does not flow into the charge storage layer 15b of the memory transistor MT3, so that it is possible to block injection of electric charges into the charge storage layer 15b and prevent data programming.

Although FIG. 8A does not illustrate the unselected memory cells (that is, the memory cell arranged on the back side or front side of plane of the drawing with respect to the memory cells C1 and C3) arranged in other columns in the program selected page, the unselected memory cells also share the drain-side select gate line BGL₁, the word line WL₁, and the source-side select gate line SGL₁ with the selected memory cell C1. However, similarly to the unselected memory cell C3, applying the same voltages as the bit line BL₂ and the source line SL₂ to the bit line BL and the source line SL, respectively, makes it possible to turn off the drain-side select transistor DT and the source-side select transistor ST, thereby to prevent data programming.

Next, a program unselected page including only the unselected memory cells C2 and C4 will be described. In this case, since the bit lines BL₁ and BL₂ and the source lines SL₁ and SL₂ connected to the unselected memory cells C2 and C4 are shared with the memory cells C1 and C3 in the program selected page, the description thereof is omitted here, and a drain-side select gate line BGL₂, the word line WL₂, and a source-side select gate line SGL₂ will be described.

In the program unselected page, a program unselected drain-side gate voltage V_{SGD2}, a program unselected memory gate voltage V_{CG2}, and a program unselected source-side gate voltage V_{SGS2}, which have a low potential (for example, 0 V), are applied to the drain-side select gate line BGL₂, the word line WL₂, and the source-side select gate line SGL₂, respectively. As a result, in the unselected memory cells C2 and C4 of the program unselected page, the drain-side select transistors DT2 and DT4 and the source-side select transistors ST2 and ST4 are turned off at both ends of the memory transistors MT2 and MT4, respectively, so that no tunnel current flows into the charge storage layer 15b of the memory transistors MT2 and MT4, injection of electric charges into the charge storage layer 15b can be blocked to prevent data programming. In the memory transistors MT of the unselected memory cells C2, C3, and C4, injection of electric charges into the charge storage layer 15b is blocked, and thus, the threshold voltage does not change.

In this manner, in the memory array CA, it is possible to prevent data programming to the unselected memory cells C2, C3, and C4 and to program data only to the selected memory cell C1.

### (1-6) Data Erase Operation

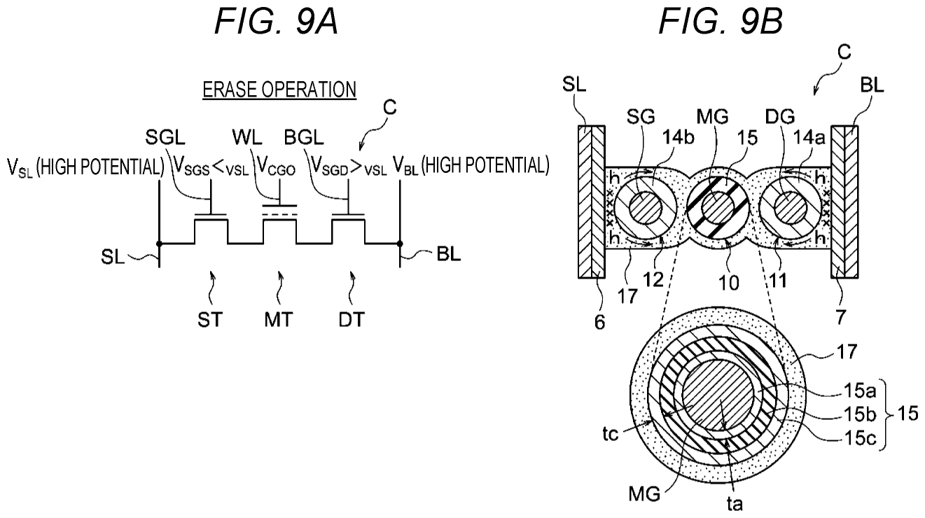

Next, a data erase operation in the memory cell C illustrated in FIGS. 2A and 2B will be described. FIG. 9A is a circuit diagram illustrating a configuration of an equivalent circuit of the memory cell C. In the case of erasing the data from the memory cell C, for example, a source voltage V_{SL}, which is a high voltage of 10 V, is applied to the source line SL, and an erase selected source-side gate voltage V_{SGS} (for example, 7 V) lower than the source voltage V_{SL} is applied to the source-side select gate line SGL connected to source-side select gate electrode SG of source-side select transistor ST.

Similarly, a bit voltage V_{BL}, which is a high voltage of 10 V, is applied to the bit line BL, and an erase selected drain-side gate voltage V_{SGD} (for example, 7 V) lower than the bit voltage V_{BL} is applied to the drain-side select gate line BGL connected to the drain-side select gate electrode DG of the drain-side select transistor DT.

Further, an erase selected memory gate voltage V_{CG0}, which is a voltage of a negative value to 0 V (for example, −5 to 0 V), is applied to the word line WL connected to the memory gate electrode MG of the memory transistor MT. At this time, the potential difference between the erase selected memory gate voltage V_{CG0} and the erase selected drain-side gate voltage V_{SGD} and the potential difference between the erase selected memory gate voltage V_{CG0} and the erase selected source-side gate voltage V_{SGS} are each desirably 9 V or more. For example, when the erase selected memory gate voltage V_{CG0} is 0 V, the erase selected drain-side gate voltage V_{SGD} and the erase selected source-side gate voltage V_{SGS} are desirably set to 9 V, and when the erase selected memory gate voltage V_{CG0} is-5 V, the erase selected drain-side gate voltage V_{SGD} and the erase selected source-side gate voltage V_{SGS} are desirably set to 4 V.

As illustrated in 9B, during the data erase operation, in the memory cell C, when a negative voltage is applied to the memory gate electrode MG, a potential difference between the gate and the drain generated in the drain-side select transistor DT and a potential difference between the gate and the source generated in the source-side select transistor ST cause a junction breakdown in the semiconductor layer 17 (regions indicated with “x” in the drawing) in the vicinity of the drain diffusion layer 7 and the source diffusion layer 6, whereby an electron-hole pair is generated (Junction current induced mode).

In the memory cell C, electrons generated in the semiconductor layer 17 flow to the source line SL and the bit line BL, and holes (indicated with “h” in the drawing) flow to the semiconductor layer 17 in the vicinity of the memory gate structure 10, so that the potential of the semiconductor layer 17 in the vicinity of the memory gate structure 10 increases. As a result, in the memory cell C, a potential difference is generated between the memory gate electrode MG and the semiconductor layer 17 around the memory gate electrode MG, the electric charges are extracted from the charge storage layer 15b, whereby the data is erased.

In the multilayer insulating layer 15 including the charge storage layer 15b, when the distance ta in the plane direction of the first memory gate insulating layer 15a is longer than the distance tc in the plane direction of the second memory gate insulating layer 15c (that is, ta>tc), electrons are extracted from the inside of the charge storage layer 15b toward the semiconductor layer 17 or holes are injected from the semiconductor layer 17 into the charge storage layer 15b during the data erase operation. As a result, the threshold of the memory transistor MT decreases. On the other hand, when the distance ta in the plane direction of the first memory gate insulating layer 15a is smaller than the distance tc in the plane direction of the second memory gate insulating layer 15c (That is, ta<tc), electrons are injected from the memory gate electrode MG into the charge storage layer 15b, or holes escape from the charge storage layer 15b to the memory gate electrode MG. As a result, the threshold of the memory transistor MT increases.

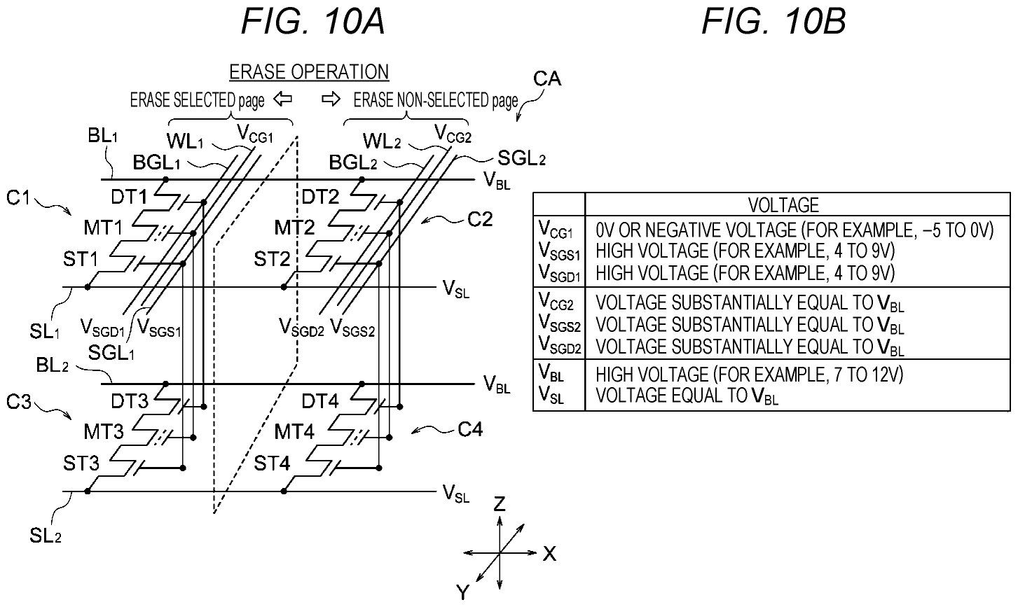

Next, as in “(1-5) Data Program Operation” described above, the data erase operation in the memory array CA will be described by exemplifying the memory array CA in which one page is constituted by the memory cells C1 and C3 arranged in the vertical direction Z and another one page is constituted by the memory cells C2 and C4 arranged in the vertical direction Z as illustrated in FIG. 10A.

Herein, a case where data is erased page by page, data is erased from the page constituted by the memory cells C1 and C3, and data is not erased from the page constituted by the memory cells C2 and C4 will be described. In this case, the page from which to erase data is designated as an erase selected page, and the page constituted by only the unselected memory cells C2 and C4 from which data is not to be erased is designated as a erase unselected page. The threshold voltages Vt of the drain-side select transistors DT and the source-side select transistors ST of the memory cells C1, C2, C3, and C4 are desirably positive values.

FIG. 10B illustrates an example of voltages of components in the memory array CA in this case. In the memory array CA, an erase bit voltage V_{BL} (for example, a high voltage of 7 to 12 V) is applied to the bit lines BL₁ and BL₂ shared between the erase selected page and the erase unselected page, and the source voltage V_{SL} having the same voltage as the erase bit voltage V_{BL} (for example, a high voltage of 7 to 12 V) is applied to the source lines SL₁ and SL₂.

In the erase selected page, for example, an erase selected drain-side gate voltage V_{SGD1}, which is a high voltage of 4 to 9 V, is applied to the drain-side select gate line BGL₁, and similarly, an erase selected source-side gate voltage V_{SGS1}, which is a high voltage of 4 to 9 V, is applied to the source-side select gate line SGL₁. In addition, in the erase selected page, an erase selection memory gate voltage V_{CG1}, which is a voltage of a negative value to 0 (for example, −5 to 0 V), is applied to the word line WL₁. As a result, in the erase selected page, in each of the memory cells C1 and C3, a potential difference is generated between the memory gate electrode MG and the semiconductor layer 17 around the memory gate electrode MG, charge is moved from the charge storage layer 15b, and data is erased.

On the other hand, in the erase unselected page, the same voltages (for example, high voltages of 7 to 12 V) as those of the bit lines BL₁ and BL₂ are applied to the drain-side select gate line BGL₂, the source-side select gate line SGL₂, and the word line WL₂ as an erase unselected drain-side gate voltage V_{SGD2}, an erase unselected source-side gate voltage V_{SGS2}, and an erase unselected memory gate voltage V_{CG2}, respectively. As a result, in the erase unselected page, in each of the memory cells C2 and C4, no potential difference occurs between the memory gate electrode MG and the semiconductor layer 17 around the memory gate electrode MG, electrical charges are not extracted from the charge storage layer 15b, and data can be prevented from being erased.

In the embodiment described above, data is erased page by page, but the present invention is not limited thereto. Alternatively, all the pages may be set as erase selected pages and data of all the memory cells C constituting the memory array CA may be collectively erased.

### (1-7) Data Read Operation

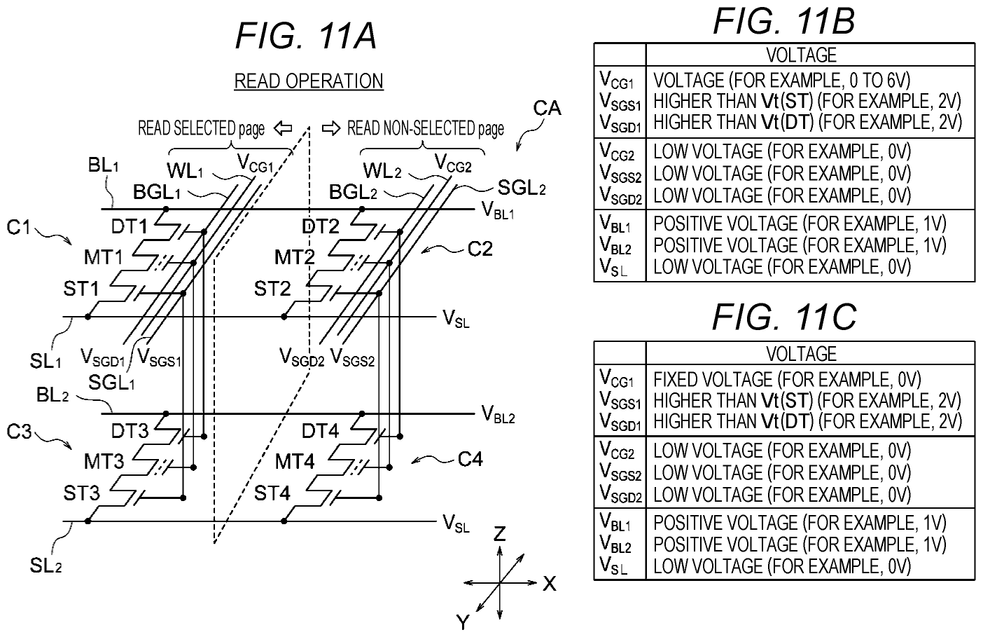

Next, a data read operation in the memory array CA will be described. Herein, as in “(1-5) Data Program Operation” described above, the data read operation in the memory array CA will be described by exemplifying the memory array CA in which one page is constituted by the memory cells C1 and C3 arranged in the vertical direction Z and another one page is constituted by the memory cells C2 and C4 arranged in the vertical direction Z as illustrated in FIG. 11A.

Herein, a case where data is read with the memory cells C1 and C3, among the memory cells C1, C2, C3, and C4, as the selected memory cells C1 and C3 will be described, for example. In this case, the page including the selected memory cells C1 and C3 from which to read data is set as a read selected page, and the page including only the unselected memory cells C2 and C4 from which data is not to be read is set as a read unselected page.

FIG. 11B illustrates an example of voltages of components in the memory array CA in this case. In the memory array CA, read bit voltages V_{BL1} and V_{BL2} (they are the same positive voltage, for example, 1 V) are applied to the bit lines BL₁ and BL₂ shared between the read selected page and the read unselected page, respectively, and a read source voltage Vs (the source lines SL have the same voltage, for example, 0 V) is applied to the source line SL.

In the read selected page, for example, a voltage (for example, 2 V) higher than the threshold voltage Vt of the drain-side select transistor DT1 is applied to the drain-side select gate line BGL₁ as read selected drain-side gate voltage V_{SGD1}, and similarly, a voltage (for example, 2 V) higher than the threshold voltage Vt of the source-side select transistor ST1 is applied to the source-side select gate line SGL₁ as the read selected source-side gate voltage V_{SGS1}. As a result, the drain-side select transistor DT1 and the source-side select transistor ST1 of the selected memory cell C1 are turned on.

Further, in the read selected page, for example, a read selected memory gate voltage V_{CG1} of 0 to 6 V is applied to the word line WL₁. Accordingly, in the selected memory cell C1, when the threshold voltage Vt of the memory transistor MT1 is lower than the read selected memory gate voltage V_{CG1}, a current flows from the source line SL₁ to the bit line BL₁, and the potential of the bit line BL₁ changes.

On the other hand, when the threshold voltage Vt of the memory transistor MT1 is higher than the read selected memory gate voltage V_{CG1}, no current flows from the source line SL₁ to the bit line BL₁, and the potential of the bit line BL₁ does not change. The data of the selected memory cell C1 can be read by detecting such a change in the potential of the bit line BL₁ by the column decoder 2b (FIG. 1). At this time, the data of the other selected memory cells C3 in the read selected page can be similarly read by detecting a change in the potential of the bit line BL₂ by the column decoder 2b (FIG. 1).

In the read unselected page, for example, a voltage (for example, 0 V) lower than the threshold voltage Vt of the drain-side select transistor DT2 is applied to the drain-side select gate line BGL₂ as read unselected drain-side gate voltage V_{SGD2}, and similarly, a voltage (for example, 0 V) lower than the threshold voltage Vt of the source-side select transistor ST is applied to the source-side select gate line SGL₂ as the read unselected source-side gate voltage V_{SGS2}.

As a result, the drain-side select transistors DT and the source-side select transistors ST of the unselected memory cells C2 and C4 of the read unselected page are turned off, and no current flows from the source lines SL₁ and SL₂ to the bit lines BL₁ and BL₂. As described above, data can be read only from the selected memory cells C1 and C3 of the read selected page.

When multi-value data is detected in one memory cell C, a fine threshold voltage of the memory transistor MT can be detected and multi-value data can be read by changing the value of the read selected memory gate voltage V_{CG1} in the read selected page and detecting a change in the potential of the bit line BL₁ at each voltage value.

FIG. 11C illustrates an example of voltages of individual parts in a data read operation according to another embodiment. In this case, in a read selected page, a read selected memory gate voltage V_{CG1} is applied to a word line WL₁ as a fixed voltage. At this time, if the threshold voltage of a memory transistor MT1 in a selected memory cell C1 is lower than the read selected memory gate voltage V_{CG1}, a current flows from a source line SL₁ to a bit line BL₁.

The cell current flowing from the source line SL₁ to the bit line BL₁ via the selected memory cell C1 is determined by the value of a threshold difference (V_{CG1}−Vt) between the read selected memory gate voltage V_{CG1} and the threshold voltage Vt of memory transistors MT1 and MT3. The magnitude of the cell current flowing from the source line SL₁ to the bit line BL₁ via the selected memory cell C1 is detected by the column decoder 2b, the threshold voltage Vt of the memory transistors MT1 and MT3 is determined in the column decoder 2b, and whether data is programed in the memory transistors MT1 and MT3 is determined.

Also in this case, the data programed in the memory transistors MT1 and MT3 can be classified and multi-valued data can be read according to the value of the cell current flowing from the source line SL₁ to the bit line BL₁ via the selected memory cell C1. A read unselected page is the same as that illustrated in FIG. 11B described above, and thus description thereof will be omitted here.

### (1-8) Specific Examples of Voltages in Data Program Operation, Erase Operation, and Read Operation

Table 1 below shows specific examples (voltage examples) of combinations of voltages at data program operation, erase operation, and read operation as described above. The unit of the voltage values shown in Table 1 is “V”.

In Table 1, “BL column” indicates a column of a memory cell C group electrically connected to the bit line BL extended from the column decoder 2b in the column direction X. As illustrated in FIG. 1, the column decoder 2b is two-dimensionally arranged in the row direction Y which is the depth direction of the plane and the vertical direction Z in the drawing, and there are two types of the BL columns in the row direction Y which is the depth direction in plane and the vertical direction Z. Therefore, strictly speaking, these can also be defined. However, in order to simplify the description, Table 1 does not particularly distinguish between the row direction Y which is the depth direction in the drawing and the vertical direction Z, and arranges operations focusing on the selected page and the unselected page indicated in FIGS. 8A, 10A, and 11A.

TABLE 1

| | | | Operation | | | | |
|---|---|---|---|---|---|---|---|
| | | | | | | | Erase |
| | | | Read | | Program | | Junction |
| | | | Selected | Unselected | Selected | Unselected | current |
| | | | BL column | BL column | BL column | BL column | induced |
| V_{CG} | Selected | V_{CG1} | 0 | 0 | 10 | 10 | −3 |
| | page | | | | | | |
| | Unselected | V_{CG2} | 0 | 0 | 0 | 0 | 10 |
| | page | | | | | | |
| V_{SGS} | Selected | V_{SGS1} | 1 | 1 | 0 | 0 | 7 |
| | page | | | | | | |
| | Unselected | V_{SGS2} | 0 | 0 | 0 | 0 | 10 |
| | page | | | | | | |
| V_{SGD} | Selected | V_{SGD1} | 1 | 1 | 1 | 1 | 7 |
| | page | | | | | | |
| | Unselected | V_{SGD2} | 0 | 0 | 0 | 0 | 10 |
| | page | | | | | | |
| V_{BL} | | | 1 | 0 | 0 | 1 | 10 |
| V_{SL} | | | 0 | 0 | 1 | 1 | 10 |

In the non-volatile semiconductor memory device 1, applying voltages as shown in Table 1 above makes it possible to adjust the voltages page by page in the memory array CA and to selectively program, erase, and read data to and from a predetermined memory cell C.

### (1-9) Method of Manufacturing Memory Array According to Another Embodiment

Next, a method of manufacturing the memory array CA including the memory cell Cb according to another embodiment illustrated in FIG. 6 will be described. As for a method of manufacturing the memory array CA illustrated in FIGS. 3, 4, and 5, a manufacturing method in a third embodiment to be described later can be used, and thus description thereof will be omitted here.

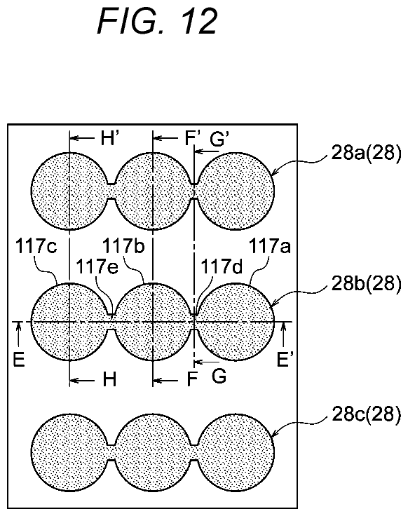

FIG. 12 is a schematic diagram illustrating positions of cross-sectional portions used for describing respective manufacturing steps, and reference numeral 28 denotes outlines of regions where a memory gate structure 10a, a drain-side select gate structure 11a, a source-side select gate structure 12a, and a semiconductor layer 17 of a memory cell Cb illustrated in FIG. 6 are formed in plan view (hereinafter, referred to as memory cell formation region).

FIG. 12 illustrates a mode in which three memory cell formation regions 28a, 28b, and 28c are arranged in parallel. Since the three memory cell formation regions 28a, 28b, and 28c have the same configuration, they are simply referred to as memory cell formation regions 28 when it is not particularly necessary to distinguish them.

In each of the memory cell formation regions 28, a region where the drain-side select gate structure 11a and the drain-side peripheral region 17a of the semiconductor layer 17 illustrated in FIG. 6 are formed constitutes a drain-side formation region 117a, a region where the memory gate structure 10a and the memory peripheral region 17b of the semiconductor layer 17 are formed constitutes a memory formation region 117b, and a region where the source-side select gate structure 12a and the source-side peripheral region 17c of the semiconductor layer 17 are formed constitutes a source-side formation region 117c.

In each of the memory cell formation region 28, a region where the memory drain region connecting portion 17d connecting the memory peripheral region 17b and the drain-side peripheral region 17a illustrated in FIG. 6 is formed constitutes a memory drain connecting formation region 117d, and a region where the memory source region connecting portion 17e connecting the memory peripheral region 17b and the source-side peripheral region 17c is formed constitutes a memory source connecting formation region 117e.

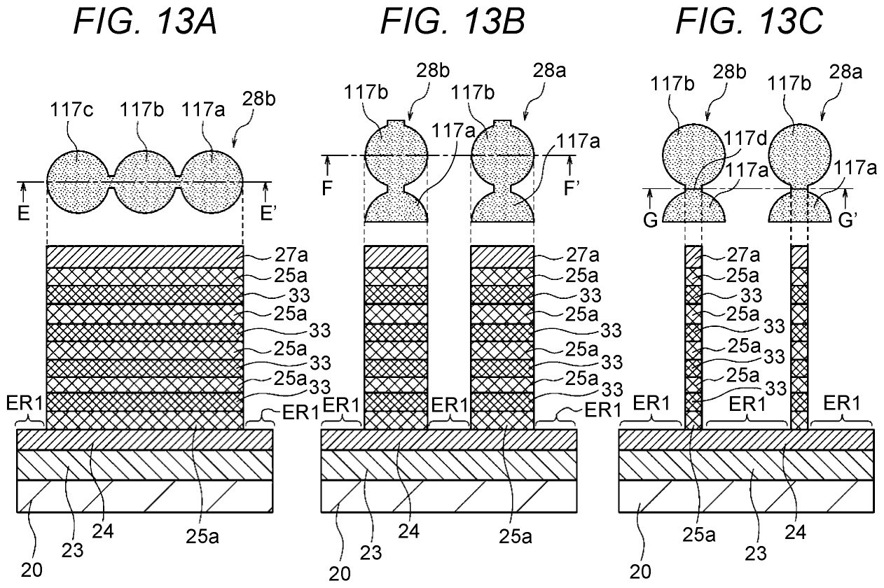

Next, a method of manufacturing the memory array CA will be described with reference to FIGS. 13A to 22C. In this case, as illustrated in FIGS. 13A, 13B, and 13C, for example, an insulating layer 23 and another insulating layer 24 different in type from the insulating layer 23 are stacked on a substrate 20 made of silicon, and a layered interlayer insulating layer 25a made of, for example, a silicon oxide film and a layered another interlayer insulating layer 33 made of, for example, a silicon nitride film are alternately stacked on the insulating layer 24. In addition, a mask layer 27a for a mask made of Al₂O₃, carbon, SiC, or the like having the same outline shape of the memory cell formation region 28b is formed on the interlayer insulating layer 25a located at the uppermost layer, and the interlayer insulating layers 25a and 33 are etched using the mask layer 27a as a mask.

As a result, the interlayer insulating layers 25a and 33 having the same outline shape as the outline shape of the memory cell formation regions 28a, 28b, and 28c are formed. The insulating layer 24 is exposed in a region ER1 where the interlayer insulating layers 25a and 33 are etched. Since the memory cell formation regions 28a, 28b, and 28c are manufactured in the same manner, the description will be given hereinafter focusing on each cross-sectional portion of the memory cell formation regions 28a and 28b illustrated in FIG. 12.

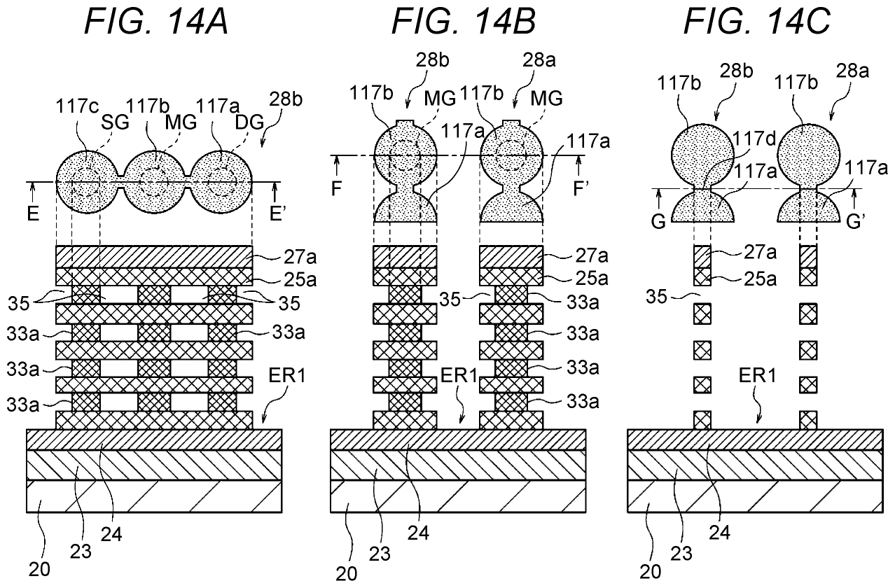

Next, out of the alternately stacked interlayer insulating layers 25a and 33, the interlayer insulating layers 33 sandwiched between the interlayer insulating layers 25a are selectively subjected to side etching from the plane direction of the surface of the substrate 20 by dry etching such as reactive ion etching, so that as illustrated in FIGS. 14A, 14B, and 14C, there are formed gaps 35 from which the interlayer insulating layers 33 are removed and pillar-shaped interlayer insulating layers 33a in which the interlayer insulating layers 33 remain in a circular pillar shape.

The pillar-shaped interlayer insulating layers 33a are formed at predetermined positions where the drain-side select gate electrode DG, the memory gate electrode MG, and the source-side select gate electrode SG are to be formed in the memory cell formation region 28b. The pillar-shaped interlayer insulating layers 33a are formed so as to have a diameter substantially equal to the diameters of the drain-side select gate electrode DG, the memory gate electrode MG, and the source-side select gate electrode SG to be formed.

As a result, in the memory cell formation region 28, the pillar-shaped interlayer insulating layers 33a are formed only at the predetermined positions where the drain-side select gate electrode DG, the memory gate electrode MG, and the source-side select gate electrode SG are to be formed, and the gaps 35 are formed around the pillar-shaped interlayer insulating layers 33a. Therefore, as illustrated in FIG. 14C, the gaps 35 are formed in the memory drain connecting formation regions 117d.

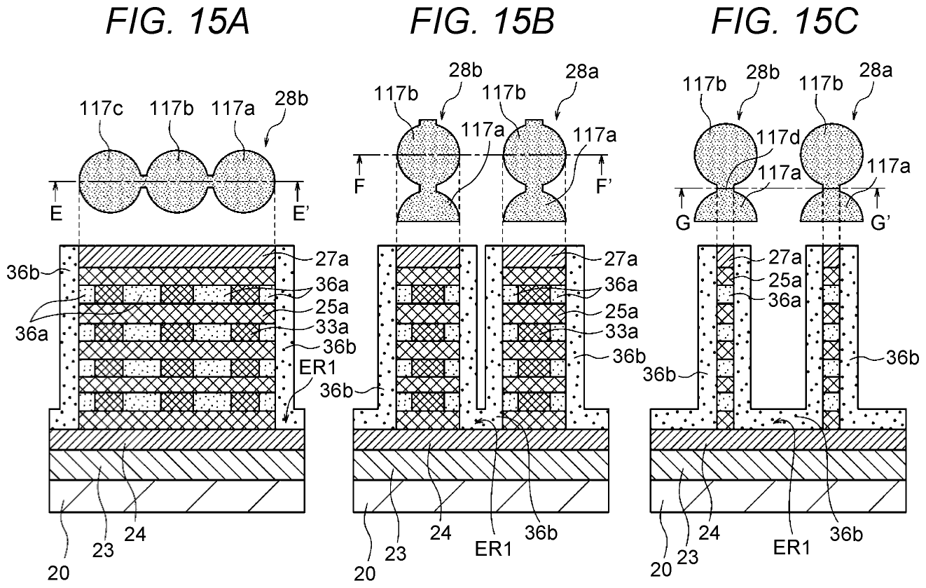

Next, as illustrated in FIGS. 15A, 15B, and 15C, for example, a semiconductor material such as polycrystalline silicon is deposited, and the gaps 35 between the stacked interlayer insulating layers 25a are filled with the semiconductor material to form semiconductor layers 36a in the gap 35. At this time, the semiconductor material is also deposited on the exposed insulating layer 24 in regions other than the memory cell formation region 28b, on the side surfaces of the memory cell formation region 28b, and on the mask layer 27a to form the semiconductor layers 36b. Thereafter, surface polishing is performed to remove the semiconductor material deposited on the mask layer 27a to expose the mask layer 27a.

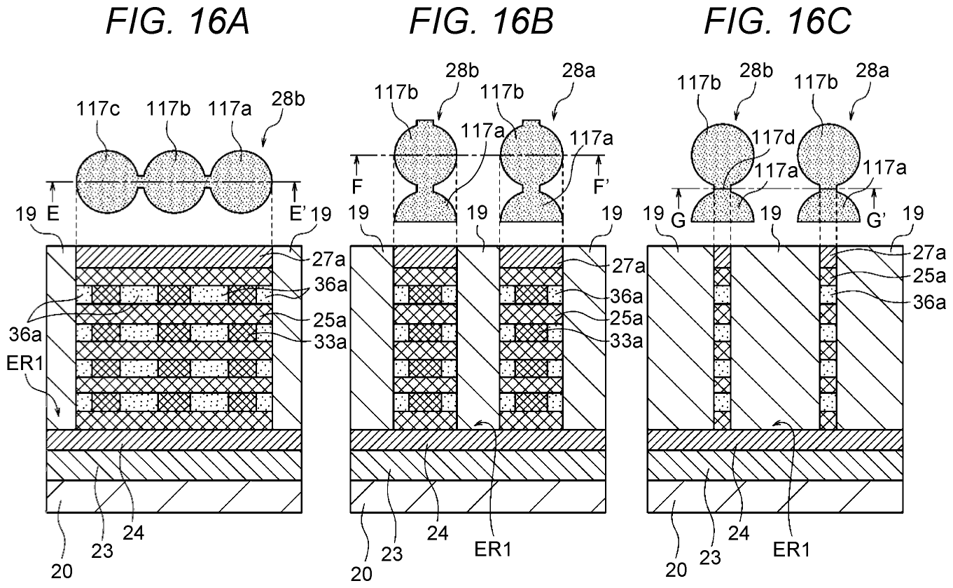

Next, using the mask layer 27a as a mask, the semiconductor layers 36b in regions not covered with the mask layer 27a are removed. Then, as illustrated in FIGS. 16A, 16B, and 16C, in the region ER1 where the insulating layer 24 is exposed, an insulating material such as a silicon oxide film is deposited in the region ER1 to form the insulating layer 19, and then surface polishing is performed to remove the interlayer insulating layer formed on the mask layer 27a to expose the mask layer 27a.

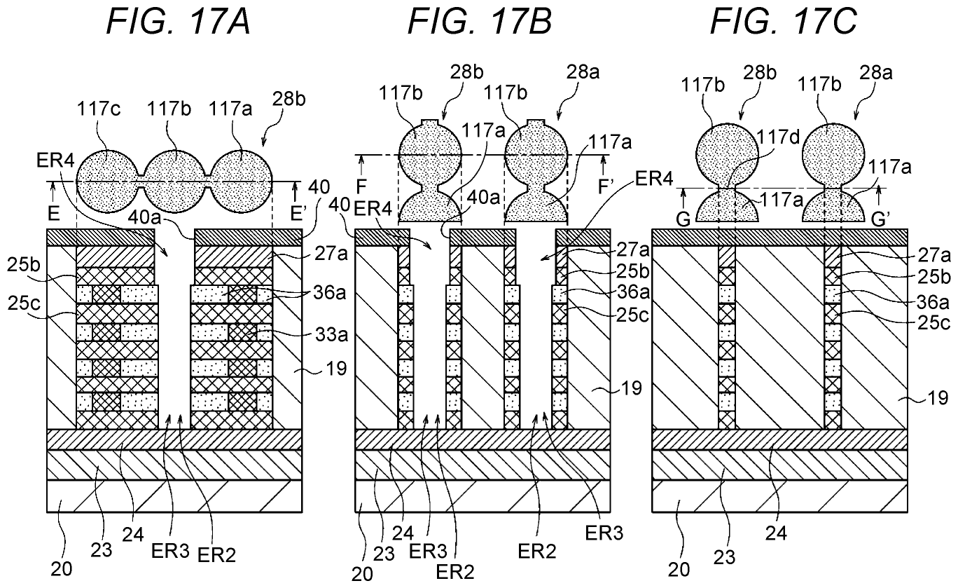

Then, as illustrated in FIGS. 17A, 17B, and 17C, for example, a new patterned mask layer 40 made of a resist material or the like is formed on the existing mask layer 27a and insulating layer 19. In the new mask layer 40, an opening 40a is formed in accordance with a predetermined position where the memory gate electrode MG is to be formed. The diameter of the opening 40a is formed to be slightly larger than the distance in the plane direction of the pillar-shaped interlayer insulating layers 33a.

Next, using the mask layer 40 as a mask, the mask layer 27a, the interlayer insulating layer 25a, and the pillar-shaped interlayer insulating layers 33a exposed from the opening 40a are etched by dry etching to form a hole ER2 for forming a memory gate electrode in which the surface of the insulating layer 24 is exposed from the opening 40a.

Here, when etching the mask layer 27a, the interlayer insulating layers 25a, and the pillar-shaped interlayer insulating layers 33a, the semiconductor layers 36a are left in the hole ER2 for forming a memory gate electrode by using an etching method in which the semiconductor layers 36a are not etched. As a result, in the hole ER2 for forming a memory gate electrode, a hole ER4 having the same opening size as the opening 40a of the mask layer 40 is formed in the mask layer 27a and the interlayer insulating layer 25b between the new mask layer 40 and the uppermost semiconductor layer 36a. In addition, in the hole ER2 for forming a memory gate electrode, a hole ER3 is formed in which the uppermost semiconductor layer 36a serves as a mask, the opening size is smaller than that of the hole ER4, and the diameter is the same as that of the removed pillar-shaped interlayer insulating layers 33a.

Since the opening 40a of the mask layer 40 is formed to be slightly larger than the diameter of the pillar-shaped interlayer insulating layers 33a provided between the semiconductor layers 36a arranged in the plane direction, the pillar-shaped interlayer insulating layers 33a between the semiconductor layers 36a arranged in the plane direction can be reliably removed by etching.

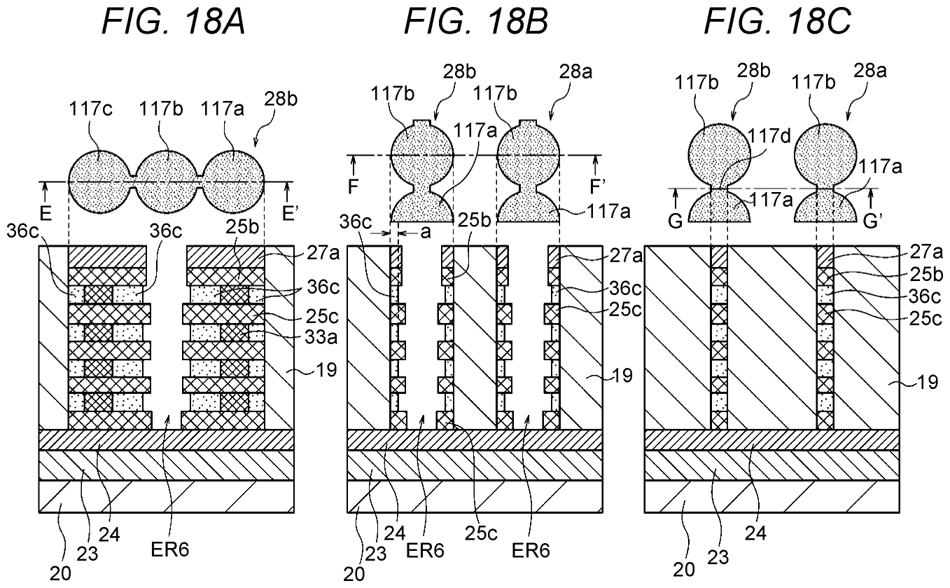

Next, as illustrated in FIGS. 18A, 18B, and 18C, after the mask layer 40 is removed, the semiconductor layers 36a exposed in the hole ER2 for forming a memory gate electrode are selectively etched by dry etching to form semiconductor layers 36c in which the distance of the semiconductor layers 36a in the plane direction is narrowed. As a result, as illustrated in FIG. 18A, a hole ER6 for forming a memory gate electrode is formed in the gap between the semiconductor layers 36c adjacent in the plane direction.

Here, as illustrated in FIG. 18B, the distance of the semiconductor layers 36c in the plane direction in the memory cell formation regions 28a and 28b is selected as the optimum distance a of less than 40 nm as described above.

Since the width of the gap in the uppermost interlayer insulating layer 25b immediately below the mask layer 27a is slightly larger than the width of the gap in the lower interlayer insulating layer 25c, the portion of the uppermost semiconductor layer 36c immediately below the uppermost interlayer insulating layer 25b may be subjected to side etching more than the portion of the lower semiconductor layer 36c. Therefore, it is desirable to form the memory cell Cb at a portion of the semiconductor layer 36c below the uppermost semiconductor layer 36c, without using the uppermost semiconductor layer 36c as the memory cell Cb.

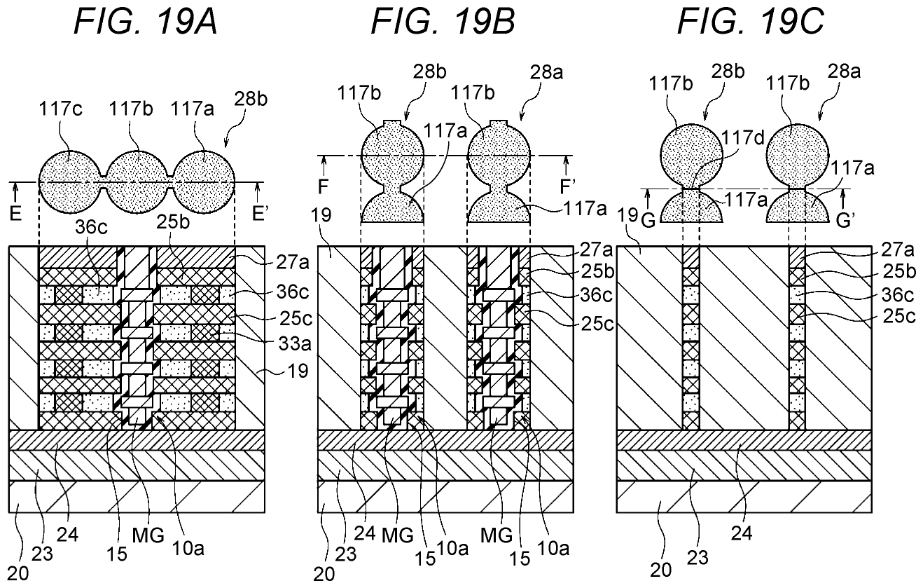

Next, as illustrated in FIGS. 19A, 19B, and 19C, after the multilayer insulating layer 15 is formed along the side surfaces and bottom surface of the hole ER6 for forming a memory gate electrode, a gate material such as low-resistance polycrystalline silicon or metal such as tungsten is deposited on the multilayer insulating layer 15 to form the memory gate electrode MG in the region surrounded by the multilayer insulating layer 15. Then, the insulating material and the like of the multilayer insulating layer 15 and the gate material deposited on the mask layer 27a and the insulating layer 19 are removed by surface polishing to expose the mask layer 27a. In this way, the memory gate structure 10a is formed in the hole ER6 for forming a memory gate electrode.

As illustrated in FIG. 6, the multilayer insulating layer 15 is formed by sequentially stacking the second memory gate insulating layer 15c made of silicon oxide (SiO₂) or the like, the charge storage layer 15b made of silicon nitride (Si₃N₄), silicon oxynitride (SiON), alumina (Al₂O₃), hafnium oxide (HfO₂), or the like, and the first memory gate insulating layer 15a made of silicon oxide (SiO₂) or the like on the side surfaces and bottom surface of the hole ER6 for forming a memory gate electrode.

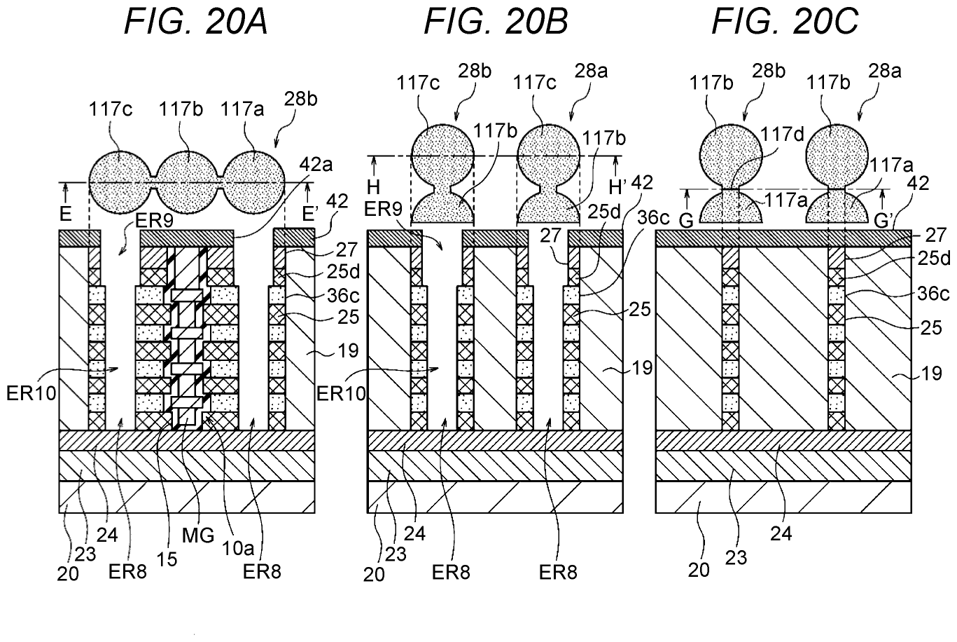

Next, as illustrated in FIGS. 20A, 20B, and 20C, for example, a new patterned mask layer 42 made of a resist material or the like is formed on the existing mask layer 27a, the memory gate structure 10a, and the insulating layer 19. In the new mask layer 42, an opening 42a is formed in accordance with each predetermined position where the drain-side select gate electrode DG and the source-side select gate electrode SG are to be formed. The diameter of the opening 42a is formed to be slightly larger than the distance in the plane direction of the pillar-shaped interlayer insulating layers 33a.

Next, using the new mask layer 42 as a mask, the existing mask layer 27a, the interlayer insulating layers 25b, and the pillar-shaped interlayer insulating layers 33a exposed from the openings 42a are etched by dry etching to form a hole ER8 for forming a select gate electrode in which the surface of the insulating layer 24 is exposed from the openings 42a.

Here, when removing the pillar-shaped interlayer insulating layers 33a by etching to form the mask layer 27 having the hole ER8 and the interlayer insulating layers 25d and 25, the semiconductor layers 36c are left in the hole ER8 for forming a select gate electrode using an etching method in which the semiconductor layers 36c are not etched. As a result, in the hole ER8 for forming a select gate electrode, a hole ER9 having the same opening size as the opening 42a of the mask layer 42 is formed in the mask layer 27 and the interlayer insulating layer 25d between the new mask layer 42 and the uppermost semiconductor layer 36c. In addition, in the hole ER8 for forming a select gate electrode, a hole ER10 is formed in which the uppermost semiconductor layer 36c serves as a mask, the opening size is smaller than that of the hole ER9, and the diameter is the same as that of the removed pillar-shaped interlayer insulating layers 33a.

Since the opening 42a of the mask layer 42 is formed to be slightly larger than the diameter of the pillar-shaped interlayer insulating layers 33a provided between the semiconductor layers 36c, the pillar-shaped interlayer insulating layers 33a between the semiconductor layers 36c can be reliably removed by etching.

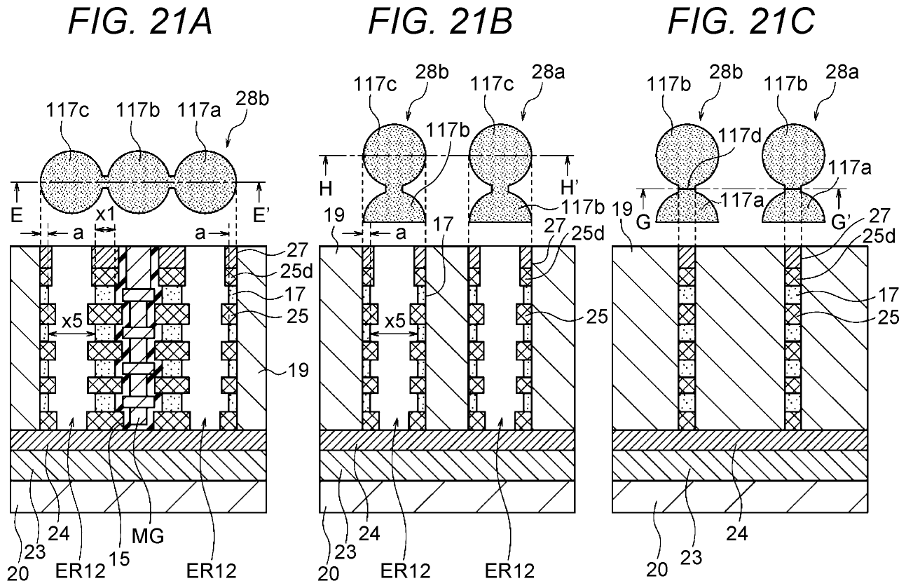

Next, as illustrated in FIGS. 21A, 21B, and 21C, after the mask layer 42 is removed, the semiconductor layers 36c exposed in the hole ER8 for forming a select gate electrode are selectively etched by dry etching to form the semiconductor layers 17 in which the distance in the plane direction is narrowed. As a result, as illustrated in FIG. 21A, a hole ER12 for forming a select gate electrode is formed in which the width (gap width) x5 in the plane direction of the gap between the semiconductor layers 17 adjacent in the plane direction is approximately 5 to 7 times that of the semiconductor layers 17.

Here, in the hole ER12 in which the drain-side select gate structure 11a is to be formed, the gap width x5 between the semiconductor layers 17 adjacent in the plane direction is the diameter of the enlarged diameter portion 30b of the drain-side select gate structure 11a to be formed in the hole ER12 (that is, the combined diameter of the drain-side select gate electrode DG and the drain-side select gate insulating layer 14a in the enlarged diameter portion 30b).

In addition, in the hole ER12 in which the source-side select gate structure 12a is to be formed, the gap width x5 between the semiconductor layers 17 adjacent in the plane direction is the diameter of the enlarged diameter portion 30b of the source-side select gate structure 12a to be formed in the hole ER12 (that is, the combined diameter of the source-side select gate electrode SG and the source-side select gate insulating layer 14b in the enlarged diameter portion 30b). In this case, as illustrated in FIGS. 21A and 21B, the distance a in the plane direction of the semiconductor layers 17 in the drain-side formation region 117a and the source-side formation region 117c is selected to be less than 40 nm as described above.

As described above, since the width of the gap in the uppermost interlayer insulating layer 25d immediately below the mask layer 27 is slightly larger than the width of the gap in the lower interlayer insulating layer 25, the portion of the uppermost semiconductor layer 17 immediately below the uppermost interlayer insulating layer 25d may be subjected to side etching more than the portion of the lower semiconductor layer 17. Therefore, it is desirable to form the memory cell Cb at a portion of the semiconductor layer 17 below the uppermost semiconductor layer 17, without using the uppermost semiconductor layer 17 as the memory cell Cb.

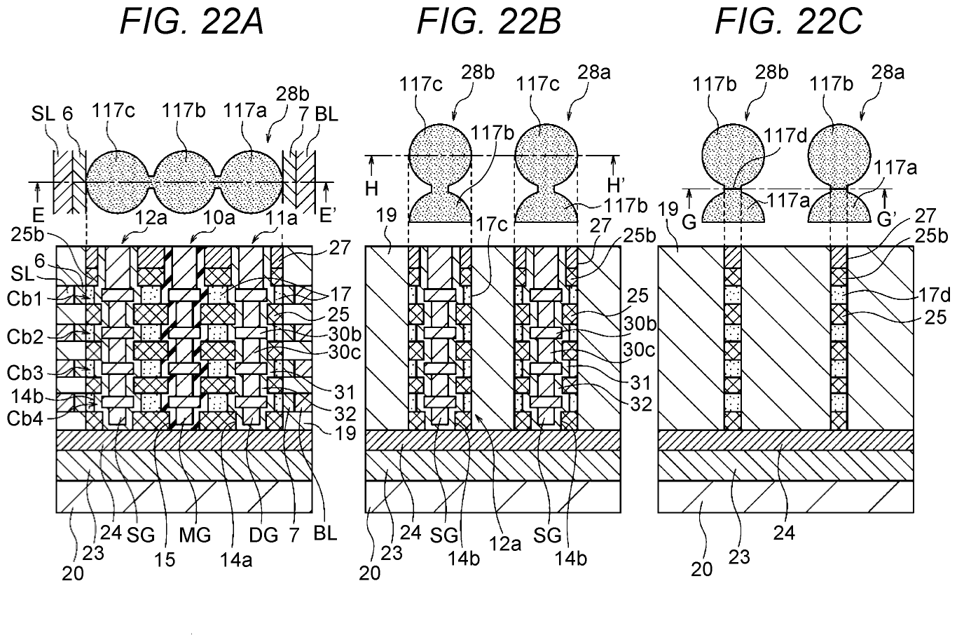

Next, an insulating material such as a silicon oxide film is deposited on the side surface and bottom surface of the hole ER12 for forming a select gate electrode, and as illustrated in FIGS. 22A, 22B, and 22C, the drain-side select gate insulating layer 14a and the source-side select gate insulating layer 14b are formed along the side surfaces and bottom surface of the hole ER12 for forming a select gate electrode. Next, a gate material such as low-resistance polycrystalline silicon or metal such as tungsten is deposited on the drain-side select gate insulating layer 14a and the source-side select gate insulating layer 14b to form the drain-side select gate electrode DG and the source-side select gate electrode SG in a region surrounded by the drain-side select gate insulating layer 14a and the source-side select gate insulating layer 14b, respectively.

Then, the insulating materials and the like of the drain-side select gate insulating layer 14a and the source-side select gate insulating layer 14b deposited on the mask layer 27 and the insulating layer 19, and the gate material are removed by surface polishing to expose the mask layer 27. In FIGS. 6 and 22C, the mask layer 27 is left as it is. However, the mask layer 27 is preferably removed by surface polishing.

In this way, the drain-side select gate structure 11a and the source-side select gate structure 12a are formed in the hole ER12 for forming a memory gate electrode.

Next, the drain diffusion layer 7 and the bit line BL are formed in the region of the insulating layer 19 adjacent to the drain-side formation region 117a, and the source diffusion layer 6 and the source line SL are formed in the region of the insulating layer 19 adjacent to the source-side formation region 117c by a general semiconductor manufacturing process using a photolithography technique, a film formation technique such as chemical vapor deposition (CVD), an etching technique, an ion implantation method, and the like. At this time, the drain diffusion layer 7 and the bit line BL, and the source diffusion layer 6 and the source line SL are formed in the layer in which the semiconductor layer 17 is formed, as illustrated in FIG. 22A. In addition, the insulating layer 19 is formed between the upper layer and the lower layer in which the drain diffusion layer 7 and the bit line BL are formed, and between the upper layer and the lower layer in which the source diffusion layer 6 and the source line SL are formed. As described above, the memory cell Cb as illustrated in FIG. 6 can be formed.

### (1-10) Operation and Advantageous Effects

In the above configuration, in the memory cell C, the pillar-shaped memory gate electrode MG disposed with the insulating layer 19 interposed therebetween on the substrate 20 is provided in the region between the drain diffusion layer 7 and the source diffusion layer 6 extending in the plane direction of the surface of the substrate 20, the pillar-shaped drain-side select gate electrode DG disposed with the insulating layer 19 interposed therebetween on the substrate 20 is provided in the region between the drain diffusion layer 7 and the memory gate electrode MG, and the pillar-shaped source-side select gate electrode SG disposed with the insulating layer 19 interposed therebetween on the substrate 20 is provided in the region between the source diffusion layer 6 and the memory gate electrode MG.

In addition, the multilayer insulating layer 15 including the charge storage layer 15b is provided on the side surfaces of the memory gate electrode MG, the drain-side select gate insulating layer 14a is provided on the side surfaces of the drain-side select gate electrode DG, and the source-side select gate insulating layer 14b is provided on the side surfaces of the source-side select gate electrode SG.

Further, in the memory cell C, the semiconductor layer 17 is provided in the region between the drain diffusion layer 7 and the source diffusion layer 6 that run in parallel, and the semiconductor layer 17 is arranged so as to be in contact with the side surfaces of the drain-side select gate insulating layer 14a, the side surfaces of the source-side select gate insulating layer 14b, the side surfaces of the multilayer insulating layer 15, the side surfaces of the drain diffusion layer 7, and the side surfaces of the source diffusion layer 6.

In this manner, in the present embodiment, the memory cells C are three-dimensionally structured such that the memory transistor MT, the drain-side select transistor DT, and the source-side select transistor ST are connected in series. Since the memory cells C are three-dimensionally structured, the memory cells C can be integrated and downsized without being restricted by two-dimensional scaling.

In the memory gate structure 10 according to the present embodiment, the multilayer insulating layer 15 is provided on the side surface of the circular pillar-shaped memory gate electrode MG over the entire circumference along the circumferential direction, and the side surfaces of the multilayer insulating layer 15 in contact with the semiconductor layer 17 are shaped with no corner and smoothly curved. In addition, in the drain-side select gate structure 11, the drain-side select gate insulating layer 14a is provided on the side surface of the circular pillar-shaped drain-side select gate electrode DG over the entire circumference along the circumferential direction, and the side surfaces of the drain-side select gate insulating layer 14a in contact with the semiconductor layer 17 are shaped with no corner and smoothly curved. In addition, in the source-side select gate structure 12, the source-side select gate insulating layer 14b is provided on the side surface of the circular pillar-shaped source-side select gate electrode SG over the entire circumference along the circumferential direction, and the side surfaces of the source-side select gate insulating layer 14b in contact with the semiconductor layer 17 are shaped with no corner and smoothly curved.

In a general memory cell having a two-dimensional structure, the gate electrode has a planar gate-type structure, and an electric field concentrates at a corner portion of the gate electrode during a data program operation or the like, so that there is a possibility that disturbance resistance is lowered.

On the other hand, in the memory gate structure 10, the drain-side select gate structure 11, and the source-side select gate structure 12 according to the present embodiment, as described above, since the side surfaces in contact with the semiconductor layer 17 have no corner and are formed in a smooth curve. Therefore, there is no portion where an electric field concentrates, and accordingly, so that the disturbance resistance can be improved as compared with the conventional planar gate-type structure.

### (1-11) Other Embodiments

The present invention is not limited to the above-described embodiments. For example, instead of the drain-side select gate insulating layer 14a and the source-side select gate insulating layer 14b made of only a single insulating material, a drain-side select gate insulating layer 14a and a source-side select gate insulating layer 14b of a multilayer structure including a charge storage layer may be applied, similarly to the multilayer insulating layer 15.

In this case, for example, as illustrated in FIGS. 18A and 19C, in the step of manufacturing the memory gate structure 10a, the drain-side select gate structure 11a and the source-side select gate structure 12a are manufactured simultaneously. Specifically, when forming the hole ER2 for forming a memory gate electrode is formed, the hole ER8 for forming a select gate electrode is formed, and in the step of forming the multilayer insulating layer 15, the drain-side select gate insulating layer and the source-side select insulating layer of the same configuration as that of the multilayer insulating layer 15 are manufactured simultaneously with the multilayer insulating layer 15, and in the step of forming the memory gate electrode MG, the drain-side select gate electrode DG and the source-side select gate electrode SG are formed simultaneously with the memory gate electrode MG.

In the present embodiment, as pillar-shaped memory gate electrode, drain-side select gate electrode, and source-side select gate electrode, the circular pillar-shaped memory gate electrode MG, drain-side select gate electrode DG, and source-side select gate electrode SG are applied. However, the present invention is not limited thereto. For example, pillar-shaped memory gate electrode, drain-side select gate electrode, and source-side select gate electrode of various shapes such as a square pillar shape and a polygonal pillar shape may be applied. In this case, the multilayer insulating layer, the drain-side select gate insulating layer, and the source-side select gate insulating layer are formed over the entire circumference along the side surfaces of the memory gate electrode, drain-side select gate electrode, and source-side select gate electrode.

In the present embodiment, as a configuration in which the semiconductor layer is in contact with the side surfaces of the drain-side select gate insulating layer, source-side select gate insulating layer, multilayer insulating layer, drain diffusion layer, and source diffusion layer, the semiconductor layer 17 is provided between the drain diffusion layer 7 and the drain-side select gate insulating layer 14a, and the semiconductor layer 17 is provided between the source diffusion layer 6 and the source-side select gate insulating layer 14b, for example, as illustrated in FIG. 2B. However, the present invention is not limited thereto. For example, the side surfaces of the drain diffusion layer 7 and the side surfaces of the drain-side select gate insulating layer 14a may be in contact with each other without providing the semiconductor layer 17 between drain diffusion layer 7 and drain-side select gate insulating layer 14a, or the side surfaces of the source diffusion layer 6 and the side surfaces of the source-side select gate insulating layer 14b may be in contact with each other without providing the semiconductor layer 17 between the source diffusion layer 6 and the source-side select gate insulating layer 14b.

Further, in the present embodiment, a plurality of memory cells is arranged in a plurality of rows, a plurality of columns, and a plurality of levels, but the present invention is not limited thereto. The number of rows, the number of columns, and the number of levels may be one or more, and for example, one row, a plurality of columns, and a plurality of levels may be used, or a plurality of row, one column, and one level may be used.

(1-12) Memory Cell According to Another Embodiment in which a Plurality of Memory Transistors is Provided Between Drain-Side Select Transistor and Source-Side Select Transistor

### (1-12-1) Configuration of Non-volatile Semiconductor Memory Device

Furthermore, in the above-described embodiments, the memory cell C with one memory transistor MT is provided between a pair of the drain-side select transistor DT and the source-side select transistor ST. However, the present invention is not limited thereto. A memory cell with a plurality of memory transistors in series may be provided between a pair of the drain-side select transistor DT and the source-side select transistor ST.

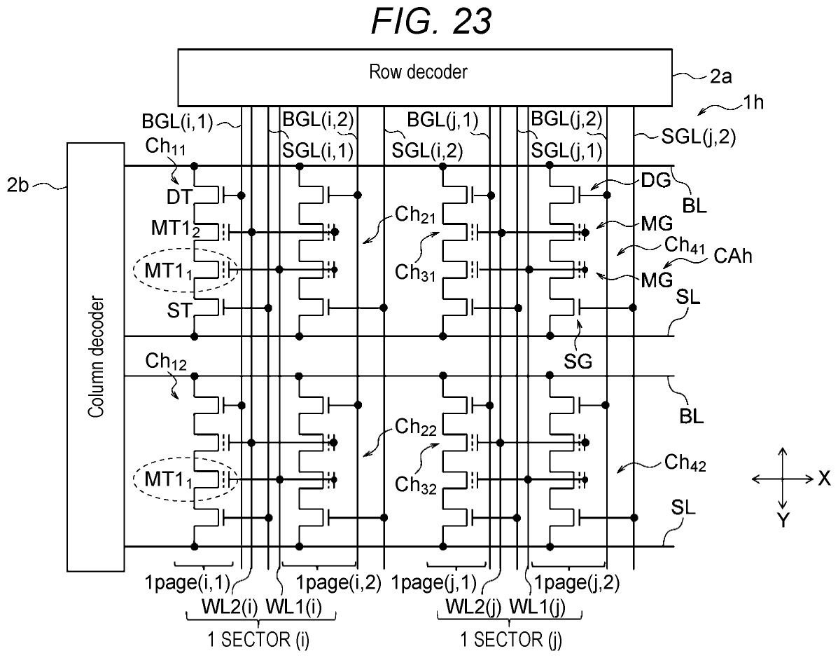

FIG. 23 is a circuit diagram that illustrates a configuration of an equivalent circuit of a non-volatile semiconductor memory device 1h having a memory cell Ch in which a plurality of memory transistors MT1₁ and MT1₂ is provided in series. Here, in a case of distinguishing the individual memory cells, assuming that i and j are set to 1, 2, 3, . . . , respectively, the memory cells in the i-th row and the j-th column will be described as memory cells Chᵢⱼ. In a case of not distinguishing the memory cells, they will be simply described as memory cells Ch.

The non-volatile semiconductor memory device 1h actually includes a memory array CAh in which a plurality of memory cells Ch arranged in a matrix in a plane direction are hierarchically arranged along a vertical direction Z orthogonal to the plane direction, similarly to the non-volatile semiconductor memory device 1 illustrated in FIG. 1. Since the arrangement configurations of the plurality of memory cells Ch arranged in a matrix at the individual levels are the same. Accordingly, FIG. 23 illustrates only the arrangement configuration of the plurality of memory cells Ch arranged at the first level that is the upper layer, and does not illustrate the arrangement configurations of the plurality of memory cells Ch arranged in the lower layers. Hereinafter, description will be given focusing on the first level that is the upper layer.

In the memory array CAh illustrated in FIG. 23, the plurality of memory cells Ch is arranged in four rows and two columns in the plane direction as an example. Similarly to the configuration illustrated in FIG. 1, the configuration of the plurality of memory cells Ch arranged in one row direction Y (vertical plane direction (normal direction in the plane direction) extending in the row direction Y orthogonal to the plane direction) including the plurality of memory cells Ch arranged at different levels and different columns will be referred to as one page (“1 page” in FIG. 1). In addition, a plurality of pages in which a first word line WL1 is shared between the first memory transistor MT1₁ and a second word line WL2 is shared by the second memory transistor MT1₂ will be described as one sector.

FIG. 23 illustrates an example in which two sectors (i) and (j) are provided. One sector (i) is provided with two pages (i, 1) and (i, 2), and the other sector (j) is also provided with two pages (j, 1) and (j, 2). Here, in a case of individually distinguishing the sectors, the pages, the word lines WL, the drain-side select gate lines BGL, and the source-side select gate lines SGL provided in the sectors, they will be described with i and j. In a case of not particularly distinguishing them, they will be simply described as the sectors, the pages, the word lines WL, the drain-side select gate lines BGL, and the source-side select gate lines SGL without i and j.

In this case, as in FIG. 1, the bit line BL extends in the column direction X at each level of the memory array CAh, and is connected to the plurality of memory cells Ch arranged in the same column at each level. Similarly to in the case of FIG. 1, the source line SL runs in parallel with the bit lines BL and extends in the column direction X at each level of the memory array CAh, and is connected to the memory cells Ch in the same column at each level. That is, one bit line BL and one source line SL are shared by the plurality of memory cells Ch arranged in the column direction X at each level.

The drain-side select gate line BGL and the source-side select gate line SGL are provided in each row (page), and are connected to the plurality of memory cells Ch arranged in the same row (in the same page) including the different levels. That is, one drain-side select gate line BGL and one source-side select gate line SGL are shared by the memory cells Ch in the page arranged in the row direction Y including the different levels.

For example, in the sector (i), for a plurality of memory cells Ch₁₁ and Ch₁₂ in one page (i, 1), a drain-side select gate line BGL(i, 1) is connected to the drain-side select gate electrode DG of each drain-side select transistor DT, and a source-side select gate line SGL (i, 1) is connected to the source-side select gate electrode SG of each source-side select transistor ST. In the sector (i), for a plurality of memory cells Ch₂₁ and Ch₂₂ in another page (i, 2), a drain-side select gate line BGL(i, 2) is connected to the drain-side select gate electrode DG of each drain-side select transistor DT, and another source-side select gate line SGL (i, 2) is connected to the source-side select gate electrode SG of each source-side select transistor ST.

The word line WL1 (WL2) is provided for each sector, and is connected to a plurality of memory transistors MT1₁ (MT1₂) arranged in the same sector including different pages and different levels. For example, in the sector (i), including different pages (i, 1) and (i, 2) and different levels, one first word line WL1(i) is shared among the plurality of first memory transistors MT1₁ provided in the sector (i), and one second word line WL2(i) is shared among the plurality of second memory transistors MT1₂ provided in the sector (i).

More specifically, in the sector (i), the memory gate electrode MG of the first memory transistor MT1₁ provided in one page (i, 1), the memory gate electrode MG of the first memory transistor MT1₁ provided in another page (i, 2), and the first word line WL1(i) are connected. In the sector (i), the memory gate electrode MG of the first memory transistor MT1₂ provided in one page (i, 1), the memory gate electrode MG of the second memory transistor MT1₂ provided in another page (i, 2), and the second word line WL2(i) are connected.

As described above, in the memory array CAh, in the plurality of pages (i, 1) and (i, 2) in one sector (i), the first memory transistors MT1₁ share one first word line WL1(i), and the second memory transistors MT1₂ share one second word line WL2(i). Therefore, since the word lines WL are not individually provided for the pages (i, 1) and (i, 2), the configuration can be simplified.

In the memory array CAh, the drain-side select gate lines BGL, the source-side select gate lines SGL, and the word lines WL1 and WL2 do not extend in the row direction Y at the second level that is the lower layer not illustrated, but extend in the row direction Y only at the first level that is the upper layer, and the drain-side select gate lines BGL, the source-side select gate lines SGL, and the word lines WL1 and WL2 provided in the upper layer are electrically connected to each of the memory cells Ch arranged in the lower layer.

Here, the cross-sectional configuration in the plan view of the memory cell Ch indicated by the equivalent circuit in FIG. 23 is a cross-sectional configuration in which a plurality of memory gate structures 10 is linearly arranged between a pair of the drain-side select gate structure 11 and the source-side select gate structure 12 in the configuration of the memory cell C illustrated in FIG. 2B. Therefore, the detailed description thereof is omitted here in order to avoid duplicate description.

In addition, the longitudinal cross-sectional configuration in the vertical direction Z of the memory cell Ch indicated by the equivalent circuit in FIG. 23 is a longitudinal cross-sectional configuration in which a plurality of memory gate structures 10 is linearly arranged between a pair of the drain-side select gate structure 11 and the source-side select gate structure 12 in the configuration of the memory cell C illustrated in FIG. 4. Therefore, the detailed description thereof is omitted here in order to avoid duplicate description.

In addition, in the pluralities of memory gate structures 10, drain-side select gate structures 11, and source-side select gate structures 12 of the memory array CAh, as illustrated in FIG. 6, the enlarged diameter portion 30b and the reduced diameter portion 30c may be alternately provided on the side surfaces of the memory gate electrode MG, the drain-side select gate electrode DG, and the source-side select gate electrode SG, thereby to form the side surfaces in a concavo-convex shape.

As described above, the memory array CAh in which the enlarged diameter portion 30b and the reduced diameter portion 30c are alternately formed on the side surfaces of the pluralities of memory gate electrodes MG, drain-side select gate electrodes DG, and source-side select gate electrodes SG can be manufactured by forming the plurality of adjacent memory gate structures 10 according to the manufacturing steps illustrated in FIGS. 12 to 22C described above.

### (1-12-2) Specific Examples of Voltages in Data Program Operation, Read Operation, and Erase Operation

Table 2 below shows specific examples (voltage examples) of combinations of voltages at a data program operation and a data read operation in the non-volatile semiconductor memory device 1h illustrated in FIG. 23. Table 3 below shows specific examples (voltage examples) of combinations of voltages at a data erase operation on a sector-by-sector basis in the non-volatile semiconductor memory device 1h. The unit of the voltage values shown in Tables 2 and 3 is “V”.

TABLE 2

| | | | Operation | | | |
|---|---|---|---|---|---|---|
| | | | Read | | Program | |
| | | | Selected | Unselected | Selected | Unselected |
| | | | BL | BL | BL | BL |
| | | | column | column | column | column |
| Word line | Selected | V_{CG1} | 0 | 0 | 15 | 15 |
| WL1 (i) | page | (connected | | | | |
| | | to selected | | | | |
| | | cells) | | | | |
| Word line | Selected | V_{CG2} | 6 | 6 | 8 | 8 |
| WL2 (i) | page | (connected | | | | |
| | | to | | | | |
| | | unselected | | | | |
| | | cells) | | | | |
| Word line | Unselected | V_{CG3} | 0 | 0 | 0 | 0 |
| WL1 (j) | page | | | | | |
| Word line | Unselected | | 0 | 0 | 0 | 0 |
| WL2 (j) | page | | | | | |
| Source- | Selected | V_{SGS1} | 1.5 | 1.5 | 0 | 0 |
| side | page (i, 1) | | | | | |
| select | | | | | | |
| gate line | | | | | | |
| SGL (i, | | | | | | |
| 1) | | | | | | |
| Source- | Unselected | V_{SGS2} | 0 | 0 | 0 | 0 |
| side | page (i, 2) | | | | | |
| select | | | | | | |
| gate line | | | | | | |
| SGL (i, | | | | | | |
| 2) | | | | | | |
| Source- | Unselected | V_{SGS3} | 0 | 0 | 0 | 0 |
| side | pages [(j, | | | | | |
| select | 1) (j, 2)] | | | | | |
| gate line | | | | | | |
| SGL (j) | | | | | | |
| Drain- | Selected | V_{SGD1} | 1.5 | 1.5 | 1.5 | 1.5 |
| side | pages (i, 1) | | | | | |
| select | | | | | | |
| gate line | | | | | | |
| BGL (i, | | | | | | |
| 1) | | | | | | |
| Drain- | Unselected | V_{SGD2} | 0 | 0 | 0 | 0 |
| side | page (i, 2) | | | | | |
| select | | | | | | |
| gate line | | | | | | |
| BGL (i, | | | | | | |
| 2 ) | | | | | | |
| Drain- | Unselected | V_{SGD3} | 0 | 0 | 0 | 0 |
| side | pages [(j, | | | | | |
| select | 1) (j, 2)] | | | | | |
| gate line | | | | | | |
| BGL (j) | | | | | | |
| Bit line | — | V_{BL} | 1 | 0 | 0 | 1.5 |
| BL | | | | | | |
| Source | — | V_{SL} | 0 | 0 | 1.2 | 1.2 |
| line SL | | | | | | |

TABLE 3

| | | | Erase |
|---|---|---|---|
| | | | Junction |
| | | | current |
| | | Operation | induced |
| Word line WL1 (i) | Selected page | V_{CG1} | −3 |
| Word line WL2 (i) | Selected page | V_{CG2} | −3 |
| Word line WL1 (j) | Unselected page | V_{CG3} | 10 |
| Word line WL2 (j) | Unselected page | | 10 |
| Source-side select gate | Selected page (i, 1) | V_{SGS1} | 7 |
| line SGL (i, 1) | | | |
| Source-side select gate | Selected page (i, 2) | V_{SGS2} | 7 |
| line SGL (i, 2) | | | |
| Source-side select gate | Unselected pages | V_{SGS3} | 10 |
| line SGL (j) | [(j, 1) (j, 2)] | | |
| Drain-side select gate | Selected page (i, 1) | V_{SGD1} | 7 |
| line BGL (i, 1) | | | |
| Drain-side select gate | Selected page (i, 2) | V_{SGD2} | 7 |
| line BGL (i, 2) | | | |
| Drain-side select gate | Unselected pages | V_{SGD3} | 10 |
| line BGL (j) | [(j, 1) (j, 2)] | | |
| Bit line BL | — | V_{BL} | 10 |
| Source line SL | — | V_{SL} | 10 |

In above Tables 2 and 3, in order to simplify the description, as illustrated in FIG. 23, each operation is organized focusing on the configuration in the plane direction in which the memory cells Ch are arranged in a matrix in the column direction X and the row direction Y. In Table 2, in FIG. 23, a column of a memory cell Ch group electrically connected to the bit line BL extended in the column direction X from the column decoder 2b will be referred to as “BL column”, a BL column including the memory cells Ch in which data is programed and data is read will be referred to as “selected BL column”, and a BL column including only the memory cells Ch in which data is not programed and data is not read will be referred to as “unselected BL column”.

V_{CG1}, V_{CG2}, V_{CG3}, V_{SGS1}, V_{SGS2}, V_{SGS3}, V_{SGD1}, V_{SGD2}, V_{SGD3}, V_{BL}, and V_{SL} shown in Tables 2 and 3 are codes representing voltages applied to the corresponding lines, similarly to Table 1 described above. In the present embodiment, since the two word lines WL1 and WL2 are provided, the memory gate voltages applied to the word lines WL1 and WL2 are represented by three of V_{CG1}, V_{CG2}, and V_{CG3}, unlike Table 1 described above.

In Table 2, the memory cells Ch in which data is programed and data is read will be referred to as selected cells, and the memory cells Ch in which data is not programed and data is not read will be referred to as unselected cells. The pages including the selected cell will be referred to as selected pages, and the pages including only the unselected cell will be referred to as unselected pages.

In the example of the data program operation shown in Table 2 (described as “Program” in Table 2), voltages when programming data to the first memory transistors MT1₁ in the memory cells Ch₁₁ in the first row and the first column in the memory array CAh illustrated in FIG. 23 are shown. In this case, the page (i, 1) is a selected page, and the remaining pages (i, 2), (j, 1), and (j, 2) are unselected pages. In FIG. 23, the column of the group of the upper memory cells Ch₁₁, Ch₂₁, Ch₃₁, and Chai is the selected BL column, and the column of the group of the lower memory cells Ch₁₂, Ch₂₂, Ch₃₂, and Ch₄₂ is the unselected BL column.

In the example of the data read operation shown in Table 2 (described as “Read” in Table 2), voltages when reading data from the first memory transistors MT1₁ in the memory cells Ch₁₁ in the first row and the first column in the memory array CAh illustrated in FIG. 23 are shown. In this case, the page (i, 1) is a selected page, and the remaining pages (i, 2), (j, 1), and (j, 2) are unselected pages. In FIG. 23, the column of the group of the upper memory cells Ch₁₁, Ch₂₁, Ch₃₁, and Ch₄₁ is the selected BL column, and the column of the group of the lower memory cells Ch₁₂, Ch₂₂, Ch₃₂, and Ch₄₂ is the unselected BL column.

In Table 3, the pages included in a sector in which data is to be erased are referred to as selected pages, and the pages included in a sector in which data is not to be erased are referred to as unselected pages. In the example of the data erase operation shown in Table 3, voltages when erasing the data from the first memory transistors MT1₁ in the memory cells Ch₁₁, Ch₁₂, Ch₂₁, and Ch₂₂ provided in the sector (i) in the memory array CAh of FIG. 23 are shown.

In the non-volatile semiconductor memory device 1, applying voltages as shown in Tables 2 and 3 makes it possible to selectively program, read, and erase data in predetermined memory cells Ch on the same principle as in the first embodiment described above.

### (1-12-3) Operations and Advantageous Effects

In the memory cells Ch described above, similarly to the memory cells C shown in FIGS. 2A, 2B and 4, a plurality of pillar-shaped memory gate electrodes MG is disposed on the substrate 20 with the insulating layer 19 interposed therebetween, in a region between the drain diffusion layer 7 and the source diffusion layer 6 extending in the plane direction of the surface of the substrate 20 and running in parallel. Further, in the memory cell Ch, the pillar-shaped drain-side select gate electrode DG disposed on the substrate 20 with the insulating layer 19 interposed therebetween is provided in the region between the drain diffusion layer 7 and the memory gate electrode MG on one side, and the pillar-shaped source-side select gate electrode SG disposed on the substrate 20 with the insulating layer 19 interposed therebetween is provided in the region between the source diffusion layer 6 and the memory gate electrode MG on the other side.

In the memory cell Ch, the multilayer insulating layer 15 including the charge storage layer 15b is provided on the side surfaces of the plurality of memory gate electrodes MG, the drain-side select gate insulating layer 14a is provided on the side surface of the drain-side select gate electrode DG, and the source-side select gate insulating layer 14b is provided on the side surface of the source-side select gate electrode SG.

Further, in the memory cell Ch, the semiconductor layer 17 is provided in the region between the drain diffusion layer 7 and the source diffusion layer 6 that run in parallel, and the semiconductor layer 17 is arranged so as to be in contact with the side surfaces of the drain-side select gate insulating layer 14a, the side surfaces of the source-side select gate insulating layer 14b, the side surfaces of the multilayer insulating layer 15, the side surfaces of the drain diffusion layer 7, and the side surfaces of the source diffusion layer 6.

In this manner, in the present embodiment, the memory cells Ch are three-dimensionally structured such that the plurality of memory transistors MT1₁ and MT1₂, the drain-side select transistor DT, and the source-side select transistor ST are connected in series. Since the memory cells Ch are three-dimensionally structured, the memory cells Ch can be integrated and downsized without being restricted by two-dimensional scaling.

In addition, in the memory cell Ch according to the present embodiment, since the word lines WL1 and WL2 are provided sector by sector including a plurality of pages, not page by page, the number of the word lines WL1 and WL2 can be decreased accordingly, and the structure can be simplified.

### (2) Second Embodiment

(2-1) Configuration of Equivalent Circuit of Non-volatile Semiconductor Memory Device according to Second Embodiment

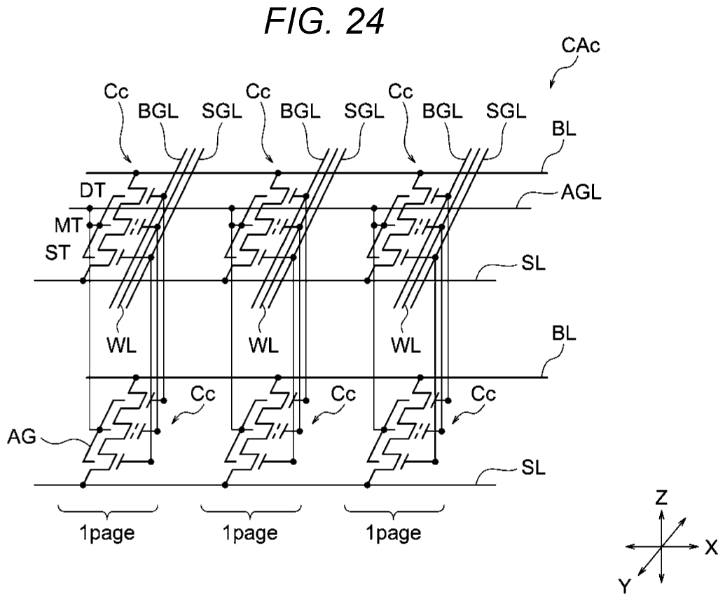

FIG. 24 is a schematic diagram illustrating a configuration of an equivalent circuit focusing on a memory array CAc provided in a non-volatile semiconductor memory device according to a second embodiment. The memory array CAc according to the second embodiment is different from the memory array CA according to the first embodiment illustrated in FIG. 1 in that an assist gate line AGL and assist gate electrodes AG are provided. The non-volatile semiconductor memory device of the second embodiment includes the memory array CAc, a plurality of bit lines BL, a plurality of source lines SL, a plurality of drain-side select gate lines BGL, a plurality of source-side select gate lines SGL, a plurality of word lines WL, and the assist gate line AGL.

The assist gate line AGL extends in the column direction X so as to run in parallel with the bit lines BL and the source lines SL extending in the column direction X, and is connected to a plurality of memory cells Cc arranged in the same row including different levels. That is, the plurality of memory cells Cc arranged in the same column direction X including different levels share the one assist gate line AGL. Each assist gate line AGL provided for each column including different levels is connected to a column decoder 2b not illustrated. Since the bit lines BL, the source lines SL, the drain-side select gate lines BGL, the source-side select gate lines SGL, and the word lines WL are provided in the same configuration as that of the first embodiment, description thereof is omitted here.

In the memory cell Cc, the voltages of the bit line BL, source line SL, drain-side select gate line BGL, source-side select gate line SGL, word line WL, and assist gate line AGL connected thereto are controlled by a row decoder 2a and the column decoder 2b not illustrated, so that programming of data, erasing of data, and reading of data are performed on the memory transistor MT. Details of a data program operation, an erase operation, and a read operation in the non-volatile semiconductor memory device according to the second embodiment will be described later.

In the memory array CAc according to the present embodiment, the plurality of memory cells Cc arranged in a matrix at each level is identical in arrangement configuration. Thus, when it is not necessary to distinguish by level, the following description will be mainly given focusing on the arrangement configuration of the plurality of memory cells Cc arranged at the first level that is the upper layer.

The memory cells Cc are different from the memory cells C according to the first embodiment illustrated in FIG. 1 in that the assist gate electrode AG is provided. The memory cells Cc are identical in configuration, and each include a drain-side select transistor DT, a memory transistor MT, and a source-side select transistor ST, and the assist gate electrode AG. The drain-side select transistor DT, the memory transistor MT, and the source-side select transistor ST are connected in series. In each memory cell Cc, the drain-side select transistor DT, the memory transistor MT, and the source-side select transistor ST share one assist gate electrode AG. Details of the configuration of the memory cell Cc will be described later.

### (2-2) Configuration of Memory Cell

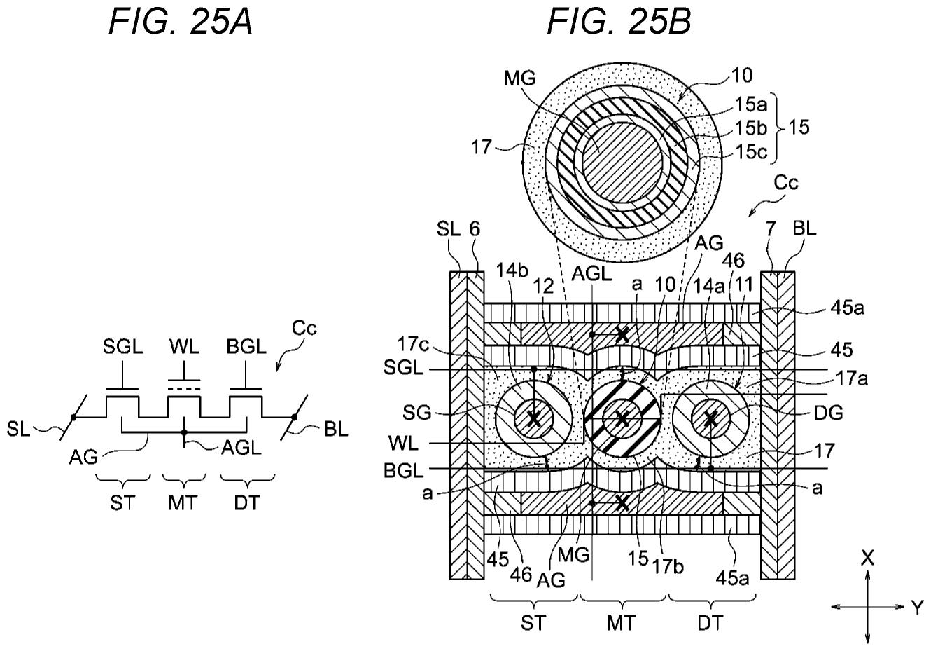

Next, the configuration of the memory cell Cc will be described. FIG. 25A is a circuit diagram illustrating a configuration of an equivalent circuit of the memory cell Cc. As illustrated in FIG. 25A, in the memory cell Cc, one end of the drain-side select transistor DT is connected to one end of the memory transistor MT having a charge storage layer to be described later, and one end of the source-side select transistor ST is connected to the other end of the memory transistor MT.

The bit line BL is connected to the other end of the drain-side select transistor DT, and the source line SL is connected to the other end of the source-side select transistor ST. The drain-side select gate line BGL is connected to the drain-side select gate electrode DG (described later with reference to FIG. 25B) of the drain-side select transistor DT, the source-side select gate line SGL is connected to the source-side select gate electrode SG (described later with reference to FIG. 25B) of the source-side select transistor ST, and the word line WL is connected to the memory gate electrode MG of the memory transistor MT. The assist gate line AGL is connected to the assist gate electrode AG shared among the drain-side select transistor DT, the memory transistor MT, and the source-side select transistor ST.

FIG. 25B illustrates an example of a cross-sectional configuration of the memory cell Cc illustrated in FIG. 25A in plan view. The memory cell Cc is formed in a region between the bit line BL and the source line SL extending in parallel in the column direction X. The memory cell C includes a drain diffusion layer 7 extending in the column direction X in contact with the bit line BL and a source diffusion layer 6 extending in the column direction X in contact with the source line SL. The source diffusion layer 6 and the drain diffusion layer 7 are n⁺-type diffusion layers made of polycrystalline silicon or the like and having a high impurity concentration, for example.

In the memory cell Cc, a semiconductor layer 17 made of polycrystalline silicon or the like is provided in a region between the drain diffusion layer 7 and the source diffusion layer 6 running in parallel. The semiconductor layer 17 is in contact with a side surface of the drain diffusion layer 7 and a side surface of the source diffusion layer 6. The semiconductor layer 17 provided between the drain diffusion layer 7 and the source diffusion layer 6 running in parallel includes a memory gate structure 10, a drain-side select gate structure 11, and a source-side select gate structure 12 so as to penetrate the semiconductor layer 17.

The memory gate structure 10, the drain-side select gate structure 11, and the source-side select gate structure 12 according to the present embodiment are each formed in a pillar shape with a circular cross section. The memory gate structure 10 is arranged between the drain-side select gate structure 11 and the source-side select gate structure 12, so that the memory gate structure 10, the drain-side select gate structure 11, and the source-side select gate structure 12 are linearly arranged. The detailed configurations of the memory gate structure 10, the drain-side select gate structure 11, and the source-side select gate structure 12 are similar to those of the first embodiment, and thus description thereof will be omitted.

In the present embodiment, wall-shaped assist gate insulating layers 45 are formed so as to run in parallel in the row direction Y between the drain diffusion layer 7 and the source diffusion layer 6 that run in parallel along the column direction X, and a semiconductor layer 17 surrounding the memory gate structure 10, the drain-side select gate structure 11, and the source-side select gate structure 12 is provided between the assist gate insulating layers 45 that run in parallel. As described above, the assist gate insulating layers 45 that run in parallel are formed so as to sandwich the semiconductor layer 17 in the column direction X. Here, the assist gate insulating layers 45 each have one end in contact with the drain diffusion layer 7 and the other end in contact with the source diffusion layer 6, and are provided between the drain diffusion layer 7 and the source diffusion layer 6. The assist gate insulating layers 45 each have one side surface in contact with the side surface of the semiconductor layer 17 extending in the row direction Y, and have the other side surface in contact with the side surface of the assist gate electrode AG. As a result, the assist gate insulating layers 45 insulate the semiconductor layer 17 and the assist gate electrodes AG, and electrically separates the assist gate electrodes AG and the semiconductor layer 17.

The assist gate electrodes AG are formed in a wall shape, and are formed so as to run in parallel in the row direction Y between the drain diffusion layer 7 and the source diffusion layer 6 running in parallel along the column direction X. The semiconductor layer 17 and the assist gate insulating layer 45 surrounding the memory gate structure 10, the drain-side select gate structure 11, and the source-side select gate structure 12 are provided between the assist gate electrodes AG running in parallel. Here, the assist gate electrodes AG are arranged to face the drain-side select gate structure 11, the memory gate structure 10, and the source-side select gate structure 12 with the assist gate insulating layer 45 and the semiconductor layer 17 interposed therebetween in the column direction X. In the present embodiment, in the column direction X, one end of each assist gate electrode AG is arranged in a region facing the source-side select gate electrode SG with the semiconductor layer 17 and the assist gate insulating layer 45 interposed therebetween, and the other end of each assist gate electrode AG is arranged in a region facing the drain-side select gate electrode DG with the semiconductor layer 17 and the assist gate insulating layer 45 interposed therebetween. An assist gate insulating layer 46 is formed between one end of each assist gate electrode AG and the source diffusion layer 6 and between the other end of each assist gate electrode AG and the drain diffusion layer 7.

As a result, each assist gate electrode AG is insulated from the source diffusion layer 6 and the drain diffusion layer 7 by the assist gate insulating layer 46, and is electrically separated from the source diffusion layer 6 and the drain diffusion layer 7. Further, one assist gate line AGL provided so as to run in parallel with the source line SL and the bit line BL is electrically connected to the assist gate electrodes AG running in parallel.

In FIG. 25B, each assist gate insulating layer 45a is an assist gate insulating layer in contact with the semiconductor layer of another memory cell (not illustrated) adjacent to the memory cell Cc in the column direction X. The assist gate insulating layer 45a has the same configuration as the assist gate insulating layer 45 described above, and insulates the semiconductor layer and the assist gate electrode AG of another memory cell (not illustrated) adjacent to the memory cell Cc in the column direction X to electrically separate the assist gate electrode AG and the semiconductor layer.

In the present embodiment, as illustrated in FIG. 25B, one and the other assist gate electrodes AG are arranged so as to run in parallel along the row direction Y in plan view, and the semiconductor layer 17 surrounding the memory gate structure 10, the drain-side select gate structure 11, and the source-side select gate structure 12 and the assist gate insulating layers 45 are sandwiched between the assist gate electrodes AG running in parallel, but the present invention is not limited thereto. For example, in plan view, only one assist gate electrode AG of one and the other assist gate electrodes AG may be arranged along the row direction Y, and the semiconductor layer 17 and the assist gate insulating layer 45 may not be sandwiched between the assist gate electrodes AG.

### (2-3) Configuration of Memory Array

Next, in the memory array CA in which the above-described memory cells Cc are arranged in a matrix, a cross-sectional configuration of the plurality of memory cells Cc arranged in the column direction X will be described. Referring to FIG. 24, in order to briefly describe the configuration of the equivalent circuit of the memory array CAc, the description has been given focusing on the configuration of the equivalent circuit without focusing on the physical arrangement position of each unit. Hereinafter, the description will be given focusing on the physical arrangement position of each unit in the memory cell Cc actually manufactured.

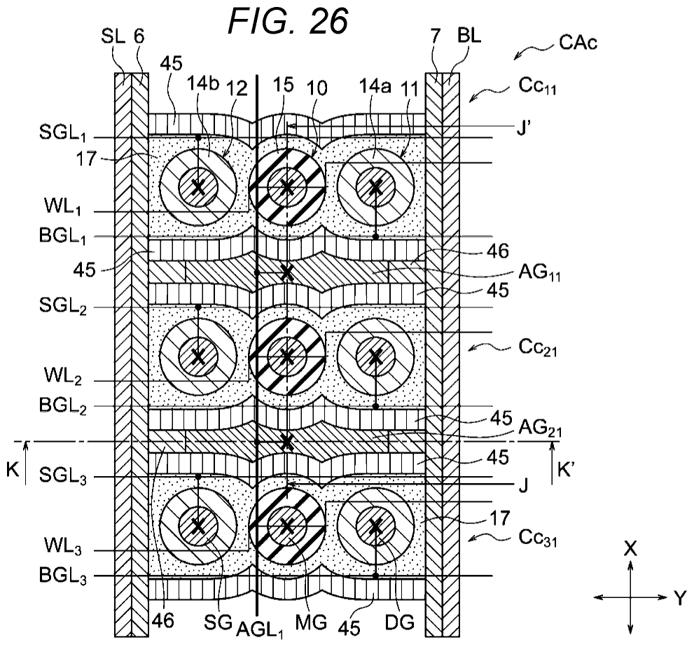

FIG. 26 is a cross-sectional view illustrating a cross-sectional configuration of the plurality of memory arrays CAc arranged along the column direction X in plan view. In FIG. 26, the assist gate insulating layers 45a illustrated in FIG. 25B are simply referred to as assist gate insulating layers 45.

In FIG. 26, the vertical direction indicates the column direction X, and the lateral direction indicates the row direction Y. For example, FIG. 26 illustrates a configuration in which the memory cells Cc are arranged in three rows and one column in the first layer. In FIG. 26, the memory cells Cc in the first row and first column, the second row and first column, and the third row and first column are referred to as memory cells Cc₁₁, Cc₂₁, and Cc₃₁, respectively. In FIG. 26, one assist gate electrode AG arranged between the memory cell Cc₁₁ and the memory cell Cc₂₁ is referred to as assist gate electrode AG₁₁, and the other assist gate electrode AG arranged between the memory cell Cc₂₁ and the memory cell Cc₃₁ is referred to as assist gate electrode AG₂₁.

FIG. 24 is a circuit diagram focusing on a configuration of the equivalent circuit of the memory array CAc, and FIG. 26 illustrates an example of arrangement of each unit of the memory array CAc manufactured. FIG. 26 illustrates the memory cells Cc₁₁, Cc₂₁, and Cc₃₁ and the assist gate electrodes AG₁₁ and AG₂₁ arranged in the first column among the memory cells Cc arranged in a matrix of the memory array CAc. Although not illustrated in FIG. 26, similarly to the first embodiment, the memory cells Cc₁₁, Cc₂₁, and Cc₃₁ and the assist gate electrodes AG₁₁ and AG₂₁ arranged in the first column, and the memory cells Cc₁₂, Cc₂₂, and Cc₃₂ and the assist gate electrodes AG₁₂ and AG₂₂ arranged in the second column (not illustrated) are formed symmetrically, and a bit line BL in the first column and a bit line BL in the second column (not illustrated) are arranged adjacent to each other with the insulating layer 19 interposed therebetween (see FIG. 3).

Here, the second embodiment is different from the first embodiment described above in that the assist gate electrodes AG₁₁ and AG₂₁ are provided between the source diffusion layer 6 in contact with the side surface of the source line SL and the drain diffusion layer 7 in contact with the side surface of the bit line BL, and that the assist gate line AGL₁ is electrically connected to the assist gate electrodes AG₁₁ and AG₂₁. Hereinafter, description of the same configuration as that of the first embodiment will be omitted, and description will be made mainly focusing on the differences from the first embodiment.

In a region between the source diffusion layer 6 and the drain diffusion layer 7 that run in parallel along the column direction X, the memory cells Cc₁₁, Cc₂₁, and Cc₃₁ are arranged along the column direction X, an assist gate electrode AG₁₁ is formed between the memory cells Cc₁₁ and Cc₂₁, and an assist gate electrode AG₂₁ is formed between the memory cells Cc₂₁ and Cc₃₁. Here, since the side surfaces of the assist gate electrodes AG₁₁ and AG₂₁ are formed in a curved shape along the outer shapes of the side surfaces of the memory gate structure 10, drain-side select gate structure 11, and source-side select gate structure 12 each having a circular cross section in plan view, the formation regions of the assist gate electrodes AG₁₁ and AG₂₁ can be increased by the convex shapes on the side surfaces of the assist gate electrodes AG₁₁ and AG₂₁.

In addition, since the assist gate electrodes AG₁₁ and AG₂₁ are formed in a shape along the concave portion of the side surface of the semiconductor layer 17 with the assist gate insulating layer 45 interposed therebetween, an electric field generated by a voltage applied to the assist gate electrodes AG₁₁ and AG₂₁ can be substantially uniformly applied to the semiconductor layer 17.

Further, the side surfaces of the semiconductor layers 17 of the memory cells Cc₁₁, Cc₂₁, and Cc₃₁ are in contact with the side surfaces of the source diffusion layer 6 and the drain diffusion layer 7. Accordingly, the memory cells Cc₁₁, Cc₂₁, and Cc₃₁ in the same column share the source line SL, the bit line BL, the source diffusion layer 6, and the drain diffusion layer 7.

In addition, the assist gate insulating layer 45 is provided between the semiconductor layers 17 of the memory cells Cc₁₁, Cc₂₁, and Cc₃₁ and the assist gate electrodes AG₁₁ and AG₂₁. Further, the assist gate insulating layer 46 is provided between the assist gate electrodes AG₁₁ and AG₂₁ and the source diffusion layer 6, and between the assist gate electrodes AG₁₁ and AG₂₁ and the drain diffusion layer 7. As a result, the assist gate electrodes AG₁₁ and AG₂₁ are electrically separated from the semiconductor layers 17 by the assist gate insulating layers 45, and are electrically separated from the source diffusion layer 6 and the drain diffusion layer 7 by the assist gate insulating layers 46.

In the second embodiment, similarly to the first embodiment, drain-side select gate lines BGL₁, BGL₂, and BGL₃, source-side select gate lines SGL₁, SGL₂, and SGL₃, and word lines WL₁ and WL₂ are extended in the row direction Y, and assist gate lines AGL₁ are extended in the column direction X. The assist gate lines AGL₁ are connected to the assist gate electrodes AG₁₁ and AG₂₁ in the first column arranged in the same column, and are shared by the assist gate electrodes AG₁₁ and AG₂₁ in the same column.

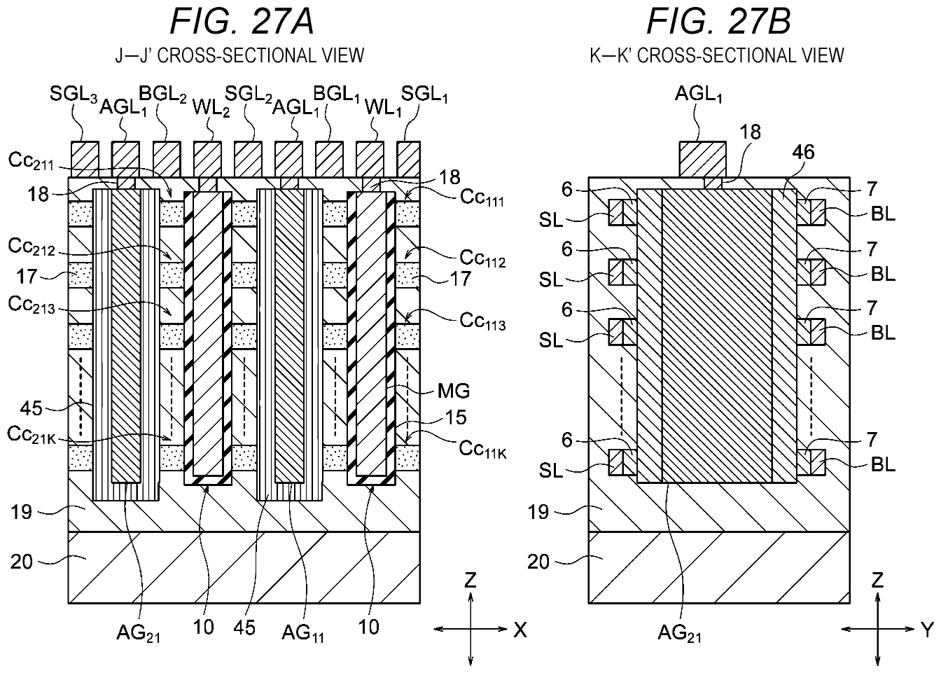

Here, FIG. 27A illustrates a cross-sectional configuration of a J-J′ portion in FIG. 26, and FIG. 27B illustrates a cross-sectional configuration of a K-K′ portion in FIG. 26. FIG. 27A illustrates a longitudinal cross-sectional configuration in the vertical direction Z at positions where the memory gate structure 10 shared among memory cells Cc₁₁₁, Cc₁₁₂, Cc₁₁₃, . . . , and Cc₁₁ₖ at the corresponding levels in the first row and the memory gate structure 10 shared among the memory cells C₁₂₁, C₁₂₂, C₁₂₃, . . . , and C₁₂ₖ at the corresponding levels in the second row, and the assist gate electrodes AG₁₁ and AG₂₁ are arranged. FIG. 27B illustrates a longitudinal cross-sectional configuration in the vertical direction Z of the assist gate electrode AG₂₁ arranged between the memory cell Cc₂₁ in the second row and the memory cell Cc₃₁ in the third row arranged in the column direction X.

As illustrated in FIG. 27A, similarly to the first embodiment, on the substrate 20, the pillar-shaped memory gate structures 10 are disposed with the insulating layer 19 as an interlayer insulating film interposed therebetween, and for example, the memory cells Cc₁₁₁, Cc₁₁₂, Cc₁₁₃, . . . , and Cc₁₁ₖ at the first level to the k-th level arranged in the vertical direction Z are formed at predetermined intervals along the memory gate structures 10. In the second embodiment, similarly to the first embodiment, one memory gate structure 10 is shared among the plurality of memory cells Cc₁₁₁, Cc₁₁₂, Cc₁₁₃, . . . , and Cc₁₁ₖ arranged in the vertical direction Z. The drain-side select gate structure 11 and the source-side select gate structure 12 (not illustrated) also have the same configuration as that of the first embodiment illustrated in FIG. 4, and are shared among the plurality of memory cells Cc₁₁₁, Cc₁₁₂, Cc₁₁₃, . . . , and Cc₁₁ₖ arranged in the vertical direction Z. The vertical cross-sectional configurations of the drain-side select gate structure 11 and source-side select gate structure 12 are the same as those of the first embodiment, and thus, description thereof is omitted here.

As illustrated in FIGS. 27A and 27B, the assist gate electrodes AG₁₁ and AG₂₁ extend in the vertical direction Z to the surface of the substrate 20, and also extend in the row direction Y, and are formed in a wall shape. In addition, the assist gate insulating layer 45 is formed on the side surfaces and bottom surfaces of the assist gate electrodes AG₁₁ and AG₂₁. In this case, the assist gate electrode AG₁₁ extends in the vertical direction Z so as to separate the memory cells Cc₁₂₁, Cc₁₂₂, Cc₁₂₃, . . . , and Cc₁₂ₖ at the corresponding levels in the first row arranged in the vertical direction Z from the memory cells Cc₂₁₁, Cc₂₁₂, Cc₂₁₃, . . . and Cc₂₁ₖ at the corresponding levels in the second row arranged in the vertical direction Z. As a result, the memory cells Cc₁₂₁, Cc₁₂₂, Cc₁₂₃, . . . , and Cc₁₂ₖ at the corresponding levels in the first row and the memory cells Cc₂₁₁, Cc₂₁₂, Cc₂₁₃, . . . , and Cc₂₁ₖ at the corresponding levels in the second row share one assist gate electrode AG₁₁. The assist gate lines AGL₁ are connected to the upper ends of the assist gate electrodes AG₁₁ and AG₂₁ with contacts 18 interposed therebetween, and the same voltage is uniformly applied to the assist gate electrodes AG₁₁ and AG₂₁ via the assist gate lines AGL₁.

Here, as illustrated in FIG. 27B, the assist gate insulating layers 46 formed at both ends in the row direction Y of the assist gate electrode AG₂₁ extend in the vertical direction Z as described above, and are in contact with the side surfaces of the source diffusion layer 6 and the side surfaces of the drain diffusion layer 7 at each level extended in the column direction X (FIG. 26). As described above, the assist gate electrode AG₂₁ is electrically separated from the source diffusion layer 6 and the drain diffusion layer 7 provided at each level by the assist gate insulating layers 46.

### (2-4) Configuration of Another Embodiment of Memory Cell

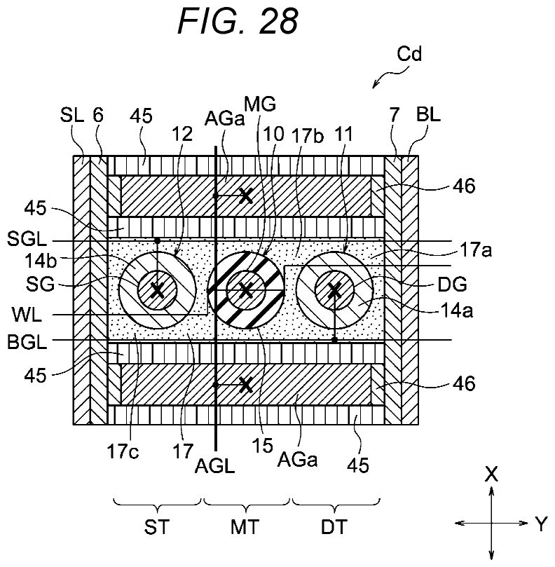

In the second embodiment described above, the assist gate electrodes AG having the shape with the side surfaces partially curved along the curved side surfaces of the memory gate structure 10, drain-side select gate structure 11, and source-side select gate structure 12 are applied. However, the present invention is not limited thereto, and assist gate electrodes having various shapes may be applied. FIG. 28 is a cross-sectional view of a memory cell Cd provided with assist gate electrodes AGa of another example in plan view. In this example, the assist gate electrodes AGa are formed in a rectangular cross-sectional shape in plan view. Hereinafter, description of the same configuration as the configuration of the memory cell Cc illustrated in FIG. 25B will be omitted, and description will be given focusing on the differences from the configuration illustrated in FIG. 25B.

In this case, the outer shape of the semiconductor layer 17 surrounding the memory gate structure 10, the drain-side select gate structure 11, and the source-side select gate structure 12 in plan view is formed with a rectangular cross section, and the assist gate insulating layers 45 are formed along the side surfaces of the semiconductor layer 17 linearly extending along the row direction Y. The assist gate electrodes AGa having a rectangular cross section in plan view and extending in the row direction Y in the longitudinal direction are provided on the side surfaces of the assist gate insulating layers 45. The assist gate insulating layer 46 having a quadrilateral cross section in plan view is provided between one end (side surface) of the assist gate electrode AGa in the row direction Y and the source diffusion layer 6 and between the other end (side surface) of the assist gate electrode AGa in the row direction Y and the drain diffusion layer 7.

### (2-5) Data Program Operation

Next, a data program operation in the memory cell Cc illustrated in FIGS. 25A and 25B will be described. To program data to the memory cell Cc illustrated in FIGS. 25A and 25B, for example, a source voltage V_{SL} of 1 V is applied to the source line SL, and a source-side gate voltage V_{SGS} smaller than a threshold voltage Vt of the source-side select transistor ST is applied to the source-side select gate electrode SG, thereby to turn off the source-side select transistor ST.

At this time, a program bit voltage V_{BL} of 0 V (hereinafter, also referred to as program selected bit voltage) is applied to the bit line BL by programming, and a drain-side gate voltage V_{SGD} larger than the threshold voltage Vt of the drain-side select transistor DT is applied to the drain-side select gate electrode DG, thereby to turn on the drain-side select transistor DT.

Furthermore, for example, when a high voltage program memory gate voltage V_{CG0}) of 10 V (program selection memory gate voltage) to the memory gate electrode MG, in the memory cell Cc, the semiconductor layer 17 in the vicinity of the outer periphery of the memory gate structure 10 has the same potential as the program selected bit voltage V_{BL0} as illustrated in FIG. 25B. As a result, in the memory cell Cc, electric charges move from the semiconductor layer 17 and/or the memory gate electrode MG to the charge storage layer 15b included in the multilayer insulating layer 15 of the memory gate structure 10, so that data is programed.

In the second embodiment, as in the first embodiment described above, in the multilayer insulating layer 15 including the charge storage layer 15b, when a distance ta in the plane direction of the first memory gate insulating layer 15a is longer than a distance tc in the plane direction of the second memory gate insulating layer 15c (that is, ta>tc), electric charges move from the semiconductor layer 17 to the charge storage layer 15b around the outer periphery of the second memory gate insulating layer 15c. On the other hand, when the distance ta in the plane direction of the first memory gate insulating layer 15a is shorter than the distance tc in the plane direction of the second memory gate insulating layer 15c (that is, ta<tc), electric charges move from the memory gate electrode MG to the charge storage layer 15b.

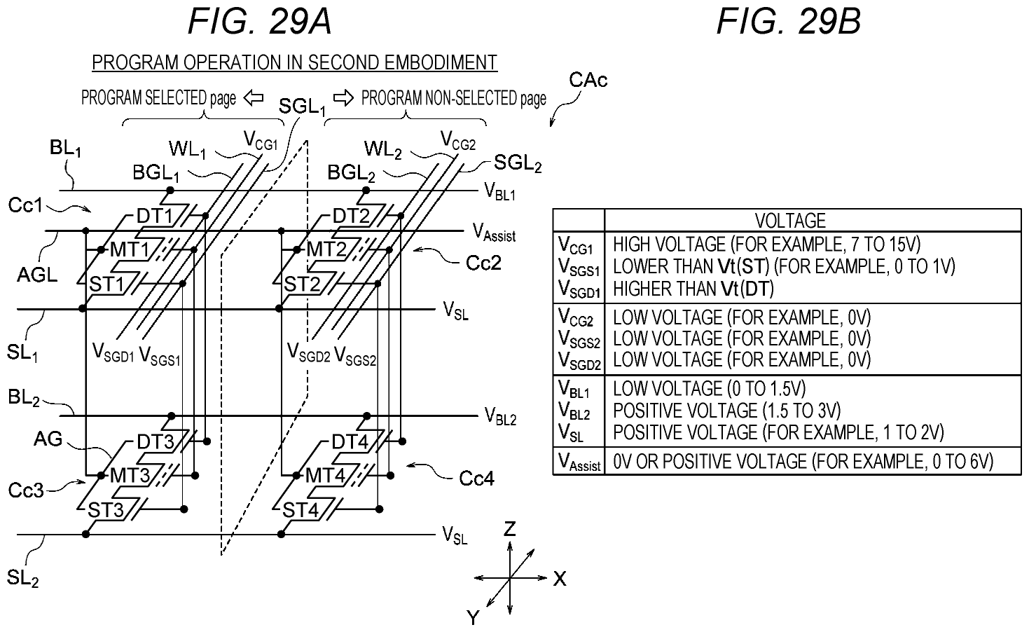

Next, as illustrated in FIG. 29A, the data program operation in the memory array CAc will be described using, as an example, the memory array CAc in which two memory cells Cc1 and Cc2 are arranged along the column direction X at the first level that is the upper layer, two memory cells Cc3 and Cc4 are similarly arranged along the column direction X in the layer under the first level, one page is constituted by the memory cells Cc1 and Cc3 arranged in the vertical direction Z, and the other page is constituted by the memory cells Cc2 and Cc4 arranged in the vertical direction Z.

Here, a case where data is programed using the memory cell Cc1, among the memory cells Cc1, Cc2, Cc3, and Cc4, as the selected memory cell Cc1 will be described. In this case, the page including the selected memory cell Cc1 to which data is programed is set as a program selected page, and the page including only the unselected memory cells Cc2 and Cc4 to which data is not programed is set as a program unselected page.

In a case of not particularly distinguishing the memory transistors MT1, MT2, MT3, and MT4, the drain-side select transistors DT1, DT2, DT3, and DT4, and the source-side select transistors ST1, ST2, ST3, and ST4, they will be simply referred to as memory transistor MT, drain-side select transistor DT, and source-side select transistor ST.

FIG. 29B illustrates an example of voltages of components in the memory array CAc in this case. The assist gate voltage V_{Assist} (for example, a positive voltage of 0 to 6 V) is applied to the assist gate line AGL connected to the memory cells Cc1, Cc2, Cc3, and Cc4. As a result, a predetermined voltage is applied to the semiconductor layers 17 of the memory cells Cc1, Cc2, Cc3, and Cc4.

In the memory array CAc, a program selected bit voltage V_{BL1} (for example, a low voltage of 0 to 1.5 V) is applied to the bit line BL₁ to be the selected bit line connected to the selected memory cell Cc1. A program selected drain-side gate voltage V_{SGD1} higher than the threshold voltage Vt of the drain-side select transistor DT1 (preferably a positive voltage, also referred to as Vt(DT)) is applied to the drain-side select gate line BGL₁ connected to the selected memory cell Cc1. As a result, in the selected memory cell Cc1, the drain-side select transistor DT1 is turned on, and the program selected bit voltage V_{BL1} is transmitted to the memory transistor MT1.

As a result, in the unselected memory cell Cc3 in the program selected page in which data is not programed, the same voltage as that of the selected memory cell Cc1 is applied from the drain-side select gate line BGL₁ to the drain-side select gate electrode DG of the drain-side select transistor DT3, which is shared with the selected memory cell Cc1. However, the program unselected bit voltage V_{BL2} is applied to the bit line BL₂ to be the unselected bit line, so that the drain-side select transistor DT3 is turned off.

In the memory array CAc, a positive voltage (for example, 1 to 2 V) is uniformly applied to the source lines SL. A program selected gate voltage V_{SGS1} lower than the threshold voltage Vt of the source-side select transistor ST1 (preferably a positive voltage, also referred to as Vt(ST)) is applied to the source-side select gate line SGL₁ connected to the selected memory cell Cc1. As a result, in the selected memory cell Cc1, the source-side select transistor ST1 is turned off.

In addition, a program selected memory gate voltage V_{CG1} (for example, a high voltage of 7 to 15 V) is applied to the word line WL₁ connected to the selected memory cell Cc1. As a result, in the selected memory cell Cc1, the potential of the memory gate electrode MG becomes high due to the program selected memory gate voltage V_{CG1} of the word line WL₁, and as in the first embodiment, for example, when ta (distance in the plane direction of the first memory gate insulating layer 15a)>tc (distance in the plane direction of the second memory gate insulating layer 15c), electrons move from the semiconductor layer 17 to the charge storage layer 15b, or holes move from the charge storage layer 15b to the semiconductor layer 17, so that data is programed. As a result, the threshold voltage of the memory transistor MT1 of the selected memory cell Cc1 increases. On the other hand, in a case of ta<tc, electrons escape from the charge storage layer 15b to the memory gate electrode MG, or holes move from the memory gate electrode MG to the charge storage layer 15b. As a result, the threshold voltage of the memory transistor MT1 of the selected memory cell Cc1 decreases.

At this time, a program unselected bit voltage V_{BL2} is applied to the other bit line BL₂ which is an unselected bit line not connected to the selected memory cell Cc1. The program unselected bit voltage V_{BL2} is desirably a positive voltage (for example, 1.5 to 3 V).

As a result, in the unselected memory cell Cc3 in the program selected page in which data is not programed, the same voltage as that of the selected memory cell Cc1 is applied from the drain-side select gate line BGL₁ to the drain-side select gate electrode DG of the drain-side select transistor DT3, which is shared with the selected memory cell Cc1. However, the program unselected bit voltage V_{BL2} is applied to the bit line BL₂ to be the unselected bit line, so that the drain-side select transistor DT3 is turned off.

In the program selected page, the unselected memory cell Cc3 shares the drain-side select gate line BGL₁, the word line WL₁, and the source-side select gate line SGL₁ with the selected memory cell Cc1. However, the drain-side select transistor DT3 and the source-side select transistor ST3 of the unselected memory cell Cc3 are turned off. Accordingly, in the unselected memory cell Cc3, even when the program selection memory gate voltage V_{CG1} (for example, a high voltage of 7 to 15 V) is applied from the word line WL₁ to the memory gate electrode MG, the potential of the semiconductor layer 17 around the memory transistor MT3 increases, so that the potential difference from the program selection memory gate voltage V_{CG1} decreases. Therefore, in the unselected memory cell Cc3, the tunnel current does not flow into the charge storage layer 15b of the memory transistor MT3, so that it is possible to block movement of electric charges to the charge storage layer 15b and prevent data programming.

Although FIG. 29A does not illustrate the unselected memory cells (that is, the memory cell arranged on the back side or front side of plane of the drawing with respect to the memory cells Cc1 and Cc3) arranged in other columns in the program selected page, the unselected memory cells also share the drain-side select gate line BGL₁, the word line WL₁, and the source-side select gate line SGL₁ with the selected memory cell Cc1. However, similarly to the unselected memory cell Cc3, applying the same voltages as the bit line BL₂ and the source line SL₂ to the bit line BL and the source line SL, respectively, makes it possible to turn off the drain-side select transistor DT and the source-side select transistor ST, thereby to prevent data programming. In addition, at this time, since the assist gate voltage V_{Assist} is applied from the assist gate line AGL in these unselected memory cells, the potential of the semiconductor layer 17 in the vicinity of the word line WL₁ also changes depending on the assist gate voltage V_{Assist}. When the assist gate voltage V_{Assist} is increased, the potential of the semiconductor layer 17 increases, and the potential difference between the semiconductor layer 17 and the word line WL₁ decreases. Accordingly, data programming can be more effectively prevented.

Next, a program unselected page including only the unselected memory cells Cc2 and Cc4 will be described. In this case, since the bit lines BL₁ and BL₂ and the source lines SL₁ and SL₂ connected to the unselected memory cells Cc2 and Cc4 are shared with the memory cells Cc1 and Cc3 in the program selected page, the description thereof is omitted here, and a drain-side select gate line BGL₂, the word line WL₂, and a source-side select gate line SGL₂ will be described.

In the program unselected page, a program unselected drain-side gate voltage V_{SGD2}, a program unselected memory gate voltage V_{CG2}, and a program unselected source-side gate voltage V_{SGS2}, which have a low potential (for example, 0 V), are applied to the drain-side select gate line BGL₂, the word line WL₂, and the source-side select gate line SGL₂, respectively. As a result, in the unselected memory cells Cc2 and Cc4 of the program unselected page, the drain-side select transistors DT2 and DT4 and the source-side select transistors ST2 and ST4 are turned off at both ends of the memory transistors MT2 and MT4, respectively, so that no tunnel current flows into the charge storage layer 15b of the memory transistors MT2 and MT4, movement of electric charges into the charge storage layer 15b can be blocked to prevent data programming.

In addition, similarly to the above case, at this time, the positive assist gate voltage V_{Assist} is also applied from the assist gate line AGL to the unselected memory cells Cc2 and Cc4 of the program unselected page, so that the potential of the semiconductor layer 17 in the vicinity of the gates of the drain-side select transistors DT2 and DT4 and the source-side select transistors ST2 and ST4 rises. Therefore, even in the unselected page, the drain-side select transistors DT2 and DT4 and the source-side select transistors ST2 and ST4 can be reliably turned off. In the memory transistors MT of the unselected memory cells Cc2, Cc3, and Cc4, movement of electric charges to the charge storage layer 15b is blocked, and thus, the threshold voltage does not change.

In this manner, in the memory array CAc, it is possible to prevent data programming to the unselected memory cells Cc2, Cc3, and Cc4 and to program data only to the selected memory cell Cc1.

### (2-6) Data Erase Operation

Next, a data erase operation in the memory cell Cc illustrated in FIGS. 25A and 25B will be described. In the case of erasing the data from the memory cell Cc illustrated in FIGS. 25A and 25B, for example, a source voltage V_{SL}, which is a positive high voltage (for example, 7 to 12 V), is applied to the source line SL, and an erase selected source-side gate voltage V_{SGS} identical to the bit voltage V_{BL} is applied to the source-side select gate line SGL connected to source-side select gate electrode SG of source-side select transistor ST.

Similarly, the bit voltage V_{BL}, which is a positive high voltage (for example, 7 to 12 V), is applied to the bit line BL, and the erase selected drain-side gate voltage V_{SGD} identical to the bit voltage V_{BL} is applied to the drain-side select gate line BGL connected to the drain-side select gate electrode DG of the drain-side select transistor DT. As a result, the potential of the semiconductor layer 17 on the drain-side of the source-side select transistor ST becomes V_{SGS}−Vₜ. Similarly, the potential of the semiconductor layer 17 on the drain-side of the drain-side select transistor DT becomes V_{SGD}−Vₜ.

Further, the assist gate voltage V_{Assist}, which is a positive high voltage (for example, 7 to 12 V) is applied to the assist gate line AGL. As a result, the potential of the semiconductor layer 17 in the vicinity of the assist gate electrode AG increases, and becomes substantially uniform in the vicinity of the semiconductor layer 17 of the memory transistor MT.

Further, an erase selected memory gate voltage V_{CG1}, which is a voltage of a negative value to 0 V (for example, −5 to 0 V), is applied to the word line WL connected to the memory gate electrode MG of the memory transistor MT. As a result, a potential difference is generated between the memory gate electrode MG of the memory transistor MT and the semiconductor layer 17, electric charges move from the charge storage layer 15b, whereby the data is erased. At this time, in the second embodiment, since the potential of the semiconductor layer 17 is increased by the assist gate voltage V_{Assist}, the difference from the negative potential of the memory gate electrode MG increases, and the electrons in the charge storage layer 15b move at a higher speed (Channel current induced mode).

In the second embodiment, similarly to the first embodiment described above, in the multilayer insulating layer 15 including the charge storage layer 15b, when the distance ta in the plane direction of the first memory gate insulating layer 15a is longer than the distance tc in the plane direction of the second memory gate insulating layer 15c (that is, ta>tc), electrons move from the inside of the charge storage layer 15b toward the semiconductor layer 17 or holes move from the semiconductor layer 17 to the charge storage layer 15b during the data erase operation. As a result, the threshold of the memory transistor MT decreases. On the other hand, when the distance ta in the plane direction of the first memory gate insulating layer 15a is smaller than the distance tc in the plane direction of the second memory gate insulating layer 15c (That is, ta<tc), electrons move from the charge storage layer 15b to the memory gate electrode MG, or holes move from the memory gate electrode MG to the charge storage layer 15b. As a result, the threshold of the memory transistor MT increases.

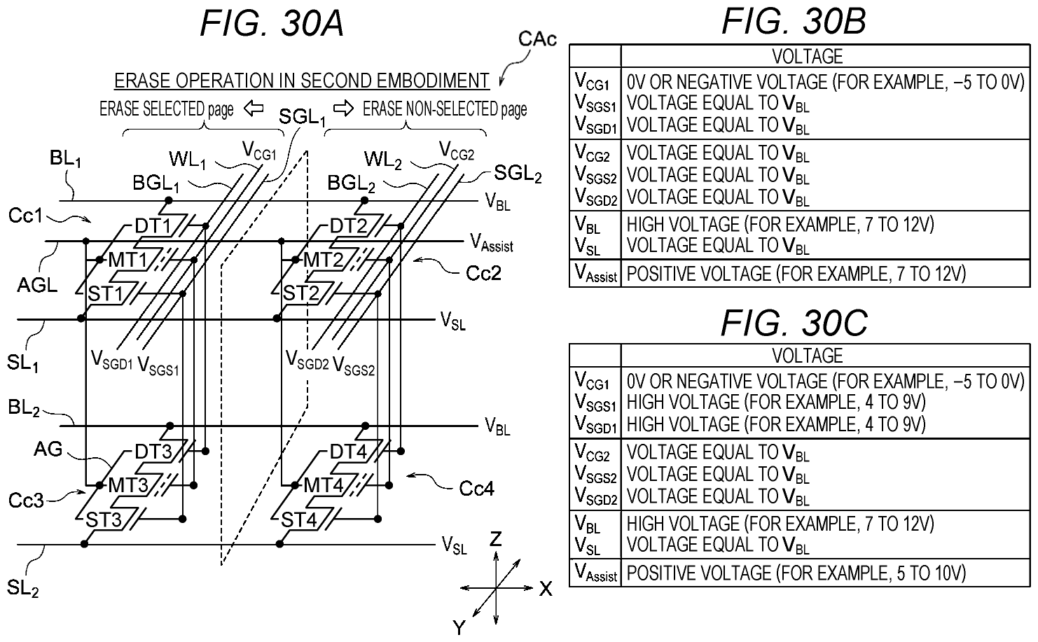

Next, as in “(2-5) Data Program Operation” described above, the data erase operation in the memory array CAc will be described by exemplifying the memory array CAc in which one page is constituted by the memory cells Cc1 and Cc3 arranged in the vertical direction Z and another one page is constituted by the memory cells Cc2 and Cc4 arranged in the vertical direction Z as illustrated in FIG. 30A.

Here, a case where data is erased in units of pages, data is erased for pages configured by the memory cells Cc1 and Cc3, and data is not erased for pages configured by the memory cells Cc2 and Cc4 will be described. In this case, the page from which to erase data is designated as an erase selected page, and the page constituted by only the unselected memory cells Cc2 and Cc4 from which data is not to be erased is designated as a program unselected page. The threshold voltages Vt of the drain-side select transistors DT and the source-side select transistors ST of the memory cells Cc1, Cc2, Cc3, and Cc4 are desirably positive values.

FIG. 30B illustrates an example of voltages of components in the memory array CAc in this case. The assist gate voltage V_{Assist}, which is a positive high voltage (for example, 7 to 12 V), is applied to the assist gate line AGL connected to the memory cells Cc1, Cc2, Cc3, and Cc4. As a result, a predetermined voltage is applied to the semiconductor layers 17 of the memory cells Cc1, Cc2, Cc3, and Cc4.

In the memory array CAc, an erase bit voltage V_{BL} (for example, a high voltage of 7 to 12 V) is applied to the bit lines BL₁ and BL₂ shared between the erase selected page and the erase unselected page, and the source voltage V_{SL} having the same voltage as the erase bit voltage V_{BL} (for example, a high voltage of 7 to 12 V) is applied to the source lines SL₁ and SL₂.

In the erase selected page, for example, an erase selected drain-side gate voltage V_{SGD1}, which is a high voltage of 7 to 12 V that is the same as the erase bit voltage V_{BL}, is applied to the drain-side select gate line BGL₁, and similarly, an erase selected source-side gate voltage V_{SGS1}, which is a high voltage of 7 to 12 V that is the same as the erase bit voltage V_{BL}, is applied to the source-side select gate line SGL₁. In addition, in the erase selected page, an erase selection memory gate voltage V_{CG1}, which is a voltage of a negative value to 0 (for example, −5 to 0 V), is applied to the word line WL₁. As a result, in the erase selected page, in each of the memory cells Cc1 and Cc3, a potential difference is generated between the memory gate electrode MG and the semiconductor layer 17 around the memory gate electrode MG, charge is moved from the charge storage layer 15b, and data is erased.

FIG. 30C illustrates an example of voltages of individual parts in a data erase operation according to another embodiment. In this case, the assist gate voltage V_{Assist}, which is a positive high voltage (for example, 5 to 10 V), is applied to the assist gate line AGL connected to the memory cells Cc1, Cc2, Cc3, and Cc4. As a result, a predetermined voltage is applied to the semiconductor layers 17 of the memory cells Cc1, Cc2, Cc3, and Cc4.

Also in this case, the memory array CAc, an erase bit voltage V_{BL} (for example, a high voltage of 7 to 12 V) is applied to the bit lines BL₁ and BL₂ shared between the erase selected page and the erase unselected page, and the source voltage V_{SL} having the same voltage as the erase bit voltage V_{BL} (for example, a high voltage of 7 to 12 V) is applied to the source lines SL₁ and SL₂.

In the erase selected page, for example, a positive erase selected drain-side gate voltage V_{SGD1} of 4 to 9 V is applied to the drain-side select gate line BGL₁, and similarly, a positive erase selected source-side gate voltage V_{SGS1} of 4 to 9 V is applied to the source-side select gate line SGL₁. As a result, in the erase selected page, in each of the memory cells Cc1 and Cc3, a potential difference is generated between the memory gate electrode MG and the semiconductor layer 17 around the memory gate electrode MG, charge is moved from the charge storage layer 15b, and data is erased.

In the erase unselected page, the same erase bit voltage V_{BL} (for example, a high voltage of 7 to 12 V) as that of the bit lines BL₁ and BL₂ is applied as the erase unselected drain-side gate voltage V_{SGD2}, the erase unselected source-side gate voltage V_{SGS2}, and the erase unselected memory gate voltage V_{CG2} to the drain-side select gate line BGL₂, the source-side select gate line SGL₂, and the word line WL₂. As a result, in the erase unselected page, in each of the memory cells Cc2 and Cc4, no potential difference occurs between the memory gate electrode MG and the semiconductor layer 17 around the memory gate electrode MG, electrical charges do not move from the charge storage layer 15b, and data can be prevented from being erased.

In the second embodiment, the potential of the semiconductor layer 17 in the vicinity of the memory gate electrode MG increases by applying the positive assist gate voltage V_{Assist} to the memory cells Cc1, Cc2, Cc3, and Cc4 during the data erase operation. Therefore, the potential difference from the erase unselected memory gate voltage V_{CG2} becomes small, and the erasure of data can be more effectively suppressed as compared with the case where the assist gate voltage V_{Assist} is not applied.

In the embodiment described above, data is erased page by page, but the present invention is not limited thereto. Alternatively, all the pages may be set as erase selected pages and data of all the memory cells Cc constituting the memory array CAc may be collectively erased.

### (2-7) Data Read Operation

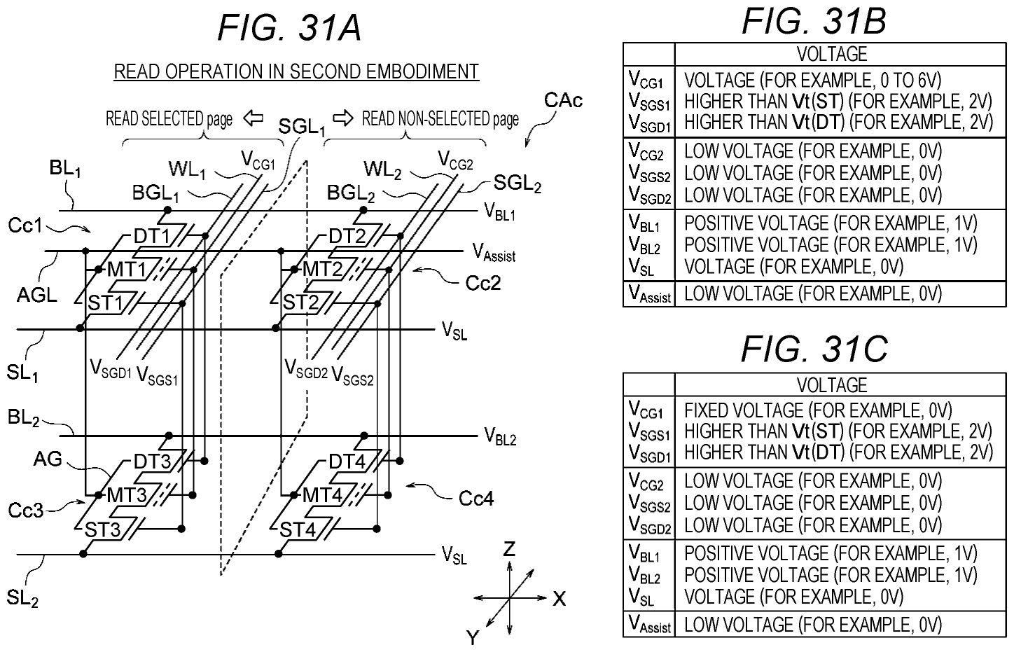

Next, a data read operation in the memory array CAc will be described. Herein, as in “(2-4) Data Program Operation” described above, the data read operation in the memory array CAc will be described by exemplifying the memory array CAc in which one page is constituted by the memory cells Cc1 and Cc3 arranged in the vertical direction Z and another one page is constituted by the memory cells Cc2 and Cc4 arranged in the vertical direction Z as illustrated in FIG. 31A.

Herein, a case where data is read with the memory cells Cc1 and Cc3, among the memory cells Cc1, Cc2, Cc3, and Cc4, as the selected memory cells Cc1 and Cc3 will be described, for example. In this case, the page including the selected memory cells Cc1 and Cc3 from which to read data is set as a read selected page, and the page including only the unselected memory cells Cc2 and Cc4 from which data is not to be read is set as a read unselected page.

FIG. 31B illustrates an example of voltages of components in the memory array CAc in this case. In this case, the assist gate voltage V_{Assist}, which is a low voltage (for example, 0 V), is applied to the assist gate line AGL connected to the memory cells Cc1, Cc2, Cc3, and Cc4. In the memory array CAc, read bit voltages V_{BL1} and V_{BL2} (they are the same positive voltage, for example, 1 V) are applied to the bit lines BL₁ and BL₂ shared between the read selected page and the read unselected page, respectively, and a read source voltage V_{SL} (the source lines SL have the same voltage, for example, 0 V) is applied to the source line SL.

In the read selected page, for example, a voltage (for example, 2 V) higher than the threshold voltage Vt(DT) of the drain-side select transistor DT1 is applied to the drain-side select gate line BGL₁ as read selected drain-side gate voltage V_{SGD1}, and similarly, a voltage (for example, 2 V) higher than the threshold voltage Vt(ST) of the source-side select transistor ST1 is applied to the source-side select gate line SGL₁ as the read selected source-side gate voltage V_{SGS1}. As a result, the drain-side select transistor DT1 and the source-side select transistor ST1 of the selected memory cell Cc1 are turned on. At this time, the potential of the semiconductor layer 17 in the vicinity of the assist gate electrode AG is lowered by applying the assist gate voltage V_{Assist}, which is a low voltage (for example, 0 V), so that the leakage current from the source line SL₁ to the bit line BL₁ in the vicinity of the assist gate electrode AG can be suppressed.

Further, in the read selected page, for example, a read selected memory gate voltage V_{CG1} of 0 to 6 V is applied to the word line WL₁. Accordingly, in the selected memory cell Cc1, when data is not programed in the memory transistor MT1 and the threshold voltage Vt of the memory transistor MT1 is lower than the read selected memory gate voltage V_{CG1}, a current flows from the source line SL₁ to the bit line BL₁, and the potential of the bit line BL₁ changes.

On the other hand, when data is programed in the memory transistor MT1 of the selected memory cell Cc1 and the threshold voltage Vt of the memory transistor MT1 is higher than the read selected memory gate voltage V_{CG1}, no current flows from the source line SL₁ to the bit line BL₁, and the potential of the bit line BL₁ does not change. The data of the selected memory cell Cc1 can be read by detecting such a change in the potential of the bit line BL₁ by the column decoder 2b (FIG. 1). At this time, the data of the other selected memory cells Cc3 in the read selected page can be similarly read by detecting a change in the potential of the bit line BL₂ by the column decoder 2b (FIG. 1).

In the read unselected page, for example, a voltage (for example, 0 V) lower than the threshold voltage Vt of the drain-side select transistor DT2 is applied to the drain-side select gate line BGL₂ as read unselected drain-side gate voltage V_{SGD2}, and similarly, a voltage (for example, 0 V) lower than the threshold voltage Vt of the source-side select transistor ST2 is applied to the source-side select gate line SGL₂ as the read unselected source-side gate voltage V_{SGS2}.

As a result, the drain-side select transistors DT and the source-side select transistors ST of the unselected memory cells Cc2 and Cc4 of the read unselected page are turned off, and no current flows from the source lines SL₁ and SL₂ to the bit lines BL₁ and BL₂. As described above, data can be read only from the selected memory cells Cc₁ and Cc3 of the read selected page.

When multi-value data is detected in one memory cell Cc, a fine threshold voltage of the memory transistor MT can be detected and multi-value data can be read by changing the value of the read selected memory gate voltage V_{CG1} in the read selected page and detecting a change in the potential of the bit line BL₁ at each voltage value.

FIG. 31C illustrates an example of voltages of individual parts in a data read operation according to another embodiment. Also in this case, an assist gate voltage V_{Assist}, which is a low voltage (for example, 0 V), is applied to an assist gate line AGL connected to memory cells Cc1, Cc2, Cc3, and Cc4. In this case, in a read selected page, a read selected memory gate voltage V_{CG1} (for example, 0 V) is applied to a word line WL₁ as a fixed voltage. At this time, if the threshold voltage of a memory transistor MT1 in the selected memory cell Cc1 is lower than the read selected memory gate voltage V_{CG1}, a current flows from the source line SL₁ to the bit line BL₁. At this time, the potential of the semiconductor layer 17 in the vicinity of the assist gate electrode AG is lowered by applying the assist gate voltage V_{Assist}, which is a low voltage (for example, 0 V), so that the leakage current from the source line SL₁ to the bit line BL₁ in the vicinity of the assist gate electrode AG can be suppressed.

The cell current flowing from the source line SL₁ to the bit line BL₁ via the selected memory cell Cc1 is determined by the value of a threshold difference (V_{CG1}−Vt) between the read selected memory gate voltage V_{CG1} and the threshold voltage Vt of memory transistors MT1 and MT3. The magnitude of the cell current flowing from the source line SL₁ to the bit line BL₁ via the selected memory cell Cc1 is detected by the column decoder 2b, the threshold voltage Vt of the memory transistors MT1 and MT3 is determined in the column decoder 2b, and whether data is programed in the memory transistors MT1 and MT3 is determined.

Also in this case, the data programed in the memory transistors MT1 and MT3 can be classified according to the value of the cell current flowing from the source line SL₁ to the bit line BL₁ via the selected memory cell Cc1, and multi-valued data can be read. A read unselected page is the same as that illustrated in FIG. 31B described above, and thus description thereof will be omitted here.

### (2-8) Specific Examples of Voltages in Data Program Operation, Erase Operation, and Read Operation

Table 4 below shows specific examples (voltage examples) of combinations of voltages at data program operation, erase operation (Junction current induced mode and Channel current induced mode), and read operation in the second embodiment described above. The unit of the voltage values shown in Table 4 is “V”.

In Table 4, “BL column” indicates a column of a memory cell Cc group electrically connected to the bit line BL extended from the column decoder 2b in the column direction X. In the second embodiment, similarly to the configuration in FIG. 1, the column decoder 2b is two-dimensionally arranged in the row direction Y which is the depth direction of the plane and the vertical direction z in the drawing, and there are two types of the BL columns in the row direction Y which is the depth direction in plane and the vertical direction Z. Therefore, strictly speaking, these can also be defined. However, in order to simplify the description, Table 4 does not particularly distinguish between the row direction Y which is the depth direction in the drawing and the vertical direction Z, and arranges operations focusing on the selected page and the unselected page indicated in FIGS. 29A, 30A, and 31A.

TABLE 4

| | | | Operation | | | | | |
|---|---|---|---|---|---|---|---|---|
| | | | Read | | Program | | Erase 1 | Erase 2 |
| | | | Selected | Unselected | Selected | Unselected | Channel | Junction |
| | | | BL | BL | BL | BL | current | current |
| | | | column | column | column | column | induced | induced |
| V_{CG} | Selected | V_{CG1} | 0 | 0 | 10 | 10 | −3 | −3 |
| | page | | | | | | | |
| | Unselected | V_{CG2} | 0 | 0 | 0 | 0 | 10 | 10 |
| | page | | | | | | | |
| V_{SGS} | Selected | V_{SGS1} | 1 | 1 | 0 | 0 | 10 | 7 |
| | page | | | | | | | |
| | Unselected | V_{SGS2} | 0 | 0 | 0 | 0 | 10 | 10 |
| | page | | | | | | | |
| V_{SGD} | Selected | V_{SGD1} | 1 | 1 | 1 | 1 | 10 | 7 |
| | page | | | | | | | |
| | Unselected | V_{SGD2} | 0 | 0 | 0 | 0 | 10 | 10 |
| | page | | | | | | | |
| V_{BL} | | | 1 | 0 | 0 | 1 | 10 | 10 |
| V_{SL} | | | 0 | 0 | 1 | 1 | 10 | 10 |
| V_{AG} | | | 0 | 0 | 5 | 5 | 10 | 10 |

In the non-volatile semiconductor memory device 1, applying voltages as shown in Table 4 above makes it possible to adjust the voltages page by page in the memory array CAc and to selectively program, erase, and read data to and from a predetermined memory cell Cc.

### (2-9) Method of Manufacturing Memory Array According to Second Embodiment

Next, a method of manufacturing the memory array according to the second embodiment including the assist gate electrode AG illustrated in FIG. 26 will be described. In the method of manufacturing the memory array according to the second embodiment, a step of manufacturing the assist gate electrode AG is added to the method of manufacturing the first embodiment described above. In the method of manufacturing the memory array according to the second embodiment, for example, similarly to the manufacturing method in the first embodiment, the memory array in which the assist gate electrode AG is not formed is manufactured according to FIGS. 12 to 22C.

Next, as illustrated in FIGS. 22B and 22C, for example, in order to form the assist gate electrode AG between the memory cell formation regions 28b and 28c, a new mask layer (not illustrated) patterned with a resist material or the like is formed on the memory gate structure 10a, the drain-side select gate structure 11a, the source-side select gate structure 12a, the existing mask layer 27, and the like. In the new mask layer, an opening is formed in accordance with a region where the assist gate electrode AG is to be formed (hereinafter, referred to as assist gate electrode formation region) between the memory cell formation regions 28b and 28c.

Next, using the new mask layer as a mask, the insulating layer 19 as an interlayer insulating film exposed from the opening is etched in the vertical direction Z by dry etching, thereby to form a hole for forming an assist gate electrode in the insulating layer 19. At this time, as illustrated in FIG. 26, for example, the insulating layer 19 is left as the assist gate insulating layers 45 and 46 between the memory cells Cc₁₁, Cc₂₁, and Cc₃₁ adjacent in the column direction X, thereby to form a hole for forming an assist gate electrode is formed.

Next, the assist gate electrode AG is formed by depositing a gate material such as low-resistance polycrystalline silicon or metal such as tungsten inside the hole for forming an assist gate electrode surrounded by the assist gate insulating layers 45 and 46 formed in the above step.

As for a method of manufacturing the memory array Cd illustrated in FIG. 28, a manufacturing method in a third embodiment to be described later can be used, and thus description thereof will be omitted here.

As described above, the memory cell in the second embodiment including the assist gate electrode AG can be manufactured by adding the step of forming the assist gate electrode AG to the manufacturing step of the memory array CA in the first embodiment. The order of the above-described steps of manufacturing step is not limited to the above-described order.

### (2-10) Operations and Advantageous Effects

With the above-described configuration, also in the second embodiment, the memory cells Cc are three-dimensionally structured such that the memory transistor MT, the drain-side select transistor DT, and the source-side select transistor ST are connected in series. Since the memory cells Cc are three-dimensionally structured, the memory cells Cc can be integrated and downsized without being restricted by two-dimensional scaling.

In addition, since the memory cell Cc according to the second embodiment is provided with the assist gate electrode AG, the potential of the semiconductor layer 17 can be determined not only by the potentials of the source diffusion layer 6, drain diffusion layer 7, source-side select gate electrode SG, memory gate electrode MG, and drain-side select gate electrode DG but also by the potential of the assist gate electrode AG.

During the data program operation, as described above, the potential of the semiconductor layer 17 can be increased by applying the assist gate voltage V_{Assist}, which is a positive voltage (for example, 1 V), to the assist gate electrode AG. As a result, in the program selected page, since the potential difference between the source-side gate voltage V_{SGS1} and the semiconductor layer 17 becomes small, the source-side select transistors ST1 and ST3 can be reliably turned off, thereby suppressing the leakage current. Also in the program unselected page, setting the potential of the semiconductor layer 17 to a potential relatively higher than the potentials of the source-side gate voltage V_{SGS2} and drain-side gate voltage V_{SGD2}, makes it possible to reliably turn off the drain-side select transistors DT2 and DT4 and the source-side select transistors ST2 and ST4, whereby suppressing the leak current.

During the data erase operation, as described above, the potential of the semiconductor layer 17 can be increased by applying the assist gate voltage V_{Assist}, which is a positive voltage (for example, 7 to 12 V), to the assist gate electrode AG. As a result, in the erase selected page, the difference between the memory gate voltage V_{CG1}, which is a negative voltage (for example, −5 to 0 V), and the potential of the semiconductor layer 17 becomes large, so that the data can be erased more effectively. Also in the erasure unselected page, setting the potential of the semiconductor layer 17 to a potential relatively higher than or equal to the memory gate voltage V_{CG2} (for example, 7 to 12 V), the potential difference from the memory gate voltage V_{CG2} becomes small, and thus the erasure of data can be suppressed more effectively.

During the data read operation, as described above, the potential of the semiconductor layer 17 can be decreased by applying the assist gate voltage V_{Assist}, which is a constant voltage (for example, 0 V), to the assist gate electrode AG. As a result, the potential difference between the potential of the semiconductor layer 17 and the read selected drain-side gate voltage V_{SGD1} can be maintained at a potential difference larger than the threshold voltage Vt(DT) of the drain-side select transistor DT1. In addition, the potential difference between the potential of the semiconductor layer 17 and the read selected source-side gate voltage V_{SGS1} can be maintained at a potential difference larger than the threshold voltage Vt(ST) of the source-side select transistor ST1. As a result, it is possible to suppress a leakage current from the source line SL₁ to the bit line BL₁ in the vicinity of the assist gate electrode AG.

Furthermore, in the memory cell Cc of the second embodiment, as described above, since the side surface of the assist gate electrode AG is formed in a curved surface shape along the shape of side surfaces of the memory gate structure 10, drain-side select gate structure 11, and source-side select gate structure 12 having a circular cross section in plan view, it is possible to substantially uniformly apply an electric field to the semiconductor layer 17 surrounding the memory gate structure 10, the drain-side select gate structure 11, and the source-side select gate structure 12. As a result, the potential of the semiconductor layer 17 can be more accurately controlled based on the voltage of the assist gate voltage V_{Assist}.

### (3) Third Embodiment

(3-1) Configuration of Equivalent Circuit of Non-volatile Semiconductor Memory Device according to Third Embodiment

In the second embodiment described above, the memory cell Cc has one assist gate electrode AG shared among the drain-side select transistor DT, the memory transistor MT, and the source-side select transistor ST. However, the present invention is not limited thereto. A memory cell may be applied in which independent assist gate electrodes are provided for the drain-side select transistor DT, the memory transistor MT, and the source-side select transistor ST. Hereinafter, a memory cell in which independent assist gate electrodes are provided for the drain-side select transistor DT, the memory transistor MT, and the source-side select transistor ST will be described as a third embodiment.

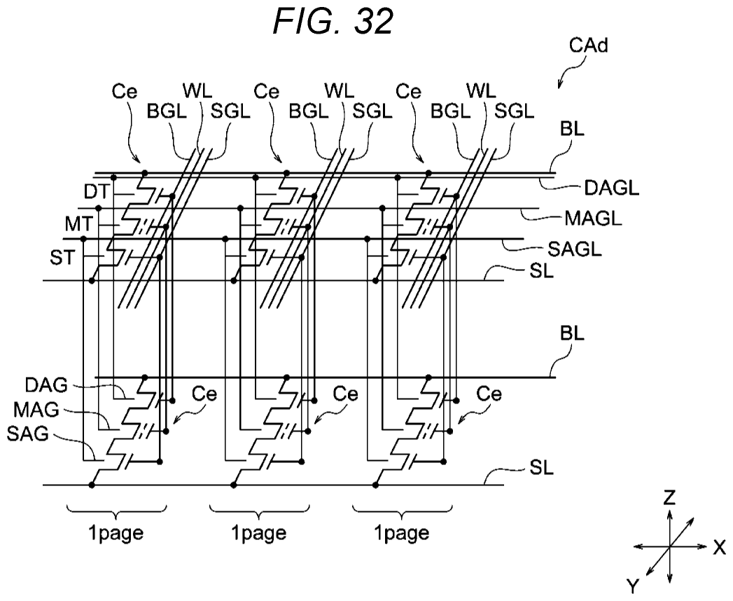

FIG. 32 is a schematic diagram illustrating a configuration of an equivalent circuit focusing on a memory array CAd provided in a non-volatile semiconductor memory device according to the third embodiment. The memory array CAd according to the third embodiment is different from the memory array CA according to the first embodiment illustrated in FIG. 1 in that a drain-side assist gate line DAGL, a memory-side assist gate line MAGL, a source-side assist gate line SAGL, a drain-side assist gate electrode DAG, a memory-side assist gate electrode MAG, and a source-side assist gate electrode SAG are provided. Since the other components are the same as those of the non-volatile semiconductor memory device 1 in the first embodiment described above, the following description will focus on the differences from the first embodiment.

The drain-side assist gate line DAGL extends in the column direction X so as to run in parallel with bit lines BL and the source lines SL extending in the column direction X, and is connected to drain-side assist gate electrodes DAG of a plurality of memory cells Ce arranged in the same row including different levels. That is, the plurality of memory cells Ce arranged in the same column direction X including different levels share the one drain-side assist gate line DAGL. Each drain-side assist gate line DAGL provided for each column including different levels is connected to a column decoder 2b not illustrated.

The memory-side assist gate line MAGL extends in the column direction X so as to run in parallel with bit lines BL and the source lines SL extending in the column direction X, and is connected to memory-side assist gate electrodes MAG of a plurality of memory cells Ce arranged in the same row including different levels. That is, the plurality of memory cells Ce arranged in the same column direction X including different levels share the one memory-side assist gate line MAGL. Each memory-side assist gate line MAGL provided for each column including different levels is connected to a column decoder 2b not illustrated.

The source-side assist gate line SAGL extends in the column direction X so as to run in parallel with bit lines BL and the source lines SL extending in the column direction X, and is connected to source-side assist gate electrodes SAG of a plurality of memory cells Ce arranged in the same row including different levels. That is, the plurality of memory cells Ce arranged in the same column direction X including different levels share the one source-side assist gate line SAGL. Each source-side assist gate line SAGL provided for each column including different levels is connected to a column decoder 2b not illustrated.

Since the bit lines BL, the source lines SL, the drain-side select gate lines BGL, the source-side select gate lines SGL, and the word lines WL are provided in the same configuration as that of the first embodiment, description thereof is omitted here.

In the memory cell Ce, the voltages of the bit line BL, source line SL, drain-side select gate line BGL, source-side select gate line SGL, word line WL, drain-side assist gate line DAGL, memory-side assist gate line MAGL, and source-side assist gate line SAGL connected thereto are controlled by a row decoder 2a and the column decoder 2b not illustrated, so that programming of data, erasing of data, and reading of data are performed on the memory transistor MT. Details of a data program operation, an erase operation, and a read operation in the non-volatile semiconductor memory device according to the third embodiment will be described later.

In the memory array CAd according to the present embodiment, the plurality of memory cells Ce arranged in a matrix at each layer in an XY plane is identical in arrangement configuration. Thus, when it is not necessary to distinguish by level, the following description will be mainly given focusing on the arrangement configuration of the plurality of memory cells Ce arranged at the first level that is the upper layer.

The memory cell Ce is different from the memory cell C according to the first embodiment illustrated in FIG. 1 in that the drain-side assist gate electrode DAG, the memory-side assist gate electrode MAG, and the source-side assist gate electrode SAG are provided. The memory cells Ce have the same configuration in which the drain-side assist gate electrode DAG is provided for the drain-side select transistor DT, the memory-side assist gate electrode MAG is provided for the memory transistor MT, and the source-side assist gate electrode SAG is provided for the source-side select transistor ST.

### (3-2) Configuration of Memory Cell

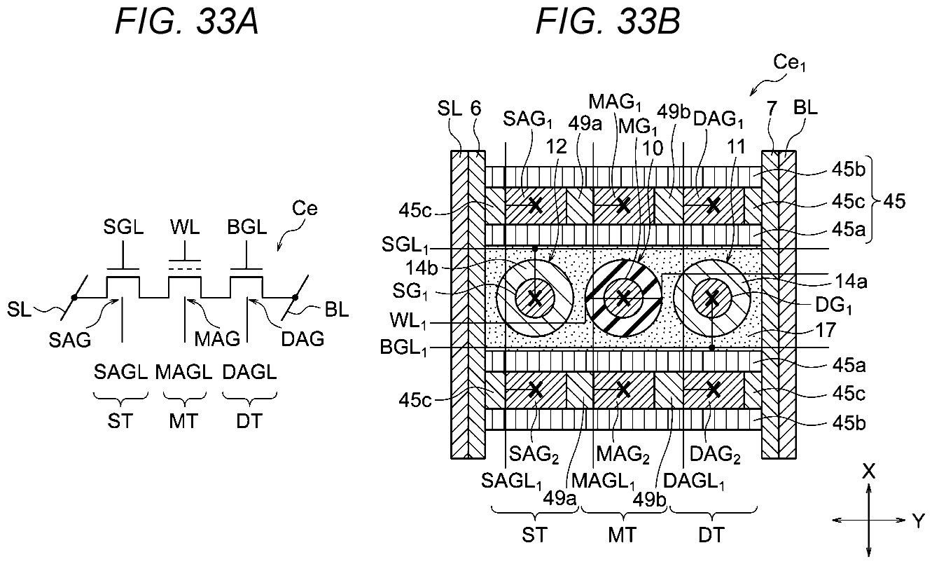

Next, the configuration of the memory cell Ce will be described. Here, duplicated description of the same configuration as that of the second embodiment will be omitted, and the following description will focus on the differences. FIG. 33A is a circuit diagram illustrating a configuration of an equivalent circuit of the memory cell Ce. As illustrated in FIG. 33A, the drain-side assist gate line DAGL is connected to the drain-side assist gate electrode DAG of the drain-side select transistor DT, the memory-side assist gate line MAGL is connected to the memory-side assist gate electrode MAG, and the source-side assist gate line SAGL is connected to the source-side assist gate electrode SAG.

FIG. 33B illustrates an example of a cross-sectional configuration of the memory cell Ce illustrated in FIG. 33A in plan view. Here, description will be given focusing on one memory cell Ce among the memory cells Ce. The memory cell Ce is different from the memory cell Cd according to the second embodiment illustrated in FIG. 28 in that a source-side assist gate electrode SAG₁ (SAG₂), a memory-side assist gate electrode MAG₁ (MAG₂), and a drain-side assist gate electrode DAG₁ (DAG₂) are provided between parallel assist gate insulating layers 45a and 45b linearly extending in the row direction Y between a drain diffusion layer 7 and a source diffusion layer 6 parallel to each other in the column direction X.

In the present embodiment, the source-side assist gate electrode SAG₁, the memory-side assist gate electrode MAG₁, and the drain-side assist gate electrode DAG₁ arranged on one side and the source-side assist gate electrode SAG₂, the memory-side assist gate electrode MAG₂, and the drain-side assist gate electrode DAG₂ arranged on the other side are arranged symmetrically with respect to the source-side select gate structure 12, the memory gate structure 10, and the drain-side select gate structure 11. Since the source-side assist gate electrode SAG₁, the memory-side assist gate electrode MAG₁, and the drain-side assist gate electrode DAG₁ arranged on one side and the source-side assist gate electrode SAG₂, the memory-side assist gate electrode MAG₂, and the drain-side assist gate electrode DAG₂ arranged on the other side have the same configuration, the description will be mainly given focusing on the source-side assist gate electrode SAG₁, the memory-side assist gate electrode MAG₁, and the drain-side assist gate electrode DAG₁ arranged on one side.

In this case, the assist gate insulating layer 45a has one side surface extending in the row direction Y in contact with the side surface of the semiconductor layer 17, and has the other side surface extending in the row direction Y in contact with the side surfaces of the source-side assist gate electrode SAG₁, the memory-side assist gate electrode MAG₁, and the drain-side assist gate electrode DAG₁. As a result, the assist gate insulating layer 45a electrically separates the semiconductor layer 17 from the source-side assist gate electrode SAG₁, the memory-side assist gate electrode MAG₁, and the drain-side assist gate electrode DAG₁.

The drain-side assist gate electrode DAG₁, the memory-side assist gate electrode MAG₁, and the source-side assist gate electrode SAG₁ are formed in a pillar shape having a rectangular cross section in plan view, and are linearly arranged along the row direction Y between the drain diffusion layer 7 and the source diffusion layer 6 that run in parallel along the column direction X. The drain-side assist gate electrode DAG₁ is arranged to face the drain-side select gate structure 11 with the assist gate insulating layer 45a and the semiconductor layer 17 interposed therebetween in the column direction X. The memory-side assist gate electrode MAG₁ is arranged to face the memory gate structure 10 with the assist gate insulating layer 45a and the semiconductor layer 17 interposed therebetween in the column direction X. The source-side assist gate electrode SAG₁ is arranged to face the source-side select gate structure 12 with the assist gate insulating layer 45a and the semiconductor layer 17 interposed therebetween in the column direction X.

More specifically, the source-side assist gate electrode SAG₁ is arranged in a region facing the source-side select gate electrode SG in source-side select gate structure 12 with the semiconductor layer 17 and the assist gate insulating layer 45a interposed therebetween. The memory-side assist gate electrode MAG₁ is arranged in a region facing the memory gate electrode MG in the memory gate structure 10 with the semiconductor layer 17 and the assist gate insulating layer 45a interposed therebetween. The drain-side assist gate electrode DAG₁ is arranged in a region facing the drain-side select gate electrode DG in drain-side select gate structure 11 with the semiconductor layer 17 and the assist gate insulating layer 45a interposed therebetween.

An assist gate insulating layer 45c is provided between the source-side assist gate electrode SAG₁ (SAG₂) and the source diffusion layer 6, and an assist gate insulating layer 45c is also provided between the drain-side assist gate electrode DAG₁ (DAG₂) and the drain diffusion layer 7. As a result, the drain-side assist gate electrode DAG₁ (DAG₂) is electrically separated from the drain diffusion layer 7 by the assist gate insulating layer 45c. The source-side assist gate electrode SAG₁ (SAG₂) is electrically separated from the source diffusion layer 6 by the assist gate insulating layer 45c.

Further, assist gate insulating layers 49a and 49b are provided between the memory-side assist gate electrode MAG₁ (MAG₂) and the source-side assist gate electrode SAG₁ (SAG₂), and between the memory-side assist gate electrode MAG₁ (MAG₂) and the drain-side assist gate electrode DAG₁ (DAG₂). As a result, the memory-side assist gate electrode MAG₁ (MAG₂), the source-side assist gate electrode SAG₁ (SAG₂), and the drain-side assist gate electrode DAG₁ (DAG₂) are electrically separated from each other by the assist gate insulating layers 49a and 49b.

Further, one drain-side assist gate line DAGL₁ provided so as to run in parallel with the source line SL and the bit line BL is electrically connected to the drain-side assist gate electrodes DAG₁ and DAG₂, one memory-side assist gate line MAGL₁ provided so as to run in parallel with the source line SL and the bit line BL is electrically connected to the memory-side assist gate electrodes MAG₁ and MAG₂, and one source-side assist gate line SAGL₁ provided so as to run in parallel with the source line SL and the bit line BL is electrically connected to the source-side assist gate electrodes SAG₁ and SAG₂.

The assist gate insulating layer 45b is in contact with a semiconductor layer of another memory cell (not illustrated) adjacent to the memory cell Ce in the column direction X. For example, the assist gate insulating layer 45b positioned at the upper side in FIG. 33B electrically separates the semiconductor layer 17 of another memory cell (not illustrated) adjacent to the memory cell Ce at the upper side in the column direction X from the drain-side assist gate electrode DAG₁, the memory-side assist gate electrode MAG₁, and the source-side assist gate electrode SAG₁.

The assist gate insulating layers 45a, 45b, and 45c formed so as to surround the source-side assist gate electrode SAG₁ (SAG₂), the memory-side assist gate electrode MAG₁ (MAG₂), and the drain-side assist gate electrode DAG₁ (DAG₂) are manufactured as an integrated assist gate insulating layer 45 in manufacturing.

As illustrated in FIG. 33B, one side surface of the semiconductor layer 17 of the memory cell Ce is in contact with the source diffusion layer 6, and the other side surface is in contact with the side surface of the drain diffusion layer 7. The source line SL, the bit line BL, the source diffusion layer 6, and the drain diffusion layer 7 are shared among the memory cells Ce in the same column.

Furthermore, as illustrated in FIG. 33B, the drain-side assist gate line DAGL₁ is connected to and shared between the drain-side assist gate electrodes DAG₁ and DAG₂ arranged in the same column. The memory-side assist gate line MAGL₁ is connected to and shared between the memory-side assist gate electrodes MAG₁ and MAG₂ arranged in the same column. The source-side assist gate line SAGL₁ is connected to and shared between the source-side assist gate electrodes SAG₁ and SAG₂ arranged in the same column.

In the third embodiment, the drain-side select gate line BGL₁, the source-side select gate line SGL₁, and the word line WL₁ are extended in the row direction Y, and the drain-side assist gate line DAGL₁, the memory-side assist gate line MAGL₁, and the source-side assist gate line SAGL₁ are extended in the column direction X.

In the present embodiment, as illustrated in FIG. 33B, in plan view, the memory gate structure 10, the drain-side select gate structure 11, and the source-side select gate structure 12 are arranged between one drain-side assist gate electrode DAG₁, memory-side assist gate electrode MAG₁, and source-side assist gate electrode SAG₁ linearly arranged along the row direction Y and the other drain-side assist gate electrode DAG₂, memory-side assist gate electrode MAG₂, and source-side assist gate electrode SAG₂ linearly arranged along the row direction Y. However, the present invention is not limited thereto. For example, in plan view, only one drain-side assist gate electrode DAG₁, memory-side assist gate electrode MAG₁, and source-side assist gate electrode SAG₁ may be arranged without providing the other drain-side assist gate electrode DAG₂, memory-side assist gate electrode MAG₂, and source-side assist gate electrode SAG₂.

Although illustration of a cross-sectional configuration in plan view in which the plurality of memory cells Ce is arranged in a column along the column direction X is omitted, the assist gate electrodes AG₁₁ and AG₂₁ illustrated in FIG. 26 of the second embodiment are replaced with the drain-side assist gate electrodes DAG₁ and DAG₂, the memory-side assist gate electrodes MAG₁ and MAG₂, and the source-side assist gate electrodes SAG and SAG₂ illustrated in FIG. 33B.

### (3-3) Data Program Operation

Next, a data program operation in the memory cell Ce illustrated in FIG. 33A will be described. To program the data into the memory cell Ce illustrated in FIG. 33A, a source-side assist gate voltage V_{AssistS} of 0 V to 2 V is applied to the source-side assist gate electrode SAG, a drain-side assist gate voltage V_{AssistD} of 0 V is applied to the drain-side assist gate electrode DAG, and a memory-side assist gate voltage V_{AssistM} of 0 V to 8 V is applied to the memory-side assist gate electrode MAG. At this time, for example, a source voltage V_{SL} of 1 V is applied to the source line SL, and a source-side gate voltage V_{SGS} smaller than a threshold voltage Vt of the source-side select transistor ST is applied to the source-side select gate electrode SG, thereby to turn off the source-side select transistor ST.

At this time, a program bit voltage V_{BL} of 0 V (hereinafter, also referred to as program selected bit voltage) is applied to the bit line BL, and a drain-side gate voltage V_{SGD} larger than the threshold voltage Vt of the drain-side select transistor DT is applied to the drain-side select gate electrode DG, thereby to turn on the drain-side select transistor DT.

Furthermore, for example, by applying a high voltage program memory gate voltage V_{CG0} (program selected memory gate voltage) of 10 V to the memory gate electrode MG, in the memory cell Ce, the semiconductor layer 17 in the vicinity of the outer periphery of the memory gate structure 10 has the same potential as the program selected bit voltage V_{BL0} as illustrated in FIG. 33B. As a result, in the memory cell Ce, electric charges move from the semiconductor layer 17 and/or the memory gate electrode MG to the charge storage layer 15b included in the multilayer insulating layer 15 of the memory gate structure 10, so that data is programed.

Also in the third embodiment, as in the first embodiment described above with reference to FIG. 7B, in the multilayer insulating layer 15 including the charge storage layer 15b, when a distance ta in the plane direction of the first memory gate insulating layer 15a is longer than a distance tc in the plane direction of the second memory gate insulating layer 15c (that is, ta>tc), electric charges move from the semiconductor layer 17 to the charge storage layer 15b around the outer periphery of the second memory gate insulating layer 15c. On the other hand, when the distance ta in the plane direction of the first memory gate insulating layer 15a is shorter than the distance tc in the plane direction of the second memory gate insulating layer 15c (that is, ta<tc), electric charges move from the memory gate electrode MG to the charge storage layer 15b.

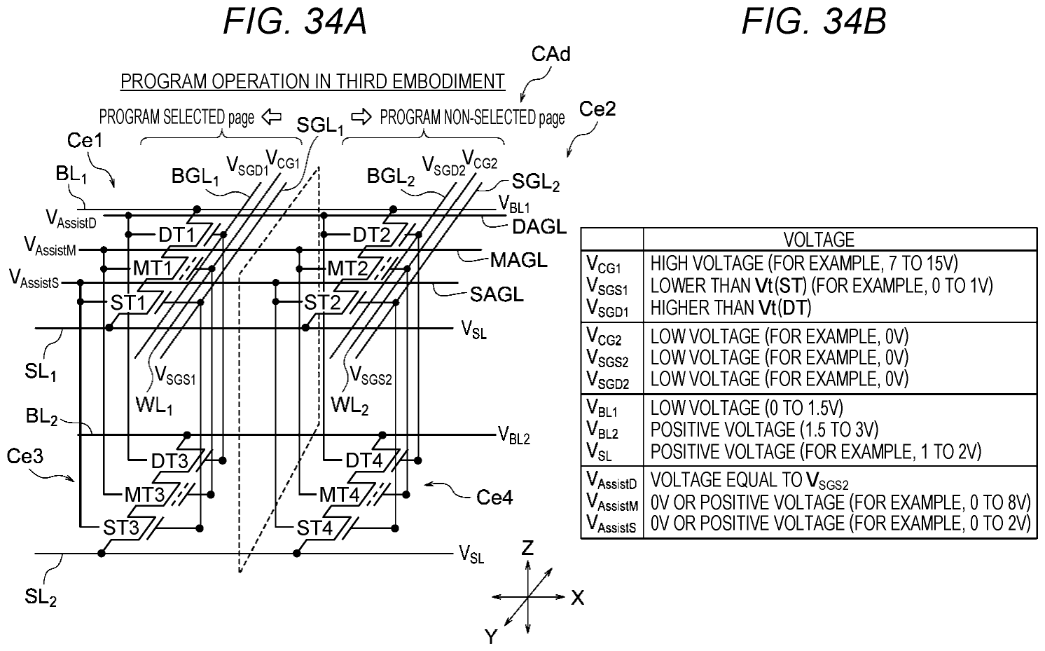

Next, as illustrated in FIG. 34A, the data program operation in the memory array CAd will be described using, as an example, the memory array CAd in which two memory cells Ce1 and Ce2 are arranged along the column direction X in the upper layer, two memory cells Ce3 and Ce4 are similarly arranged along the column direction X in the lower layer, one page is constituted by the memory cells Ce1 and Ce3 arranged in the vertical direction Z, and the other page is constituted by the memory cells Ce2 and Ce4 arranged in the vertical direction Z.

Here, a case where data is programed using the memory cell Ce1 among the memory cells Ce1, Ce2, Ce3, and Ce4 as the selected memory cell Ce1 will be described. In this case, the page including the selected memory cell Ce1 to which data is programed is set as a program selected page, and the page including only the unselected memory cells Ce2 and Ce4 to which data is not programed is set as a program unselected page.

In a case of not particularly distinguishing the memory transistors MT1, MT2, MT3, and MT4, the drain-side select transistors DT1, DT2, DT3, and DT4, and the source-side select transistors ST1, ST2, ST3, and ST4, they will be simply referred to as memory transistor MT, drain-side select transistor DT, and source-side select transistor ST.

FIG. 34B illustrates an example of voltages of components in the memory array CAd in this case. The drain-side assist gate voltage V_{AssistD} (for example, 0 V) that is the same as the unselected source-side gate voltage V_{SGS2} described later is applied to the drain-side assist gate line DAGL connected to the memory cells Ce1, Ce2, Ce3, and Ce4. A memory-side assist gate voltage V_{AssistM} (for example, a positive voltage of 0 V or 0 to 8 V) is applied to the memory-side assist gate line MAGL, and a source-side assist gate voltage V_{AssistS} (for example, a positive voltage of 0 V or 0 to 2 V) is applied to the source-side assist gate line SAGL.

As a result, in the drain-side select transistors DT of the memory cells Ce1, Ce2, Ce3, and Ce4, the drain-side assist gate voltage V_{AssistD} is applied to the semiconductor layer 17 in the vicinity of the drain-side assist gate electrode DAG. In the memory transistors MT of the memory cells Ce1, Ce2, Ce3, and Ce4, the memory-side assist gate voltage V_{AssistM} is applied to the semiconductor layer 17 in the vicinity of the memory-side assist gate electrode MAG. Further, in the source-side select transistors ST of the memory cells Ce1, Ce2, Ce3, and Ce4, the source-side assist gate voltage V_{AssistS} is applied to the semiconductor layer 17 in the vicinity of the source-side assist gate electrode SAG.

In the memory array CAd, a program selected bit voltage V_{BL1} (for example, a low voltage of 0 to 1.5 V) is applied to the bit line BL₁ to be the selected bit line connected to the selected memory cell Ce1. A program selected drain-side gate voltage V_{SGD1} higher than the threshold voltage Vt of the drain-side select transistor DT (preferably a positive voltage, also referred to as Vt(DT)) is applied to the drain-side select gate line BGL₁ connected to the selected memory cell Ce1. As a result, in the selected memory cell Ce1, the drain-side select transistor DT1 is turned on, and the program selected bit voltage V_{BL1} is transmitted to the memory transistor MT1.

In the unselected memory cell Ce3 in the program selected page in which data is not programed, the same voltage as that of the selected memory cell Ce1 is applied from the drain-side select gate line BGL₁ to the drain-side select gate electrode DG of the drain-side select transistor DT3, which is shared with the selected memory cell Ce1. However, the program unselected bit voltage V_{BL2} is applied to the bit line BL₂ to be the unselected bit line, so that the drain-side select transistor DT3 is turned off.

In the memory array CAd, a positive voltage (for example, 1 to 2 V) is uniformly applied to the source lines SL. A program selected gate voltage V_{SGS1} lower than the threshold voltage Vt of the source-side select transistor ST1 (preferably a positive voltage, also referred to as Vt(ST)) is applied to the source-side select gate line SGL₁ connected to the selected memory cell Ce1. As a result, in the selected memory cell Ce1, the source-side select transistor ST1 is turned off.

In addition, a program selected memory gate voltage V_{CG1} (for example, a high voltage of 7 to 15 V) is applied to the word line WL₁ connected to the selected memory cell Ce1. In the selected memory cell Ce1, the potential of the memory gate electrode MG becomes high due to the program selected memory gate voltage V_{CG1} of the word line WL₁, and as in the first embodiment, for example, when ta (distance in the plane direction of the first memory gate insulating layer 15a)>tc (distance in the plane direction of the second memory gate insulating layer 15c), electrons move from the semiconductor layer 17 to the charge storage layer 15b, or holes move from the charge storage layer 15b to the semiconductor layer 17, so that data is programed. As a result, the threshold voltage of the memory transistor MT1 of the selected memory cell Ce1 increases. On the other hand, in a case of ta<tc, electrons escape from the charge storage layer 15b to the memory gate electrode MG, or holes move from the memory gate electrode MG to the charge storage layer 15b. As a result, the threshold voltage of the memory transistor MT1 of the selected memory cell Ce1 decreases.

At this time, a program unselected bit voltage V_{BL2} is applied to the other bit line BL₂ which is an unselected bit line not connected to the selected memory cell Ce1. The program unselected bit voltage V_{BL2} is desirably a positive voltage (for example, 1.5 to 3 V).

As a result, in the unselected memory cell Ce3 in the program selected page in which data is not programed, the same voltage as that of the selected memory cell Ce1 is applied from the drain-side select gate line BGL₁ to the drain-side select gate electrode DG of the drain-side select transistor DT3, which is shared with the selected memory cell Ce1. However, the program unselected bit voltage V_{BL2} is applied to the bit line BL₂ to be the unselected bit line, so that the drain-side select transistor DT3 is turned off.

In the program selected page, the unselected memory cell Ce3 shares the drain-side select gate line BGL₁, the word line WL₁, and the source-side select gate line SGL₁ with the selected memory cell Ce1. However, the drain-side select transistor DT3 and the source-side select transistor ST3 of the unselected memory cell Ce3 are turned off. Accordingly, in the unselected memory cell Ce3, even when the program selection memory gate voltage V_{CG1} (for example, a high voltage of 7 to 15 V) is applied from the word line WL₁ to the memory gate electrode MG, the potential of the semiconductor layer 17 around the memory transistor MT3 increases, so that the potential difference from the program selection memory gate voltage V_{CG1} decreases. Therefore, in the unselected memory cell Ce3, the tunnel current does not flow into the charge storage layer 15b of the memory transistor MT3, so that it is possible to block movement of electric charges to the charge storage layer 15b and prevent data programming.

Although FIG. 34A does not illustrate the unselected memory cells (that is, the memory cell arranged on the back side or front side of plane of the drawing with respect to the memory cells Ce1 and Ce3) arranged in other columns in the program selected page, the unselected memory cells also share the drain-side select gate line BGL₁, the word line WL₁, and the source-side select gate line SGL₁ with the selected memory cell Ce1. However, similarly to the unselected memory cell Ce3, applying the same voltages as the bit line BL₂ and the source line SL₂ to the bit line BL and the source line SL, respectively, makes it possible to turn off the drain-side select transistor DT and the source-side select transistor ST, thereby to prevent data programming.

Similarly to the above case, at this time, the drain-side assist gate voltage V_{AssistD} is applied from the drain-side assist gate line DAGL, the memory-side assist gate voltage V_{AssistM} is applied from the memory-side assist gate line MAGL, and the source-side assist gate voltage V_{AssistS} is applied from the source-side assist gate line SAGL to the unselected memory cells (the memory cells arranged on the back side or the front side of the plane of the drawing with respect to the memory cells Ce1 and Ce3) arranged in other columns in these program selected pages. Therefore, the potential of the semiconductor layer 17 in the vicinity of the word line WL₁ also changes depending on the drain-side assist gate voltage V_{AssistD}, the memory-side assist gate voltage V_{AssistM}, and the source-side assist gate voltage V_{AssistS}. When the drain-side assist gate voltage V_{AssistD}, the memory-side assist gate voltage V_{AssistM}, and the source-side assist gate voltage V_{AssistS} are increased, the potential of the semiconductor layer 17 increases, and the potential difference between the potential of the semiconductor layer 17 and the word line WL₁ decreases. Accordingly, data programming can be more effectively prevented.

Next, a program unselected page including only the unselected memory cells Ce2 and Ce4 will be described. In this case, since the bit lines BL₁ and BL₂ and the source lines SL₁ and SL₂ connected to the unselected memory cells Ce2 and Ce4 are shared with the memory cells Ce1 and Ce3 in the program selected page, the description thereof is omitted here, and a drain-side select gate line BGL₂, the word line WL₂, and a source-side select gate line SGL₂ will be described.

In the program unselected page, a program unselected drain-side gate voltage V_{SGD2}, a program unselected memory gate voltage V_{CG2}, and a program unselected source-side gate voltage V_{SGS2}, which have a low potential (for example, 0 V), are applied to the drain-side select gate line BGL₂, the word line WL₂, and the source-side select gate line SGL₂, respectively. As a result, in the unselected memory cells Ce2 and Ce4 of the program unselected page, the drain-side select transistors DT2 and DT4 and the source-side select transistors ST2 and ST4 are turned off at both ends of the memory transistors MT2 and MT4, respectively, so that no tunnel current flows into the charge storage layer 15b of the memory transistors MT2 and MT4, movement of electric charges into the charge storage layer 15b can be blocked to prevent data programming.

In addition, similarly to the above case, at this time, the drain-side assist gate voltage V_{AssistD} is applied from the drain-side assist gate line DAGL, the memory-side assist gate voltage V_{AssistM} is applied from the memory-side assist gate line MAGL, and the source-side assist gate voltage V_{AssistS} is applied from the source-side assist gate line SAGL to the program unselected memory cells Ce2 and Ce4 in the program unselected pages. As a result, in the drain-side select transistors DT2 and DT4 and the source-side select transistors ST2 and ST4, the potentials of the semiconductor layer 17 in the vicinity of the drain-side assist gate electrode DAG and the semiconductor layer 17 in the vicinity of the source-side assist gate electrode SAG rise.

In particular, the drain-side assist gate voltage V_{AssistD} (for example, 0 V) is applied from the drain-side assist gate line DAGL, and the source-side assist gate voltage V_{AssistS} (for example, 0 V) is applied from the source-side assist gate line SAGL, whereby the drain-side select transistors DT2 and DT4 and the source-side select transistors ST2 and ST4 can be reliably turned off even in the program unselected pages. In the memory transistors MT of the unselected memory cells Ce2, Ce3, and Ce4, movement of electric charges to the charge storage layer 15b is blocked, and thus, the threshold voltage does not change.

In this manner, in the memory array CAd, it is possible to prevent data programming to the unselected memory cells Ce2, Ce3, and Ce4 and to program data only to the selected memory cell Ce1.

As described above, in the third embodiment, during the data program operation, the potential of the semiconductor layer 17 around the source-side select gate structure 12, the potential of the semiconductor layer 17 around the memory gate structure 10, and the potential of the semiconductor layer 17 around the drain-side select gate structure 11 can be individually adjusted by the source-side assist gate voltage V_{AssistS}, the memory-side assist gate voltage V_{AssistM}, and the drain-side assist gate voltage V_{AssistD}. Therefore, in the present embodiment, it is possible to suppress leakage current more reliably.

### (3-4) Data Erase Operation

Next, a data erase operation in the memory cell Ce illustrated in FIG. 33A will be described. To erase the data from the memory cell Ce illustrated in FIG. 33A, the source-side assist gate voltage V_{AssistS}, which is a positive voltage of 7 V to 12 V, is applied to the source-side assist gate electrode SAG, the drain-side assist gate voltage V_{AssistD}, which is a positive voltage of 7V to 12 V, is applied to the drain-side assist gate electrode DAG, and the memory-side assist gate voltage V_{AssistM}, which is a positive voltage of 7 V to 12 V, is applied to the memory-side assist gate electrode MAG.

As a result, the potential of the semiconductor layer 17 in the vicinity of the drain-side assist gate electrode DAG, the potential of the semiconductor layer 17 in the vicinity of the memory-side assist gate electrode MAG, and the potential of the semiconductor layer 17 in the vicinity of the source-side assist gate electrode SAG rise and become substantially uniform. The values of the drain-side assist gate voltage V_{AssistD}, memory-side assist gate voltage V_{AssistM}, and source-side assist gate voltage V_{AssistS} are desirably identical.

At this time, for example, a source voltage V_{SL}, which is a positive high voltage (for example, 7 to 12 V), is applied to the source line SL, and an erase selected source-side gate voltage V_{SGS} identical to the bit voltage V_{BL} is applied to the source-side select gate line SGL connected to source-side select gate electrode SG of source-side select transistor ST.

Similarly, the bit voltage V_{BL}, which is a positive high voltage (for example, 7 to 12 V), is applied to the bit line BL, and the erase selected drain-side gate voltage V_{SGD} identical to the bit voltage V_{BL} is applied to the drain-side select gate line BGL connected to the drain-side select gate electrode DG of the drain-side select transistor DT. As a result, the potential of the semiconductor layer 17 on the drain-side of the source-side select transistor ST becomes V_{SGS}−Vₜ. Similarly, the potential of the semiconductor layer 17 on the drain-side of the drain-side select transistor DT becomes V_{SGD}−Vₜ.

Further, an erase selected memory gate voltage V_{CG1}, which is a voltage of a negative value to 0 V (for example, −5 to 0 V), is applied to the word line WL connected to the memory gate electrode MG of the memory transistor MT. As a result, a potential difference is generated between the memory gate electrode MG of the memory transistor MT and the semiconductor layer 17, electric charges move from the charge storage layer 15b, whereby the data is erased. At this time, in the third embodiment, since the potential of the semiconductor layer 17 is increased by the drain-side assist gate voltage V_{AssistD}, the memory-side assist gate voltage V_{AssistM}, and the source-side assist gate voltage V_{AssistS}, the difference from the potential of the memory gate electrode MG increases, and electrons in the charge storage layer 15b move at a higher speed.

In the third embodiment, similarly to the first embodiment described above, in the multilayer insulating layer 15 including the charge storage layer 15b, when the distance ta in the plane direction of the first memory gate insulating layer 15a is longer than the distance tc in the plane direction of the second memory gate insulating layer 15c (that is, ta>tc), electrons move from the inside of the charge storage layer 15b toward the semiconductor layer 17 or holes move from the semiconductor layer 17 to the charge storage layer 15b during the data erase operation. As a result, the threshold of the memory transistor MT decreases. On the other hand, when the distance ta in the plane direction of the first memory gate insulating layer 15a is smaller than the distance tc in the plane direction of the second memory gate insulating layer 15c (That is, ta<tc), electrons move from the charge storage layer 15b to the memory gate electrode MG, or holes move from the memory gate electrode MG to the charge storage layer 15b. As a result, the threshold of the memory transistor MT increases.

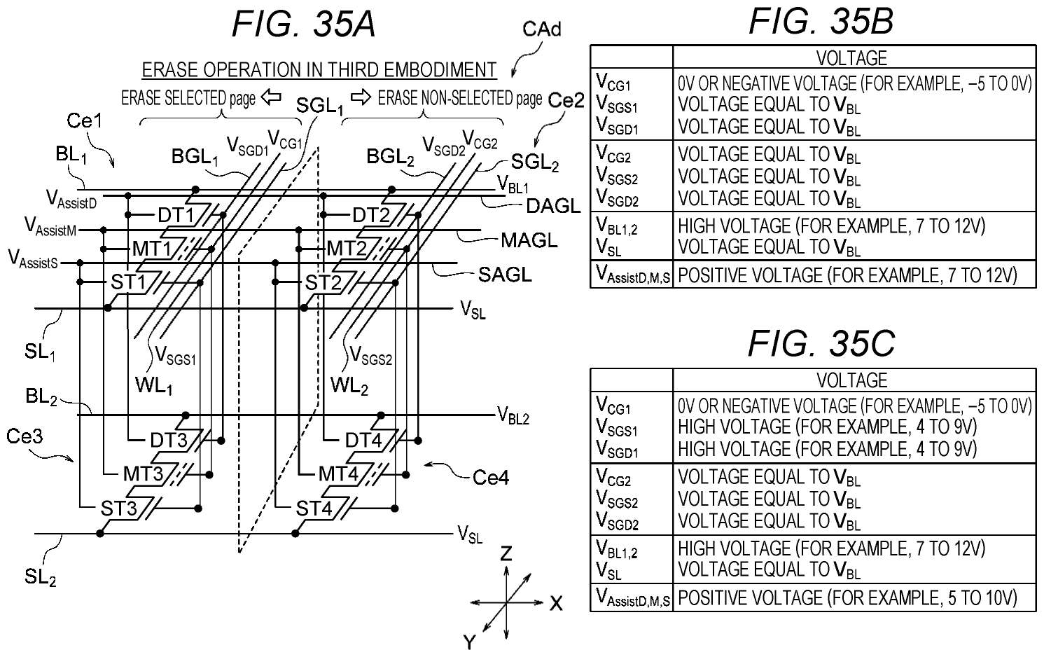

Next, as in “(3-3) Data Program Operation” described above, the data erase operation in the memory array CAd will be described by exemplifying the memory array CAd in which one page is constituted by the memory cells Ce1 and Ce3 arranged in the vertical direction Z and another one page is constituted by the memory cells Ce2 and Ce4 arranged in the vertical direction Z as illustrated in FIG. 35A.

Here, a case where data is erased in units of pages, data is erased for pages configured by the memory cells Ce1 and Ce3, and data is not erased for pages configured by the memory cells Ce2 and Ce4 will be described. In this case, the page from which to erase data is designated as an erase selected page, and the page constituted by only the unselected memory cells Ce2 and Ce4 from which data is not to be erased is designated as an erase unselected page. The threshold voltages Vt of the drain-side select transistors DT and the source-side select transistors ST of the memory cells Ce1, Ce2, Ce3, and Ce4 are desirably positive values.

FIG. 35B illustrates an example of voltages of components in the memory array CAd in this case. The drain-side assist gate voltage V_{AssistD}, the memory-side assist gate voltage V_{AssistM}, and the source-side assist gate voltage V_{AssistS}, which are identical positive high voltages (for example, 7 to 12 V), are applied to the drain-side assist gate line DAGL, the memory-side assist gate line MAGL, and the source-side assist gate line SAGL connected to the memory cells Ce1, Ce2, Ce3, and Ce4, respectively. As a result, a predetermined voltage is applied to the semiconductor layers 17 of the memory cells Ce1, Ce2, Ce3, and Ce4.

In the memory array CAd, the erase bit voltages V_{BL1} and V_{BL2} (also referred to as “V_{BL}1, 2”, for example, high voltages of 7 to 12 V) are applied to the bit lines BL₁ and BL₂ shared between the erase selected page and the erase unselected page, and the source voltage VSL, which is the same voltage as the erase bit voltages V_{BL1} and V_{BL2} (for example, high voltages of 7 to 12 V), is applied to the source lines SL₁ and SL₂.

In the erase selected page, for example, the erase selected drain-side gate voltage V_{SGD1}, which is a high voltage of 7 to 12 V that is the same as the erase bit voltages V_{BL1} and V_{BL2}, is applied to the drain-side select gate line BGL₁, and similarly, an erase selected source-side gate voltage V_{SGS1}, which is a high voltage of 7 to 12 V that is the same as the erase bit voltages V_{BL1} and V_{BL2}, is applied to the source-side select gate line SGL₁. In addition, in the erase selected page, an erase selection memory gate voltage V_{CG1}, which is a voltage of a negative value to 0 (for example, −5 to 0 V), is applied to the word line WL₁. As a result, in the erase selected page, in each of the memory cells Ce1 and Ce3, a potential difference is generated between the memory gate electrode MG and the semiconductor layer 17 around the memory gate electrode MG, charge is moved from the charge storage layer 15b, and data is erased.

On the other hand, in the erase unselected page, the same voltage as the erase bit voltages V_{BL1} and V_{BL2} applied to the bit lines BL₁ and BL₂ (for example, a high voltage of 7 to 12 V) is applied as the erase unselected drain-side gate voltage V_{SGD2}, the erase unselected source-side gate voltage V_{SGS2}, and the erase unselected memory gate voltage V_{CG2} to the drain-side select gate line BGL₂, the source-side select gate line SGL₂, and the word line WL₂, respectively. As a result, in the erase unselected page, in each of the memory cells Ce2 and Ce4, no potential difference occurs between the memory gate electrode MG and the semiconductor layer 17 around the memory gate electrode MG, electrical charges do not move from the charge storage layer 15b, and data can be prevented from being erased.

FIG. 35C illustrates an example of voltages of components in the data erase operation according to another embodiment, which is different from the example in FIG. 35B in the voltage values of an erase selected source-side gate voltage V_{SGS1}, an erase selected drain-side gate voltage V_{SGD1}, a drain-side assist gate voltage V_{AssistD}, a memory-side assist gate voltage V_{AssistM}, and a source-side assist gate voltage V_{AssistS}, and which is the same as the example in FIG. 35B in the voltages of the other components.

In this case, as illustrated in FIG. 35B, the drain-side assist gate voltage V_{AssistD}, the memory-side assist gate voltage V_{AssistM}, and the source-side assist gate voltage V_{AssistS}, which are identical positive high voltages (for example, 5 to 10 V), are applied to the drain-side assist gate line DAGL, the memory-side assist gate line MAGL, and the source-side assist gate line SAGL, respectively. In addition, in the erase selected page, for example, an erase selection drain-side gate voltage V_{SGD1}, which is a high voltage of 4 to 9 V, is applied to the drain-side select gate line BGL₁, and similarly, an erase selection source-side gate voltage V_{SGS1}, which is a high voltage of 4 to 9 V, is applied to the source-side select gate line SGL₁. In the erase selected page, even when these voltages are applied, a potential difference generated between the memory gate electrode MG and the semiconductor layer 17 around the memory gate electrode MG moves electrical charges from the charge storage layer 15b, and data can be erased in each of the memory cells Ce1 and Ce3.

As described above, in the third embodiment, the potentials of the semiconductor layers 17 of the memory cells Ce1, Ce2, Ce3, and Ce4 are increased by applying the positive drain-side assist gate voltage V_{AssistD}, the memory-side assist gate voltage V_{AssistM}, and the source-side assist gate voltage V_{AssistS} to the memory cells Ce1, Ce2, Ce3, and Ce4 during the data erase operation. Therefore, in the erase unselected page, in each of the memory cells Ce2 and Ce4, the potential difference between the memory gate electrode MG and the semiconductor layer 17 around the memory gate electrode MG is reduced and the erasing of data can be more effectively suppressed, as compared with the case where the drain-side assist gate voltage V_{AssistD}, the memory-side assist gate voltage V_{AssistM}, and the source-side assist gate voltage V_{AssistS} are not applied.

In the third embodiment described above, data is erased page by page, but the present invention is not limited thereto. Alternatively, all the pages may be set as erase selected pages and data of all the memory cells Ce constituting the memory array CAd may be collectively erased.

### (3-5) Data Read Operation

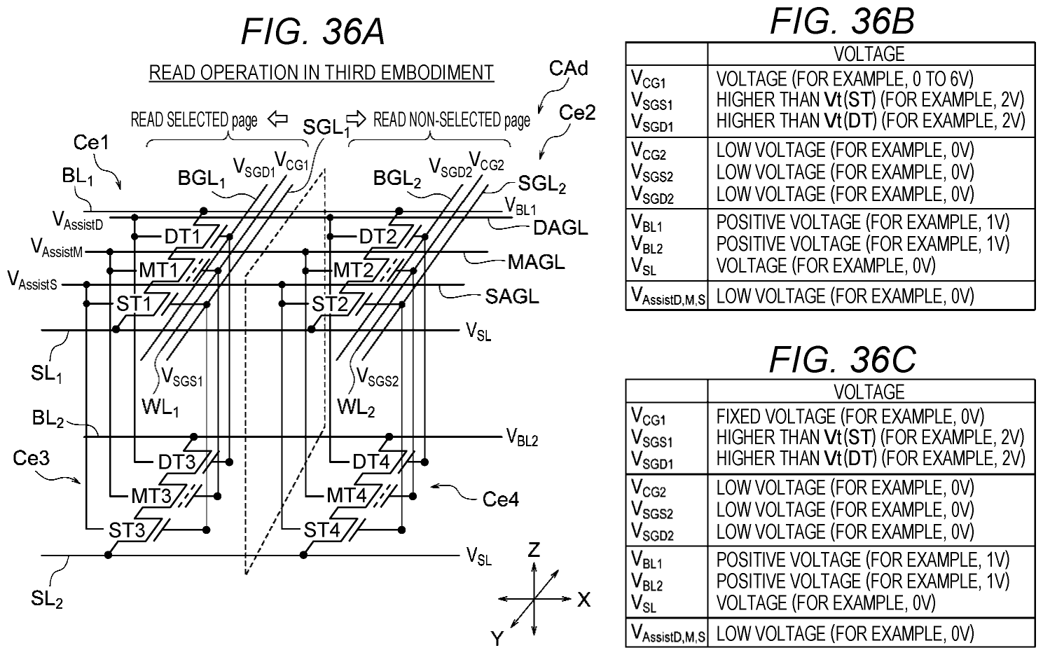

Next, a data read operation in the memory array CAd will be described. Here, as in “(3-3) Data Program Operation” described above, the data read operation in the memory array CAd will be described by exemplifying the memory array CAd in which one page is constituted by the memory cells Ce1 and Ce3 arranged in the vertical direction Z and another one page is constituted by the memory cells Ce2 and Ce4 arranged in the vertical direction Z as illustrated in FIG. 36A.

Herein, a case where data is read with the memory cells Ce1 and Ce3, among the memory cells Ce1, Ce2, Ce3, and Ce4, as the selected memory cells Ce1 and Ce3 will be described, for example. In this case, the page including the selected memory cells Ce1 and Ce3 from which to read data is set as a read selected page, and the page including only the unselected memory cells Ce2 and Ce4 from which data is not to be read is set as a read unselected page.

FIG. 36B illustrates an example of voltages of components in the memory array CAd in this case. In this case, the drain-side assist gate voltage V_{AssistD}, the memory-side assist gate voltage V_{AssistM}, and the source-side assist gate voltage V_{AssistS}, which are identical low voltages (for example, 0 V), are applied to the drain-side assist gate line DAGL, the memory-side assist gate line MAGL, and the source-side assist gate line SAGL connected to the memory cells Ce1, Ce2, Ce3, and Ce4, respectively. In the memory array CAd, read bit voltages V_{BL1} and V_{BL2} (they are the same positive voltage, for example, 1 V) are applied to the bit lines BL₁ and BL₂ shared between the read selected page and the read unselected page, respectively, and a read source voltage V_{SL} (the source lines SL have the same voltage, for example, 0 V) is applied to the source lines SL₁ and SL₂.

In the read selected page, for example, a voltage (for example, 2 V) higher than the threshold voltage Vt(DT) of the drain-side select transistor DT1 is applied to the drain-side select gate line BGL₁ as read selected drain-side gate voltage V_{SGD1}, and similarly, a voltage (for example, 2 V) higher than the threshold voltage Vt(ST) of the source-side select transistor ST1 is applied to the source-side select gate line SGL₁ as the read selected source-side gate voltage V_{SGS1}. As a result, the drain-side select transistor DT1 and the source-side select transistor ST1 of the selected memory cell Ce1 are turned on.

At this time, in the read selected page, the potential of the semiconductor layer 17 is lowered by applying the drain-side assist gate voltage V_{AssistD}, the memory-side assist gate voltage V_{AssistM}, and the source-side assist gate voltage V_{AssistS}, which are low voltages (for example, 0 V), and the leakage current from the source line SL₁ to the bit line BL₁ can be suppressed accordingly.

Further, in the read selected page, for example, a read selected memory gate voltage V_{CG1} of 0 to 6 V is applied to the word line WL₁. Accordingly, in the selected memory cell Ce1, when data is not programed in the memory transistor MT1 and the threshold voltage Vt of the memory transistor MT1 is lower than the read selected memory gate voltage V_{CG1}, a current flows from the source line SL₁ to the bit line BL₁, and the potential of the bit line BL₁ changes.

On the other hand, when data is programed in the memory transistor MT1 of the selected memory cell Ce1 and the threshold voltage Vt of the memory transistor MT1 is higher than the read selected memory gate voltage V_{CG1}, no current flows from the source line SL₁ to the bit line BL₁, and the potential of the bit line BL₁ does not change. The data of the selected memory cell Ce1 can be read by detecting such a change in the potential of the bit line BL₁ by the column decoder 2b (FIG. 1). At this time, the data of the other selected memory cells Ce3 in the read selected page can be similarly read by detecting a change in the potential of the bit line BL₂ by the column decoder 2b (FIG. 1).

In the read unselected page, for example, a voltage (for example, 0 V) lower than the threshold voltage Vt of the drain-side select transistor DT2 is applied to the drain-side select gate line BGL₂ as read unselected drain-side gate voltage V_{SGD2}, and similarly, a voltage (for example, 0 V) lower than the threshold voltage Vt of the source-side select transistor ST2 is applied to the source-side select gate line SGL₂ as the read unselected source-side gate voltage V_{SGS2}.

As a result, the drain-side select transistors DT and the source-side select transistors ST of the unselected memory cells Ce2 and Ce4 of the read unselected page are turned off, and no current flows from the source lines SL₁ and SL₂ to the bit lines BL₁ and BL₂. As described above, data can be read only from the selected memory cells Ce1 and Ce3 of the read selected page.

When multi-value data is detected in one memory cell Ce, a fine threshold voltage of the memory transistor MT can be detected and multi-value data can be read by changing the value of the read selected memory gate voltage V_{CG1} in the read selected page and detecting a change in the potential of the bit line BL₁ at each voltage value.

FIG. 36C illustrates an example of voltages of individual parts in a data read operation according to another embodiment. The voltages at the data read operation illustrated in FIG. 36C are different from those illustrated in FIG. 36B in that the read selection memory gate voltage V_{CG1} (for example, 0 V) is applied to the word line WL₁ as a fixed voltage in the read selected page, and the voltages of the other components are the same as those illustrated in FIG. 36B.

The cell current flowing from the source line SL₁ to the bit line BL₁ via the selected memory cell Ce1 is determined by the value of a threshold difference (V_{CG1}−Vt) between the read selected memory gate voltage V_{CG1} and the threshold voltage Vt of memory transistors MT1 and MT3. The magnitude of the cell current flowing from the source line SL₁ to the bit line BL₁ via the selected memory cell Ce1 is detected by the column decoder 2b, the threshold voltage Vt of the memory transistors MT1 and MT3 is determined in the column decoder 2b, and whether data is programed in the memory transistors MT1 and MT3 is determined.

Also in this case, the data programed in the memory transistors MT1 and MT3 can be classified according to the value of the cell current flowing from the source line SL₁ to the bit line BL₁ via the selected memory cell Ce1, and multi-valued data can be read. A read unselected page is the same as that illustrated in FIG. 36B described above, and thus description thereof will be omitted here.

### (3-6) Specific Examples of Voltages in Data Program Operation, Erase Operation, and Read Operation

Table 5 below shows specific examples (voltage examples) of combinations of voltages at data program operation, erase operation (Junction current induced mode and Channel current induced mode), and read operation in the third embodiment described above. The unit of the voltage values shown in Table 5 is “V”.

In Table 5, “BL column” indicates a column of a memory cell Ce group electrically connected to the bit line BL extended from the column decoder 2b in the column direction X. In the third embodiment, similarly to the configuration in FIG. 1, the column decoder 2b is two-dimensionally arranged in the row direction Y which is the depth direction of the plane and the vertical direction z in the drawing, and there are two types of the BL columns in the row direction Y which is the depth direction in plane and the vertical direction Z. Therefore, strictly speaking, these can also be defined. However, in order to simplify the description, Table 5 does not particularly distinguish between the row direction Y which is the depth direction in the drawing and the vertical direction Z, and arranges operations focusing on the selected page and the unselected page indicated in FIGS. 34A, 35A, and 36A.

TABLE 5

| | | | Operation | | | | | |
|---|---|---|---|---|---|---|---|---|
| | | | Read | | Program | | | Erase 2 |
| | | | Selected | Unselected | Selected | Unselected | Erase 1 | Junction |
| | | | BL | BL | BL | BL | Channel | current |
| | | | column | column | column | column | current | induced |
| V_{CG} | Selected | V_{CG1} | 0 | 0 | 10 | 10 | −3 | −3 |
| | page | | | | | | | |
| | Unselected | V_{CG2} | 0 | 0 | 0 | 0 | 10 | 10 |
| | page | | | | | | | |
| V_{SGS} | Selected | V_{SGS1} | 1 | 1 | 0 | 0 | 10 | 7 |
| | page | | | | | | | |
| | Unselected | V_{SGS2} | 0 | 0 | 0 | 0 | 10 | 10 |
| | page | | | | | | | |
| V_{SGD} | Selected | V_{SGD1} | 1 | 1 | 1 | 1 | 10 | 7 |
| | page | | | | | | | |
| | Unselected | V_{SGD2} | 0 | 0 | 0 | 0 | 10 | 10 |
| | page | | | | | | | |
| V_{BL1}, | | | 1 | 0 | 0 | 1 | 10 | 10 |
| V_{BL2} | | | | | | | | |
| V_{SL} | | | 0 | 0 | 1 | 1 | 10 | 10 |

| | | | | | | |
|---|---|---|---|---|---|---|
| V_{AssistM} | 0 | 0 | 7 | 7 | 10 | 10 |
| V_{AssistS} | 0 | 0 | 0 | 0 | 10 | 10 |
| V_{AssistD} | 0 | 0 | 0 | 0 | 10 | 10 |

In the non-volatile semiconductor memory device according to the third embodiment, applying voltages as shown in Table 5 above makes it possible to adjust the voltages page by page in the memory array CAd and to selectively program, erase, and read data to and from a predetermined memory cell Ce.

### (3-7) Method of Manufacturing Memory Array According to Third Embodiment

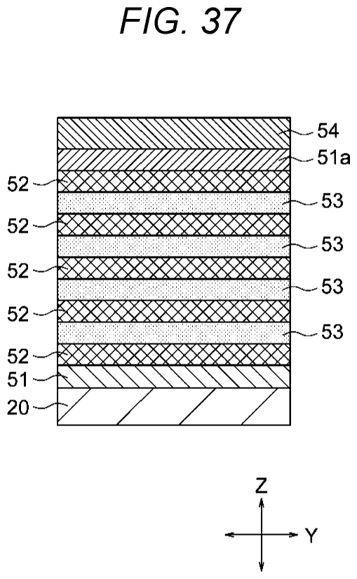

Next, a method of manufacturing the memory array CAd will be described with reference to FIGS. 37 to 46. In this case, as illustrated in FIG. 37, for example, an insulating layer 51 is stacked on a substrate 20 made of silicon, and an interlayer insulating layer 52 different in type from the insulating layer 51 and a silicon layer 53 made of polycrystalline silicon, for example, are alternately stacked on the insulating layer 51. Furthermore, another insulating layer 51a different in type from the insulating layer 51 and the interlayer insulating layer 52 is stacked on the uppermost interlayer insulating layer 52 among the interlayer insulating layers 52, and a mask layer 54 for a mask made of Al₂O₃, carbon, SiC or the like, for example, is further formed thereon. Here, the insulating layer 51 and the insulating layer 51a are made of materials different from that of the silicon layer 53, and are layers that are unlikely to be etched when etching the interlayer insulating layer 52 and the silicon layer 53.

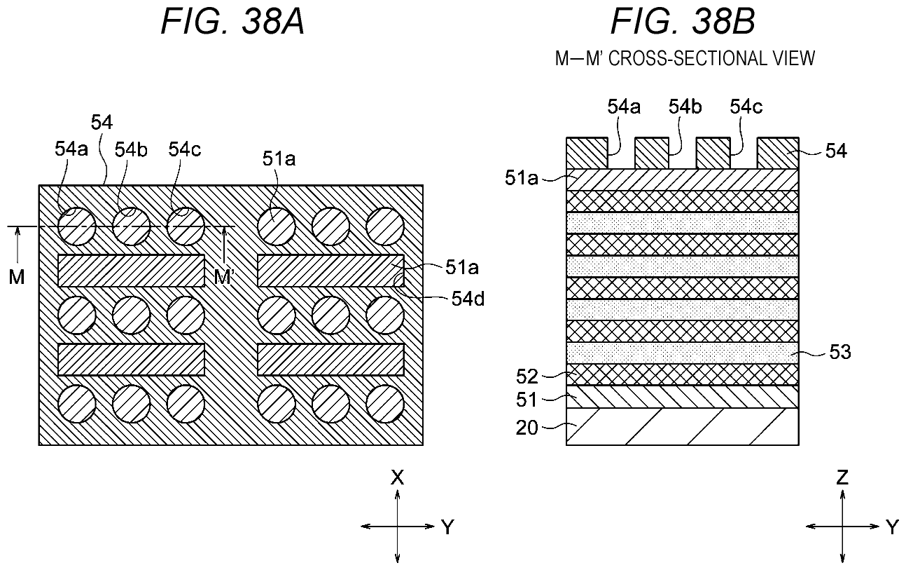

Subsequently, as illustrated in FIGS. 38A and 38B, the mask layer 54 is selectively etched by a dry etching method using a predetermined mask layer, for example. FIG. 38A is a schematic diagram illustrating the mask layer 54 after etching in plan view, and FIG. 38B is a cross-sectional view of a cross-sectional configuration of an M-M′ portion in FIG. 38A. As illustrated in FIG. 38A, openings are formed in accordance with regions (gate structure formation regions) 54a, 54b, and 54c in which the source-side select gate structure 12, the memory gate structure 10, and the drain-side select gate structure 11 are to be formed, and a region (assist gate electrode formation region) 54d in which the source-side assist gate electrode SAG, the memory-side assist gate electrode MAG, and the drain-side assist gate electrode DAG are to be formed.

The surface of the insulating layer 51a is exposed in the openings of the gate structure formation regions 54a, 54b, and 54c formed in the mask layer 54 and in the opening of the assist gate electrode formation region 54d.

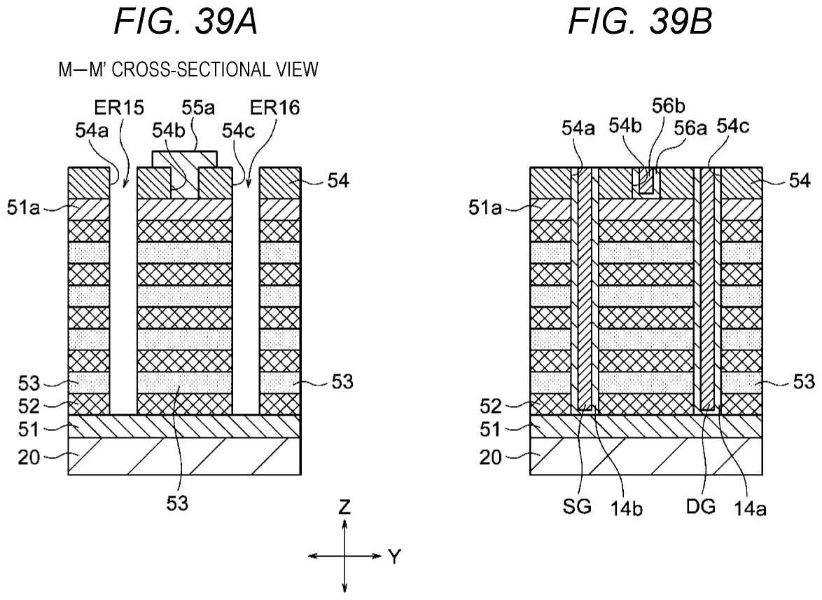

Subsequently, a new mask layer is formed on the mask layer 54 so as to cover the gate structure formation region 54b for forming the memory gate structure 10 among the gate structure formation regions 54a, 54b, and 54c formed in the mask layer 54. Here, FIG. 39A is a cross-sectional view of a cross-sectional configuration of a new mask layer 55a formed so as to cover the gate structure formation region 54b at the M-M′ portion illustrated in FIG. 38A. Then, using the new mask layer 55a as a mask, the gate structure formation region 54a where the source-side select gate structure 12 is to be formed and the gate structure formation region 54c where the drain-side select gate structure 11 is to be formed are etched in the vertical direction Z by dry etching. As a result, the insulating layer 51a, the interlayer insulating layer 52, and the silicon layer 53 in the gate structure formation regions 54a and 54c are etched from the surface of the insulating layer 51a to the surface of the insulating layer 51 in the vertical direction Z.

As a result, a hole ER15 for forming a source-side select gate structure is formed in the gate structure formation region 54a, and a hole ER16 for forming a drain-side select gate structure is formed in the gate structure formation region 54c. At this time, also in the assist gate electrode formation region 54d not covered with the mask layer 55a, the insulating layer 51a, the interlayer insulating layer 52, and the silicon layer 53 are etched from the surface of the insulating layer 51a to the surface of the insulating layer 51 in the vertical direction Z by dry etching. As a result, a hole (not illustrated) for forming an assist gate electrode is formed in the assist gate electrode formation region 54d. Thereafter, the uppermost mask layer 55a is removed.

Next, as illustrated in FIG. 39B, an insulating material such as a silicon oxide film is deposited in the hole ER15 for forming a source-side select gate structure, the hole ER16 for forming a drain-side select gate structure, and the opening in the gate structure formation region 54b. As a result, the source-side select gate insulating layer 14b is formed along the side surfaces and bottom surface of the hole ER15 for forming a source-side select gate structure, the drain-side select gate insulating layer 14a is formed along the side surfaces and bottom surface of the hole ER16 for forming a drain-side select gate structure, and the insulating layer 56a is also formed in the gate structure formation region 54b. Thereafter, a gate material such as low-resistance polycrystalline silicon or metal such as tungsten is deposited in the region surrounded by the source-side select gate insulating layer 14b and the drain-side select gate insulating layer 14a, thereby to form the source-side select gate electrode SG and the drain-side select gate electrode DG in the region surrounded by the source-side select gate insulating layer 14b and the drain-side select gate insulating layer 14a. At this time, also in the gate structure formation region 54b, the gate material is deposited in the region surrounded by the insulating layer 56a to form the gate material deposition portion 56b.

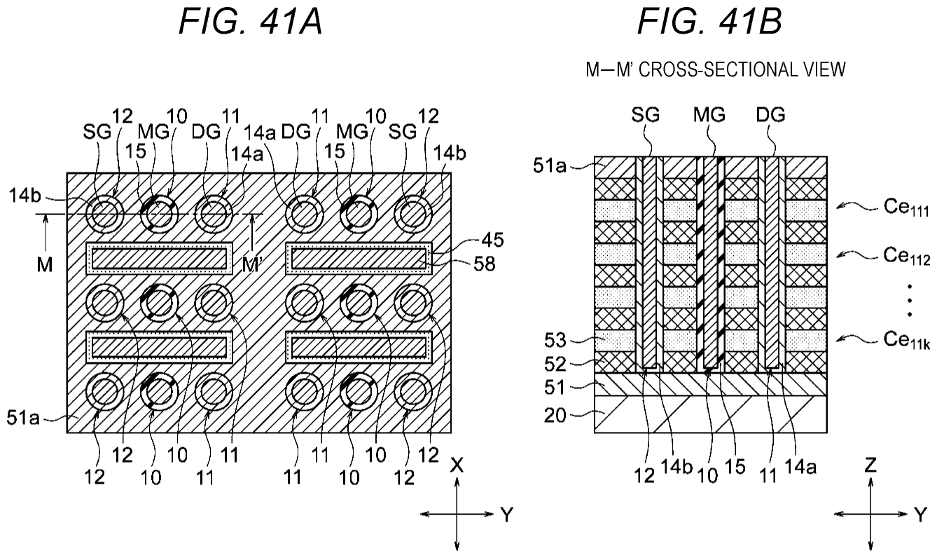

When the source-side select gate insulating layer 14b and the drain-side select gate insulating layer 14a are formed in the hole ER15 for forming a source-side select gate structure and in the hole ER16 for forming a drain-side select gate structure, the assist gate insulating layer 45 (FIG. 41A) is also formed inside the hole for forming an assist gate electrode along the side surfaces and the bottom surface. In addition, when the source-side select gate electrode SG and the drain-side select gate electrode DG are formed, the gate material is also deposited in a region surrounded by the assist gate insulating layer 45 to form an assist gate electrode 58 (FIG. 41A).

Next, the insulating material and the gate material deposited on the mask layer 54 and the like are removed by surface polishing to expose the upper surface of the mask layer 54. In this way, the source-side select gate structure 12 is formed in the hole ER15 for forming a source gate electrode, and the drain-side select gate structure 11 is formed in the hole ER16 for forming a drain gate electrode.

Here, the mask layer 55a illustrated in FIG. 39A is removed after the formation of the hole ER15 for forming a source-side select gate structure and the hole ER16 for forming a drain-side select gate structure. Alternatively, the insulating material and the gate material may be respectively deposited in the hole ER15 for forming a source-side select gate structure and the hole ER16 for forming a drain-side select gate structure, without removing the mask layer 55a. In this case, the insulating layer 56a and the gate material deposition portion 56b are not formed in the gate structure formation region 54b, and then the mask layer 55a is removed.

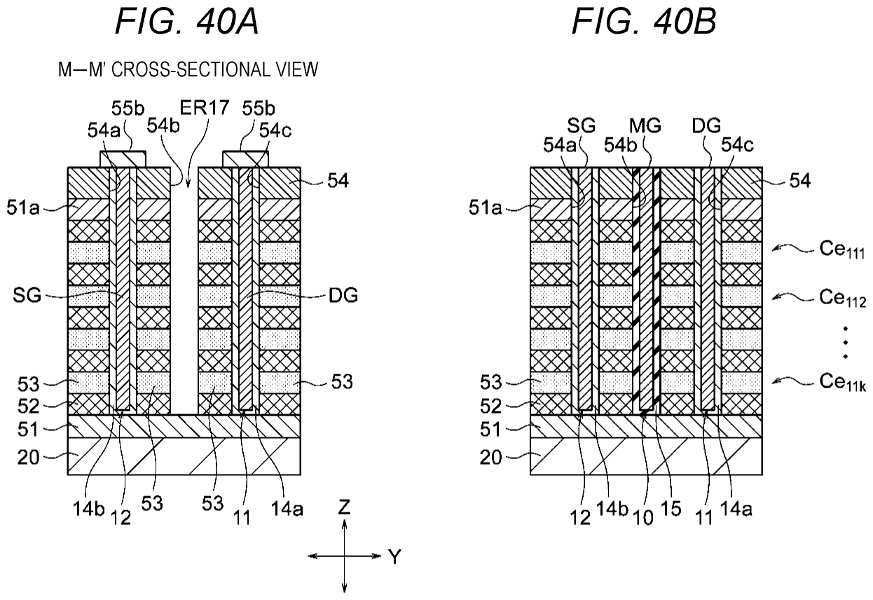

Next, in the mask layer 54, a new mask layer is formed on the mask layer 54 so as to cover the gate structure formation region 54a where the source-side select gate structure 12 is formed, the gate structure formation region 54c where the drain-side select gate structure 11 is formed, and the assist gate electrode formation region 54d where the assist gate insulating layer 45 and the assist gate electrode 58 are formed. FIG. 40A is a cross-sectional view of a cross-sectional configuration of a new mask layer 55b formed so as to cover the gate structure formation regions 54a and 54c and the assist gate electrode formation region 54d in the M-M′ portion illustrated in FIG. 38A.

Using the mask layer 55b as a mask, the insulating layer 56a, the gate material deposition portion 56b, the insulating layer 51a, the interlayer insulating layer 52, and the silicon layer 53 are etched up to the surface of the insulating layer 51 in the vertical direction Z, in the gate structure formation region 54b where the memory gate structure 10 is to be formed, which is not covered with the mask layer 55b. As a result, as illustrated in FIG. 40A, a hole ER17 for forming a memory gate structure having the same outline shape as the outline shape of the gate structure formation region 54b is formed in the gate structure formation region 54b.

Then, as illustrated in FIG. 40B, after the multilayer insulating layer 15 is formed along the side surfaces and bottom surface of the hole ER17 for forming a memory gate electrode, a gate material such as low-resistance polycrystalline silicon or metal such as tungsten is deposited on the multilayer insulating layer 15 to form the memory gate electrode MG in the region surrounded by the multilayer insulating layer 15. Thereafter, the insulating material and the gate material deposited on the mask layer 55b, the mask layer 54, and the like are removed by surface polishing to form the memory gate structure 10 in the hole ER17 for forming a memory gate structure.

As described above, the pillar-shaped memory gate structure 10, the drain-side select gate structure 11, and the source-side select gate structure 12 are disposed on the substrate 20 with the insulating layer 51 as an insulating layer interposed therebetween. As will be described later, the memory cells Ce are formed at each level at predetermined intervals along the memory gate structure 10, the drain-side select gate structure 11, and the source-side select gate structure 12. The memory gate structure 10, the drain-side select gate structure 11, and the source-side select gate structure 12 are shared among the plurality of memory cells Ce arranged in the vertical direction Z. The longitudinal cross-sectional configurations of the memory gate structure 10, the drain-side select gate structure 11, and the source-side select gate structure 12 are the same as those of the second embodiment, and thus, description thereof is omitted here.

The order of the formation steps of the hole ER15, hole ER16 (FIG. 39A), and hole ER17 (FIG. 40A) is not limited to the above-described order, and may be appropriately changed.

Next, the mask layer 54 is removed by surface polishing to expose the insulating layer 51a to the surface as illustrated in FIGS. 41A and 41B. FIG. 41A is a schematic view of a configuration in plan view when the insulating layer 51a is exposed to the surface, and FIG. 41B is a cross-sectional view of a cross-sectional configuration of a M-M′ portion of 41 A. In this case, the source-side select gate structure 12, the memory gate structure 10, the drain-side select gate structure 11, and the assist gate electrode 58 whose outer periphery is surrounded by the assist gate insulating layer 45 are exposed to the surface of the insulating layer 51a.

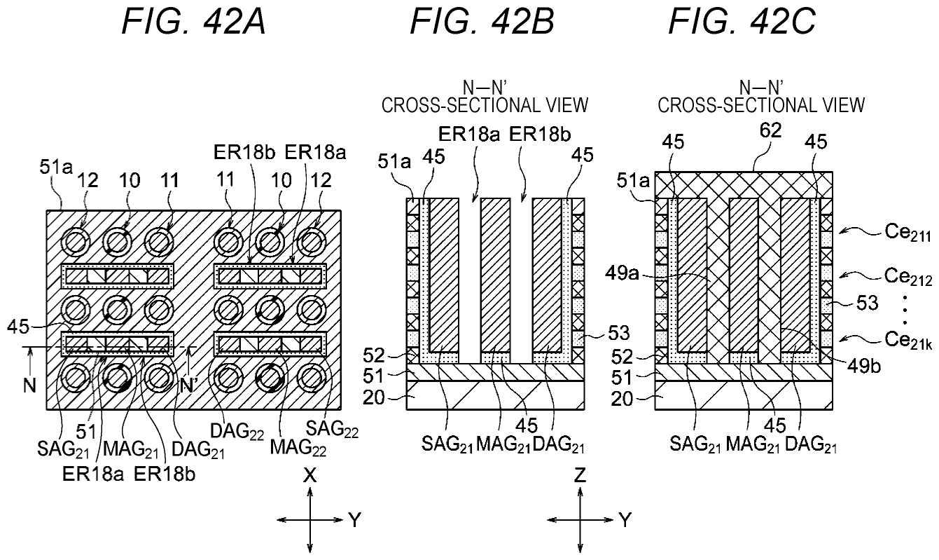

Next, a new patterned mask layer (not illustrated) is formed on the surface of the insulating layer 51a, a predetermined region in each assist gate electrode 58 is etched in the vertical direction Z up to the surface of the insulating layer 51 using the mask layer to form two holes penetrating the assist gate electrode 58 in the vertical direction Z, the assist gate electrode 58 is divided into three, and then the mask layer is removed. FIG. 42A is a schematic diagram illustrating a configuration in plan view of two holes ER18a and 18b formed in each assist gate electrode 58, and FIG. 42B is a cross-sectional view of a cross-sectional configuration of an N-N′ portion of FIG. 42A.

As illustrated in FIGS. 42A and 42B, the two holes ER18a and ER18b are formed in the assist gate electrode 58 at equal spacings in the longitudinal direction, each assist gate electrode 58 is divided into three to form the source-side assist gate electrode SAG₂₁, the memory-side assist gate electrode MAG₂₁, and the drain-side assist gate electrode DAG₂₁, for example. In the present embodiment, only the assist gate electrode 58 is etched without etching the assist gate insulating layer 45 on the outer periphery of the assist gate electrode 58 to form the two holes ER18a and ER18b in the assist gate electrode 58. However, the present invention is not limited thereto. When the holes ER18a and ER18b are formed by etching the assist gate electrode 58, the assist gate insulating layer 45 in the region facing the holes ER18a and ER18b may be etched together with the assist gate electrode 58.

In the present embodiment, the source-side assist gate electrode SAG₂₁ is formed to face the source-side select gate structure 12 along the column direction X, the memory-side assist gate electrode MAG₂₁ is formed to face the memory gate structure 10, and the drain-side assist gate electrode DAG₂₁ is formed to face the drain-side select gate structure 11. In addition, the surface of the insulating layer 51 is exposed inside the hole ER18a between the source-side assist gate electrode SAG₂₁ and the memory-side assist gate electrode MAG₂₁ and inside the hole ER18b between the memory-side assist gate electrode MAG₂₁ and the drain-side assist gate electrode DAG₂₁.

Then, as illustrated in FIG. 42C, an insulating material such as a silicon oxide film is deposited on the substrate surface to form an insulating layer (mask layer) 62 so as to cover the assist gate insulating layer 45, the insulating layer 51a, the drain-side assist gate electrode DAG₂₁, the memory-side assist gate electrode MAG₂₁, and the source-side assist gate electrode SAG₂₁, thereby forming the assist gate insulating layers 49a and 49b in the holes ER18a and ER18b, respectively. Accordingly, for example, the source-side assist gate electrode SAG₂₁ and the memory-side assist gate electrode MAG₂₁ are electrically separated from each other by the assist gate insulating layer 49a, and the memory-side assist gate electrode MAG₂₁ and the drain-side assist gate electrode DAG₂₁ are electrically separated from each other by the assist gate insulating layer 49b.

As illustrated in FIG. 42C, the source-side assist gate electrode SAG₂₁, the memory-side assist gate electrode MAG₂₁, and the drain-side assist gate electrode DAG₂₁ extend in a pillar shape along the vertical direction Z to the surface of substrate 20. As a result, the source-side assist gate electrode SAG₂₁, the memory-side assist gate electrode MAG₂₁, and the drain-side assist gate electrode DAG₂₁ are shared among the memory cells Ce₂₁₁, ₂₁₂, . . . , ₂₁ₖ at the corresponding levels arranged along the vertical direction Z.

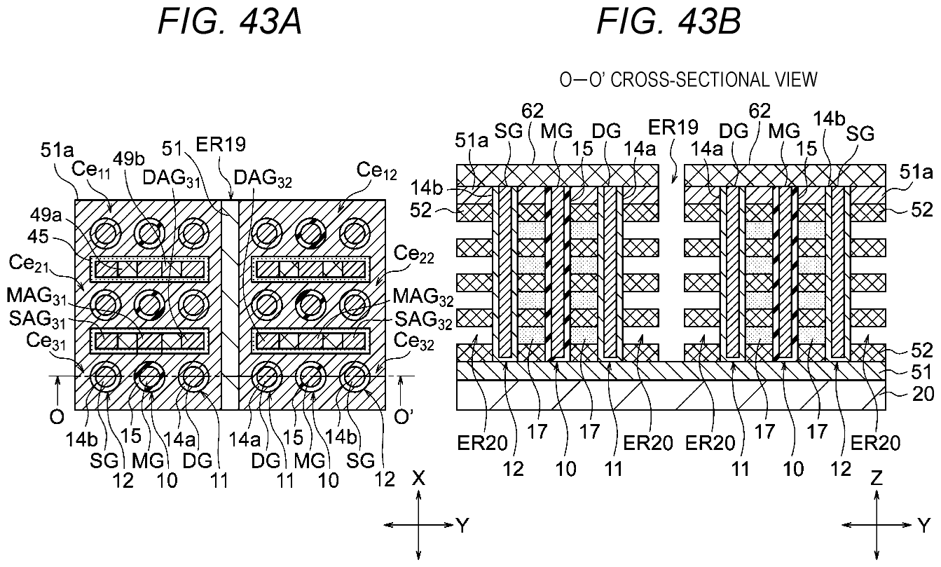

Next, as illustrated in FIG. 43A, for example, a new mask layer patterned so as to form a hole ER19 extending along the column direction X between memory cells Ce₁₁, Ce₂₁, and Ce₃₁ arranged along the column direction X and memory cells Ce₁₂, Ce₂₂, and Ce₃₂ arranged along the column direction X is formed on the mask layer 62, and etching is performed, then the new mask layer is removed. As a result, the hole ER19 extending along the column direction X is formed between the memory cells Ce₁₁, Ce₂₁, and Ce₃₁ arranged along the column direction X and the memory cells Ce₁₂, Ce₂₂, and Ce₃₂ arranged along the column direction X. In FIG. 43A, illustration of the mask layer 62 in the uppermost position is omitted, and a configuration of the layer under the mask layer 62 is illustrated in plan view. The surface of the insulating layer 51 is exposed on the bottom surface of the hole ER19 formed in this manner. FIG. 43B is a cross-sectional view of a cross-sectional configuration of an O-O′ portion illustrated in FIG. 43A, which also illustrates the mask layer 62 in the uppermost position.

FIG. 43A illustrates the hole ER19 alone extending along the column direction X and formed between the memory cells Ce₁₁, Ce₂₁, and Ce₃₁ arranged along the column direction X and the memory cells Ce₁₂, Ce₂₂, and Ce₃₂ arranged adjacent to the right side of the memory cells. Similarly, the hole ER19 extending along the column direction X is also formed on the left side of the memory cells Ce₁₁, Ce₂₁, and Ce₃₁ and on the right side of the memory cells Ce₁₂, Ce₂₂, and Ce₃₂.

Here, as illustrated in FIG. 43B, the hole ER19 is formed by etching the insulating layer 51a, the interlayer insulating layer 52, and the silicon layer 53 (see FIG. 42C) between the interlayer insulating layers 52, from the surface of the mask layer 62 to the surface of the insulating layer 51. The silicon layer 53 is removed from the hole ER19, while the silicon layer 53 remains as the semiconductor layer 17 in the region between the memory gate structure 10 and the drain-side select gate structure 11 and in the region between the memory gate structure 10 and the source-side select gate structure 12. In this case, in the hole ER19, when removing the silicon layer 53 between the interlayer insulating layers 52, the silicon layer 53 is side-etched until reaching the drain-side select gate insulating layer 14a of the drain-side select gate structure 11 to form a hollow portion ER20. Therefore, in the hollow portion ER20, the side surface of the drain-side select gate insulating layer 14a of the drain-side select gate structure 11 or the side surface of the source-side select gate insulating layer 14b of the source-side select gate structure 12 is exposed.

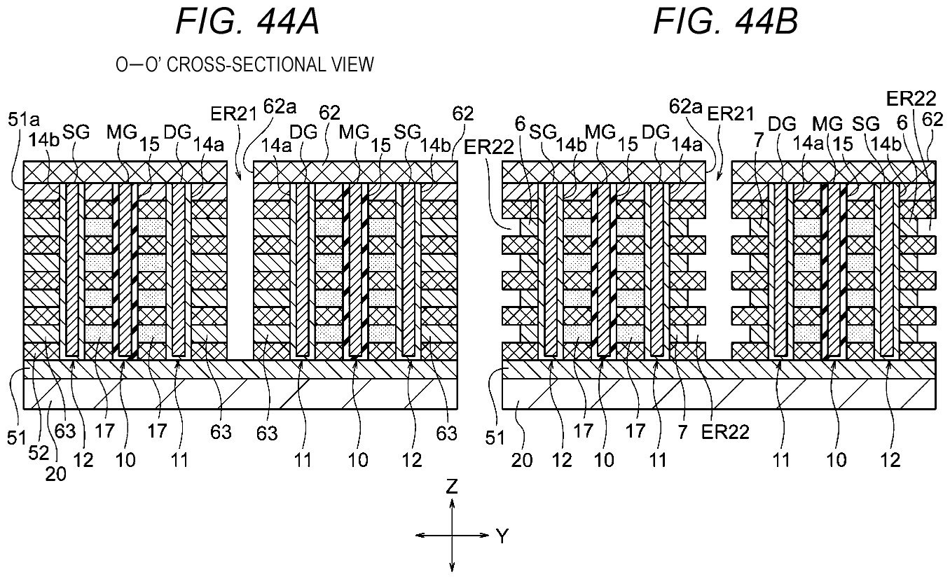

Then, as illustrated in FIG. 44A, a semiconductor material made of n-type silicon is deposited in the hole ER19, and then is etched using the mask layer 62 as a mask from the opening 62a in the mask layer 62 so that the semiconductor material remains in the hollow portion ER20. As a result, a hole ER20 is formed in which the semiconductor layer 63 is formed is formed in a hollow portion ER21 along the vertical direction Z from the opening 62a in the mask layer 62.

Next, as illustrated in FIG. 44B, the semiconductor layer 63 is side-etched from the side surface of the hole ER21 such that a part of the semiconductor layer 63 formed between the interlayer insulating layers 52 remains, and the source diffusion layer 6 or the drain diffusion layer 7 is formed from the semiconductor layer 63 between the interlayer insulating layers 52. The source diffusion layer 6 and the drain diffusion layer 7 are electrically separated between levels by the interlayer insulating layers 52.

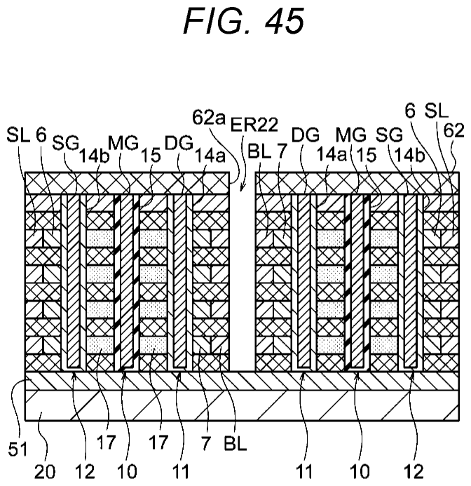

Thereafter, after the hole ER21 is filled with a metal material, as illustrated in FIG. 45, the metal material is etched such that the metal material remains in the region where the source diffusion layer 6 or the drain diffusion layer 7 is formed between the interlayer insulating layers 52, thereby forming a hole ER22. As a result, the source line SL or the bit line BL is formed by the metal material remaining between the interlayer insulating layers 52. The source line SL and the bit line BL are electrically separated between levels by the interlayer insulating layers 52.

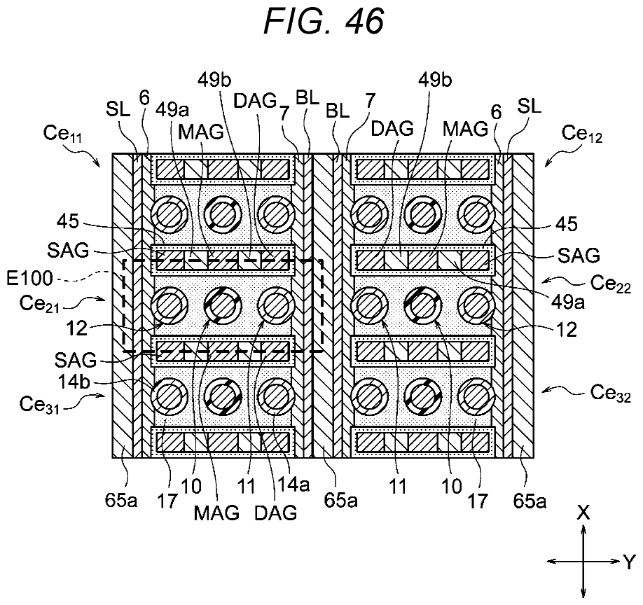

FIG. 46 is a schematic diagram illustrating a configuration of the layer under the mask layer 62 in plan view, without illustrating the mask layer 62 formed in the uppermost position. As illustrated in FIG. 46, an insulating material is charged into the hole ER22 between the bit lines BL adjacent to each other in the row direction Y illustrated in FIG. 45 and into the hole ER22 (not illustrated in FIG. 45) between the source lines SL adjacent to each other in the row direction Y to form an insulating layer 65a. As a result, the bit lines BL adjacent to each other in the row direction Y are electrically separated from each other by the insulating layer 65a, and similarly, the source lines SL adjacent to each other in the row direction Y are electrically separated from each other by the insulating layer 65a.

A region E100 illustrated in FIG. 46 indicates a region where one memory cell Ce₂₁ is formed. The memory cell Ce₂₁ has a configuration in which the source-side select gate structure 12, the memory gate structure 10, and the drain-side select gate structure 11 are arranged in order in the row direction Y. In addition, the source-side assist gate electrode SAG is arranged on both sides of the source-side select gate structure 12 as seen in the column direction X, the memory-side assist gate electrode MAG is arranged on both sides of the memory gate structure 10 as seen in the column direction X, and the drain-side assist gate electrode DAG is arranged on both sides of the drain-side select gate structure 11 as seen in the column direction X.

A semiconductor layer 17 made of a semiconductor material is provided around the source-side select gate structure 12, the memory gate structure 10, and the drain-side select gate structure 11 so as to surround them. A wall-shaped assist gate insulating layer 45 is provided between the semiconductor layer 17 and the source-side assist gate electrode SAG, the memory-side assist gate electrode MAG, and the drain-side assist gate electrode DAG. As a result, the semiconductor layer 17 is electrically separated from the source-side assist gate electrode SAG, the memory-side assist gate electrode MAG, and the drain-side assist gate electrode DAG.

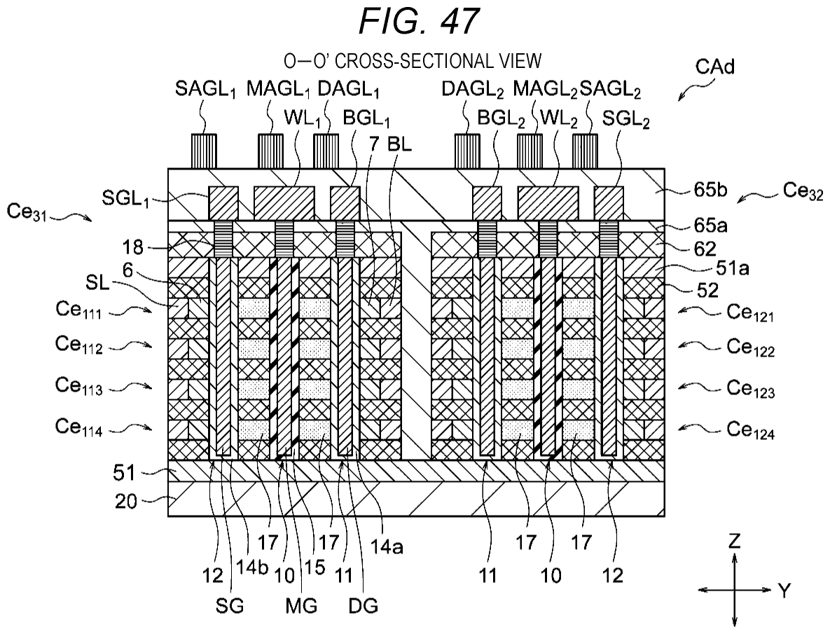

Next, as illustrated in FIG. 47, contacts 18 electrically connected to the source-side select gate electrode SG, the memory gate electrode MG, and the drain-side select gate electrode DG are formed on the surface of the insulating layer 65a on the surface of the mask layer 62 by a general semiconductor manufacturing process using a photolithography technique, a film forming technique such as CVD, an etching technique, an ion implantation method, and the like. Next, the insulating layer 65b is formed on the surface, the source-side select gate lines SGL₁ and SGL₂, the word lines WL₁ and WL₂, and the drain-side select gate lines BGL₁ and BGL₂ electrically connected to the contacts 18 are formed in the insulating layer 65b, and the source-side assist gate lines SAGL₁ and SAGL₂, the memory-side assist gate lines MAGL₁ and MAGL₂, and the drain-side assist gate lines DAGL₁ and DAGL₂ are formed on the surface of the insulating layer 65a. The source-side assist gate lines SAGL₁ and SAGL₂, the memory-side assist gate lines MAGL₁ and MAGL₂, and the drain-side assist gate lines DAGL₁ and DAGL₂ are respectively connected to the corresponding source-side assist gate electrode SAG, the memory-side assist gate electrode MAG, or the drain-side assist gate electrode DAG via contacts (not illustrated). In this manner, the memory array CAd according to the third embodiment can be manufactured.

The memory array in which the memory cells Cd according to the second embodiment illustrated in FIG. 28 are hierarchically arranged in a matrix can be similarly manufactured according to the method of manufacturing the memory array CAd according to the third embodiment described above.

That is, in the method of manufacturing the memory array according to the second embodiment described above, the “step of dividing the assist gate electrode 58 into three” described with reference to FIGS. 42A, 42B, and 42C is omitted from the steps described with reference to FIGS. 37 to 47, so that the assist gate electrode 58 can be formed as the assist gate electrode AG in the second embodiment as it is. Other components of the memory array according to the second embodiment can be similarly manufactured according to the manufacturing step of the third embodiment.

### (3-8) Operations and Advantageous Effects

With the above-described configuration, also in the third embodiment, the memory cells Ce are three-dimensionally structured such that the memory transistor MT, the drain-side select transistor DT, and the source-side select transistor ST are connected in series. Since the memory cells Ce are three-dimensionally structured, the memory cells Ce can be integrated and downsized without being restricted by two-dimensional scaling.

In addition, since the memory cell Ce according to the third embodiment is provided with the source-side assist gate electrode SAG, the memory-side assist gate electrode MAG, and the drain-side assist gate electrode DAG, the potential of the semiconductor layer 17 can be determined by individually adjusting not only the potentials of the source diffusion layer 6, drain diffusion layer 7, source-side select gate electrode SG, memory gate electrode MG, and drain-side select gate electrode DG but also the potentials of the source-side assist gate electrode SAG, memory-side assist gate electrode MAG, and drain-side assist gate electrode DAG.

That is, in the third embodiment, the potential of the semiconductor layer 17 around the source-side select gate structure 12 can be controlled by the source-side assist gate electrode SAG, the potential of the semiconductor layer 17 around the memory gate structure 10 can be controlled by the memory-side assist gate electrode MAG, and the potential of the semiconductor layer 17 around the drain-side select gate structure 11 can be controlled by the drain-side assist gate electrode DAG.

During the data program operation, increasing the potential of the semiconductor layer 17 by the source-side assist gate electrode SAG makes it possible to reduce the potential difference between the source-side gate voltage V_{SGS1} and the semiconductor layer 17 in the program selected page, reliably turn off the source-side select transistors ST1 and ST3, and suppress the leakage current. In addition, even in the program unselected page, it is possible to adjust the potential of the semiconductor layer 17 by the source-side assist gate electrode SAG and the drain-side assist gate electrode DAG, reliably turn off the drain-side select transistors DT2 and DT4 and the source-side select transistors ST2 and ST4, and suppress the leakage current.

During the data erase operation, adjusting the voltages of the drain-side assist gate electrode DAG, memory-side assist gate electrode MAG, and source-side assist gate electrode SAG makes it possible to increase the difference between the memory gate voltage V_{CG1} and the potential of the semiconductor layer 17 in the erase selected page, and execute the data erasure more effectively, reduce the potential difference from the memory gate voltage V_{CG2} in the erasure unselected page, and suppress the data erasure more effectively.

During the data read operation, adjusting the voltages of the drain-side assist gate electrode DAG, memory-side assist gate electrode MAG, and source-side assist gate electrode SAG makes it possible to adjust the potential difference between the potential of the semiconductor layer 17 and the read selection drain-side gate voltage V_{SGD1} and the potential difference between the potential of the semiconductor layer 17 and the read selection source-side gate voltage V_{SGS1}, and suppress the leakage current from the source line SL₁ to the bit line BL₁ in the vicinity of the drain-side assist gate electrode DAG, the memory-side assist gate electrode MAG, and the source-side assist gate electrode SAG.

### (4) Fourth Embodiment

### (4-1) Configuration of Memory Cell According to Fourth Embodiment

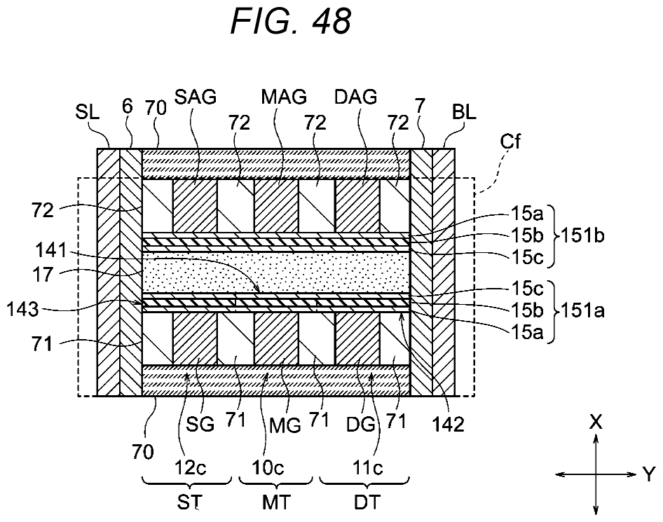

FIG. 48 is a schematic diagram illustrating a configuration of a memory cell Cf according to a fourth embodiment in plan view. In the memory cell Cf, similarly to the third embodiment, a drain-side assist gate electrode DAG is provided in a drain-side select transistor DT, a memory-side assist gate electrode MAG is provided in a memory transistor MT, and a source-side assist gate electrode SAG is provided in a source-side select transistor ST.

The memory cell Cf is different from the third embodiment described above in the configurations of a memory gate structure 10c, drain-side select gate structure 11c, and source-side select gate structure 12c. Specifically, unlike the third embodiment, the memory gate structure 10c has a configuration in which no multilayer insulating layer is provided on the side surface of the memory gate electrode MG over the entire circumference along the circumferential direction, and a memory-side multilayer insulating layer 141 is provided so as to be in contact with only one side of the side surface of the pillar-shaped memory gate electrode MG having a quadrangular cross section. The drain-side select gate structure 11c has a configuration in which a drain-side select gate multilayer insulating layer 142 is provided as a drain-side select gate insulating layer such that the drain-side select gate multilayer insulating layer 142 is in contact with only one side of the side surface of the drain-side select gate electrode DG having a pillar shape with a quadrangular cross section. The source-side select gate structure 12c has a configuration in which a source-side select gate multilayer i insulating layer 143 is provided as the source-side select gate insulating layer such that the source-side select gate multilayer insulating layer 143 is in contact with only one side of the side surface of the pillar-shaped source-side select gate electrode SG having a quadrangular cross section. In the fourth embodiment, the drain-side select gate multilayer insulating layer 142, the memory-side multilayer insulating layer 141, and the source-side select gate multilayer insulating layer 143 are linearly connected together to form a multilayer insulating layer 151a extending in the row direction Y.

In the memory cell Cf, the memory gate structure 10c, the drain-side select gate structure 11c, and the source-side select gate structure 12c are provided in a region between the source diffusion layer 6 and the drain diffusion layer 7 that run in parallel along the column direction X in a plane direction of the surface of a substrate (not illustrated). In FIG. 48, one direction indicates the column direction X in plan view, and the other direction orthogonal to the one direction indicates the row direction Y. For example, a semiconductor layer 17 extending in the row direction Y is provided in a region between a source diffusion layer 6 and a drain diffusion layer 7 that run in parallel along the column direction X so as to be in contact with the side surfaces of the source diffusion layer 6 and drain diffusion layer 7. The multilayer insulating layer 151a in which the drain-side select gate multilayer insulating layer 142, the memory-side multilayer insulating layer 141, and the source-side select gate multilayer insulating layer 143 are linearly connected is provided on one side surface of the semiconductor layer 17 extending in the row direction Y between the source diffusion layer 6 and the drain diffusion layer 7.

The multilayer insulating layer 151a includes a linear first memory gate insulating layer 15a provided so as to be in contact with the side surfaces of one side of the drain-side select gate electrode DG, the memory gate electrode MG, and the source-side select gate electrode SG in plan view, a linear charge storage layer 15b provided along the side surface of the first memory gate insulating layer 15a, and a linear second memory gate insulating layer 15c provided along the side surface of the charge storage layer 15b. Similarly to the above-described embodiments, the first memory gate insulating layer 15a and the second memory gate insulating layer 15c are formed of silicon oxide (SiO₂) or the like, and the charge storage layer 15b is formed of silicon nitride (Si₃N₄), silicon oxynitride (SiON), alumina (Al₂O₃), hafnium oxide (HfO₂), or the like.

The other linear multilayer insulating layer 151b is formed along the other side surface of the semiconductor layer 17 extending in the row direction Y between the source diffusion layer 6 and the drain diffusion layer 7, and the drain-side assist gate electrode DAG, the memory-side assist gate electrode MAG, and the source-side assist gate electrode SAG are arranged with the multilayer insulating layer 151b interposed therebetween. The multilayer insulating layer 151b is formed between the source diffusion layer 6 and the drain diffusion layer 7 so as to run in parallel with the one multilayer insulating layer 151a, and is provided with the side surface extending in the row direction Y in contact with the side surfaces of one side of the drain-side assist gate electrode DAG, the memory-side assist gate electrode MAG, and the source-side assist gate electrode SAG.

The other multilayer insulating layer 151b includes a linear first memory gate insulating layer 15a provided so as to be in contact with the side surfaces of one side of the drain-side assist gate electrode DAG, the memory-side assist gate electrode MAG, and the source-side assist gate electrode SAG having a quadrangular cross section in plan view, a linear charge storage layer 15b provided along the side surface of the first memory gate insulating layer 15a, and a linear second memory gate insulating layer 15c provided along the side surface of the charge storage layer 15b. Similarly to the above-described embodiments, the first memory gate insulating layer 15a and the second memory gate insulating layer 15c are formed of silicon oxide (SiO₂) or the like, and the charge storage layer 15b is formed of silicon nitride (Si₃N₄), silicon oxynitride (SiON), alumina (Al₂O₃), hafnium oxide (HfO₂), or the like.

The other multilayer insulating layer 151b insulates the semiconductor layer 17 and the drain-side assist gate electrode DAG, the semiconductor layer 17 and the memory-side assist gate electrode MAG, and the semiconductor layer 17 and the source-side assist gate electrode SAG. In the present embodiment, the multilayer insulating layer 151b having the same three-layer structure as the multilayer insulating layer 151a for programming data is applied in order to simplify the manufacturing step by manufacturing the multilayer insulating layer 151b at the same time with the one multilayer insulating layer 151a. However, the present invention is not limited thereto. Alternatively, a linear insulating layer having a one-layer structure may be formed at a manufacturing step different from the multilayer insulating layer 151a, and the simple insulating layer may be provided instead of the multilayer insulating layer 151b.

An insulating layer 71 is formed each between the source diffusion layer 6 and the source-side select gate electrode SG, between the source-side select gate electrode SG and the memory gate electrode MG, between the memory gate electrode MG and the drain-side select gate electrode DG, and between the drain-side select gate electrode DG and the drain diffusion layer 7. These layers and electrodes are insulated from each other by the insulating layers 71.

In addition, an insulating layer 72 is formed each between the source diffusion layer 6 and the source-side assist gate electrode SAG, between the source-side assist gate electrode SAG and the memory-side assist gate electrode MAG, between the memory-side assist gate electrode MAG and the drain-side assist gate electrode DAG, and between the drain-side assist gate electrode DAG and the drain diffusion layer 7. These layers and electrodes are insulated from each other by the insulating layers 72.

In the semiconductor layer 17 according to the present embodiment, a region facing the memory-side multilayer insulating layer 141 on the multilayer insulating layer 151a in contact with the memory gate electrode MG constitutes a memory peripheral region, a region facing the drain-side select gate multilayer insulating layer 142 on the multilayer insulating layer 151a in contact with the drain-side select gate electrode DG constitutes a drain-side peripheral region, and a region facing the source-side select gate multilayer insulating layer 143 on the multilayer insulating layer 151a in contact with the source-side select gate electrode SG constitutes a source-side peripheral region.

The memory cell Cf is insulated from other memory cells (not illustrated) adjacent in the column direction X by a pair of insulating layers 70 provided between the source diffusion layer 6 and the drain diffusion layer 7 and running in parallel along the row direction Y. In this case, one insulating layer 70 on the lower side in FIG. 48 is provided such that a linear side surface extending in the row direction Y is in contact with the side surfaces of one side of the drain-side select gate electrode DG, the memory gate electrode MG, the source-side select gate electrode SG, and the insulating layer 71 is in contact with each other. The other insulating layer 70 on the upper side in FIG. 48 is provided such that a linear side surface extending in the row direction Y is in contact with the side surfaces of one side of the drain-side assist gate electrode DAG, the memory-side assist gate electrode MAG, the source-side assist gate electrode SAG, and the insulating layer 72.

In the fourth embodiment described above, similarly to the third embodiment described above, the drain-side assist gate electrode DAG, the memory-side assist gate electrode MAG, and the source-side assist gate electrode SAG are provided separately. However, the present invention is not limited to this. For example, similarly to the second embodiment described above, the drain-side assist gate electrode DAG, the memory-side assist gate electrode MAG, and the source-side assist gate electrode SAG may be linearly connected together to form one assist gate electrode.

### (4-2) Configuration of Memory Array According to Fourth Embodiment

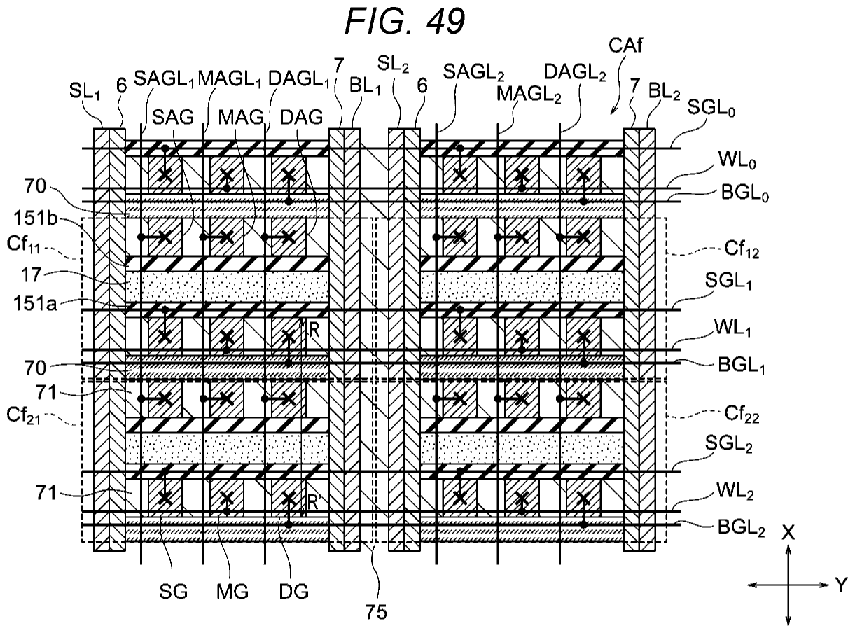

Next, a cross-sectional configuration of a memory array in plan view in which the above-described memory cells Cf are arranged in a matrix will be described. FIG. 49 is a cross-sectional view of a cross-sectional configuration of a memory array CAf according to the fourth embodiment in plan view. In FIG. 49, one direction indicates the column direction X in plan view, and the other direction orthogonal to the one direction indicates the row direction Y. For example, FIG. 49 illustrates a configuration in which the memory cells Cf are arranged in two rows and two columns at the first level. In FIG. 49, the memory cells Cf in the first row and first column and in the second row and first column on the left side of the drawing will be referred to as memory cells Cf₁₁ and Cf₂₁, respectively, and the memory cells Cf in the first row and second column and in the second row and second column on the right side of the drawing will be referred to as memory cells Cf₁₂ and Cf₂₂, respectively. These memory cells Cf₁₁, Cf₂₁, Cf₁₂, and Cf₂₂ will be simply referred to as memory cells Cf in a case where it is not particularly necessary to distinguish them.

The configuration in which the memory cells Cf₁₁ and Cf₂₁ in the first column are arranged and the configuration in which the memory cells Cf₁₂ and Cf₂₂ in the second column are arranged are the same except that they are formed symmetrically. The memory cells Cf₁₁ and Cf₂₁ are arranged along the column direction X in a region between the source diffusion layer 6 and the drain diffusion layer 7 running in parallel along the column direction X, and the side surfaces of the semiconductor layer 17 of the memory cells Cf₁₁ and Cf₂₁ are in contact with the side surfaces of the source diffusion layer 6 and the drain diffusion layer 7. Accordingly, the memory cells Cf₁₁ and Cf₂₁ in the same column share the source line SL₁, the bit line BL₁, the source diffusion layer 6, and the drain diffusion layer 7. An insulating layer 70 is provided between the memory cells Cf₁₁ and Cf₂₁, and the memory cells Cf₁₁ and Cf₂₁ are insulated by the insulating layer 70.

A drain-side select gate line BGL₁ extending in the row direction Y is connected to the drain-side select gate electrodes DG of the memory cells Cf₁₁ and Cf₁₂ of the first column and the second column arranged in the same row. A source-side select gate line SGL₁ extending in the row direction Y is connected to the source-side select gate electrodes SG of the memory cells Cf₁₁ and Cf₁₂ of the first column and the second column arranged in the same row. A word line WL₁ extending in the row direction Y is connected to the memory gate electrodes MG of the memory cells Cf₁₁ and Cf₁₂ of the first column and the second column arranged in the same row. The drain-side select gate lines BGL₀ and BGL₂, the source-side select gate lines SGL₀ and SGL₂, and the word lines WL₀ and WL₂ also have the same configurations as the drain-side select gate line BGL₁, the source-side select gate line SGL₁, and the word line WL₁.

A drain-side assist gate line DAGL₁ extending in the column direction X is connected to the drain-side assist gate electrodes DAG of the memory cells Cf₁₁ and Cf₂₁ in the first row and the second row arranged in the same column, a source-side assist gate line SAGL₁ extending in the column direction X is connected to the source-side assist gate electrodes SAG of the memory cells Cf₁₁ and Cf₂₁ in the first row and the second row arranged in the same column, and a memory-side assist gate line MAGL₁ extending in the column direction X is connected to the memory-side assist gate electrodes MAG of memory cells Cf₁₁ and Cf₂₁ in the first row and the second row arranged in the same column. The drain-side assist gate line DAGL₂, the source-side assist gate line SAGL₂, and the memory-side assist gate line MAGL₂ also have the same configurations as those of the drain-side assist gate line DAGL₁, the source-side assist gate line SAGL₁, and the memory-side assist gate line MAGL₁ described above.

The bit line BL₁ connected to the memory cells Cf₁₁ and Cf₂₁ in the first column and the source line SL₂ connected to the memory cells Cf₁₂ and Cf₂₂ in the second column run in parallel so as to be adjacent to each other with an insulating layer 75 interposed therebetween, and are insulated by the insulating layer 75.

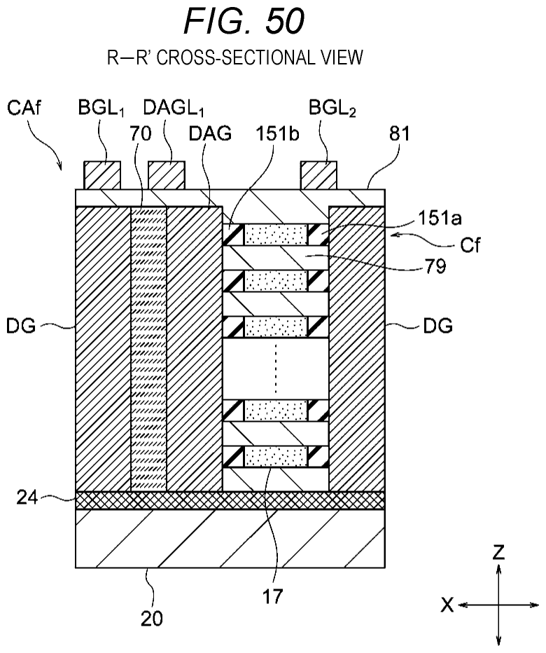

FIG. 50 is a cross-sectional view of a cross-sectional configuration of a portion R-R′ in FIG. 49. FIG. 50 also illustrates an arrangement configuration of an insulating layer 81 provided at the top of the cross-sectional configuration of the memory array CAf illustrated in FIG. 49 in plan view, and illustrates the drain-side select gate lines BGL₁ and BGL₂ and the drain-side assist gate line DAGL₁ arranged on the insulating layer 81. In the memory array CAf, as illustrated in FIG. 50, the pillar-shaped drain-side select gate electrode DG and the pillar-shaped drain-side assist gate electrode DAG are disposed on a substrate 20 with an insulating layer 24 interposed therebetween. Similarly, the memory gate electrode MG, the source-side select gate electrode SG, the memory-side assist gate electrode MAG, and the source-side assist gate electrode SAG are disposed on the substrate 20 with the insulating layer 24 interposed therebetween.

Between the drain-side select gate electrode DG and the drain-side assist gate electrode DAG, a layer with the semiconductor layer 17 and the multilayer insulating layers 151a and 151b and an interlayer insulating layer 79 are alternately arranged along the vertical direction Z. As a result, the interlayer insulating layer 79 insulates the semiconductor layer 17 and the layer with the multilayer insulating layers 151a and 151b at the upper level from the semiconductor layer 17 and the layer with the multilayer insulating layers 151a and 151b at the lower level.

In the memory array CAf, the memory cells Cf are formed at corresponding positions (levels) of the semiconductor layers 17 formed along the vertical direction Z. The plurality of memory cells Cf arranged along the vertical direction Z share the drain-side select gate electrode DG, the memory gate electrode MG, the source-side select gate electrode SG, the drain-side assist gate electrode DAG, the memory-side assist gate electrode MAG, and the source-side assist gate electrode SAG.

Data program operation, data erase operation, and data read operation in the memory cell Cf according to the fourth embodiment are similar to those in the third embodiment described above, and thus the description thereof will be omitted here.

### (4-3) Method of Manufacturing Memory Array According to Fourth Embodiment

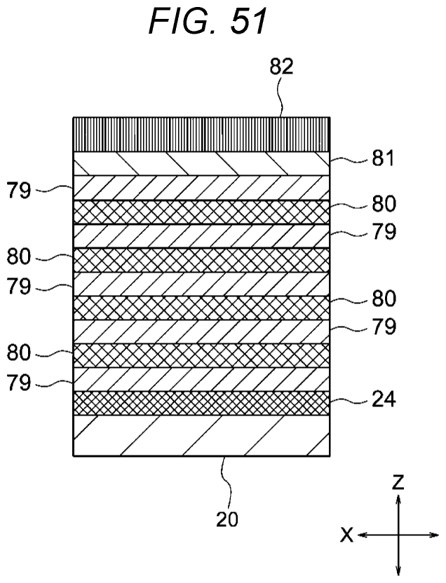

Next, a method of manufacturing the memory array CAf will be described with reference to FIGS. 51 to 57B. In this case, as illustrated in FIG. 51, the insulating layer 24 is stacked on the substrate 20 made of silicon, for example, and the interlayer insulating layer 79 different in type from the insulating layer 24 and a silicon layer 80 made of polycrystalline silicon, for example, are alternately stacked on the insulating layer 24. Furthermore, the other insulating layer 81 different in type from the insulating layer 24 and the interlayer insulating layer 79 is stacked on the uppermost interlayer insulating layer 79 among the interlayer insulating layers 79, and a mask layer 82 for a mask made of Al₂O₃, carbon, SiC or the like, for example, is further formed thereon. Here, the insulating layer 24 and the insulating layer 81 are made of materials different from that of the silicon layer 80, and are layers that are unlikely to be etched when etching the interlayer insulating layer 79 and the silicon layer 80.

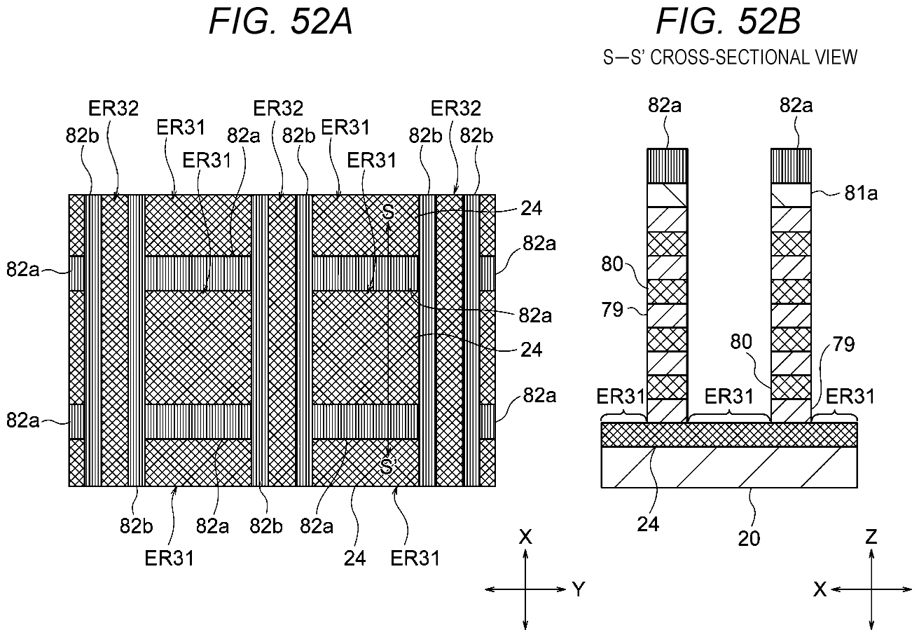

Subsequently, as in FIG. 52A and FIG. 52B illustrating a cross-sectional configuration of an S-S′ portion of FIG. 52A, the mask layer 82 is selectively etched by a dry etching method, for example, using a predetermined mask layer (not illustrated) to form mask layers 82a and 82b in a predetermined pattern, and the lower interlayer insulating layers 79 and silicon layers 80 are etched using the mask layers 82a and 82b as masks.

Here, FIG. 52A is a schematic diagram illustrating a configuration in plan view after etching the lower interlayer insulating layers 79 and silicon layers 80 using the mask layers 82a and 82b in a predetermined pattern. The formation positions of the mask layers 82a are located in intended formation regions of the multilayer insulating layers 151a and 151b and the semiconductor layer 17. The formation positions of the mask layers 82b are intended formation positions of the source line SL and the source diffusion layer 6 and intended formation positions of the bit line BL and the drain diffusion layer 7.

As a result, between the mask layers 82b adjacent in the row direction Y, the interlayer insulating layers 79 and the silicon layers 80 are etched until the surface of the insulating layer 24 is exposed to form a hole ER32. In addition, between the mask layers 82a adjacent in the column direction X, the interlayer insulating layers 79 and the silicon layers 80 are etched until the surface of the insulating layer 24 is exposed to form a hole ER31.

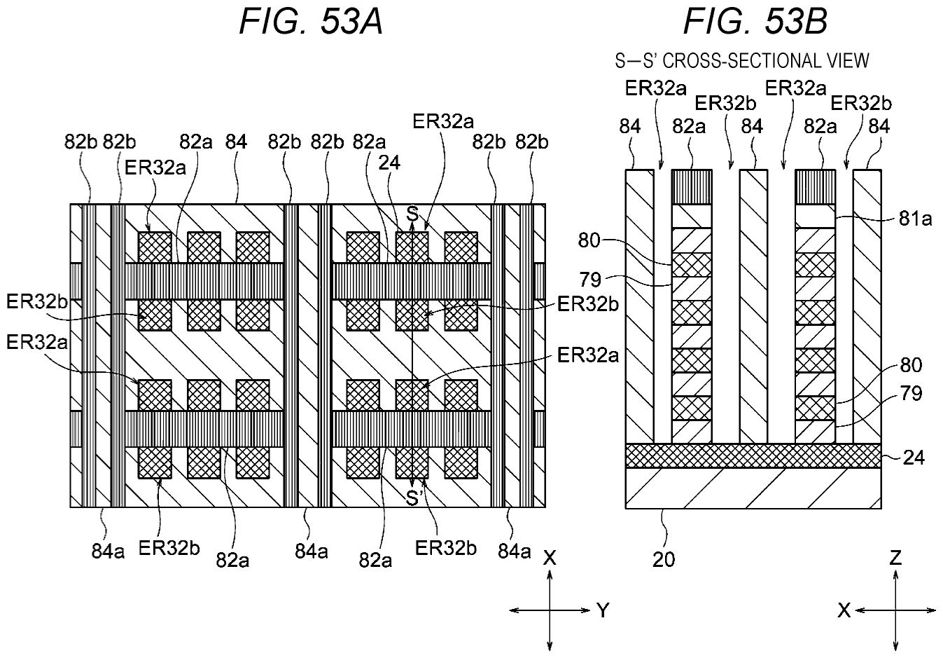

Next, an insulating material is deposited in the spaces of the holes ER31 and ER32 where the insulating layer 24 is exposed to form an insulating layer, and then the surface of the insulating layer is polished to form a mask layer (not illustrated) in a predetermined pattern on the mask layers 82a and 82b and the like on the surface. Then, as illustrated in FIGS. 53A and 53B, the insulating layers 84 at the intended formation positions of the drain-side select gate electrode DG, the memory gate electrode MG, the source-side select gate electrode SG, the drain-side assist gate electrode DAG, the memory-side assist gate electrode MAG, and the source-side assist gate electrode SAG are etched until the surface of the lower insulating layer 24 is exposed to form holes ER32a and ER32b.

Here, FIG. 53A is a schematic diagram illustrating a configuration in plan view after the holes ER32a and ER32b are formed at the intended formation positions of the drain-side select gate electrode DG, the memory gate electrode MG, the source-side select gate electrode SG, the drain-side assist gate electrode DAG, the memory-side assist gate electrode MAG, and the source-side assist gate electrode SAG, and FIG. 53B illustrates a cross-sectional configuration of an S-S′ portion in FIG. 53A. In FIG. 53A, the insulating layer in the region where the holes ER32a and ER32b are formed is referred to as the insulating layer 84, and the insulating layer extending in the column direction X and formed between the mask layers 82b running in parallel along the column direction X is referred to as the insulating layer 84a.

The hole ER32a is formed at intended formation positions of the drain-side assist gate electrode DAG, the memory-side assist gate electrode MAG, and the source-side assist gate electrode SAG. The hole ER32b arranged symmetrically with the mask layer 82a interposed therebetween with respect to the hole ER32a in plan view is formed at intended formation positions of the drain-side select gate electrode DG, the memory gate electrode MG, and the source-side select gate electrode SG.

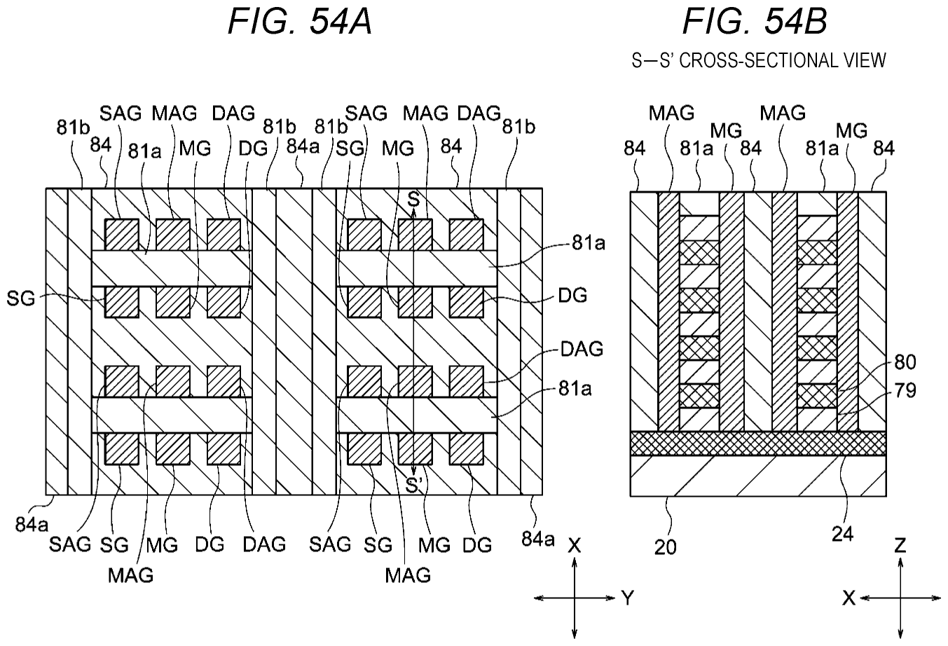

Next, after a gate material of low-resistance polycrystalline silicon or metal such as tungsten is deposited in the holes ER32a and 32b, the excess gate material deposited on the surface and the mask layers 82a and 82b are removed by surface polishing. As a result, as illustrated in FIGS. 54A and 54B, the drain-side assist gate electrode DAG, the memory-side assist gate electrode MAG, and the source-side assist gate electrode SAG are formed in the hole ER32a, and the drain-side select gate electrode DG, the memory gate electrode MG, and the source-side select gate electrode SG are formed in the hole ER32b.

FIG. 54A is a schematic diagram illustrating a configuration in plan view after the drain-side assist gate electrode DAG, the memory-side assist gate electrode MAG, the source-side assist gate electrode SAG, the drain-side select gate electrode DG, the memory gate electrode MG, and the source-side select gate electrode SG are formed in the holes ER32a and 32b, and FIG. 54B illustrates a cross-sectional configuration of the S-S′ portion in FIG. 54 A.

Next, a new patterned mask layer is formed on the surface, and using the mask layer, the insulating layer 84a extending in the column direction X is removed until the surface of the insulating layer 24 is exposed, thereby forming a hole (not illustrated) in the formation region of the insulating layer 84a. Accordingly, in the hole formed at the formation position of the insulating layer 84a, the ends of the interlayer insulating layers 79 and the silicon layers 80 alternately stacked under the insulating layer 81b are exposed.

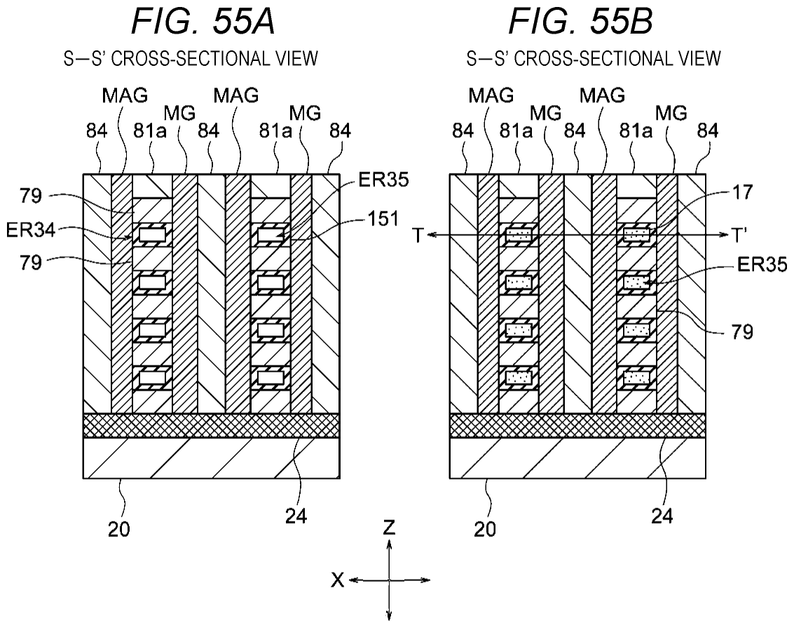

Next, only the silicon layer 80 between the interlayer insulating layers 79 is selectively removed by side etching from the hole under the insulating layers 81a and 81b, and a hollow portion ER34 is formed in the interlayer insulating layers 79 in which the silicon layer 80 was present. Next, as illustrated in FIG. 55A, a layered multilayer insulating layer 151 is formed in the hole along the inner surface of a hollow portion ER34 formed by side etching between the interlayer insulating layers 79. The multilayer insulating layer 151 is formed by sequentially stacking the layered first memory gate insulating layer 15a, the charge storage layer 15b, and the second memory gate insulating layer 15c along the inner surface of the hollow portion ER34.

The multilayer insulating layers 151a and 151b illustrated in FIG. 48 constitute a part of the multilayer insulating layer 151 illustrated in FIG. 55A, and the multilayer insulating layers 151a and 151b are continuously provided in the longitudinal cross-sectional configuration. In the hollow portion ER34 in which the multilayer insulating layer 151 is formed, a hollow portion ER35 surrounded by the multilayer insulating layer 151 is formed.

Next, as illustrated in FIG. 55B, for example, a semiconductor material such as polycrystalline silicon is deposited from the hole (hole formed at the formation position of the insulating layer 84a) into the hollow portion ER35, and the inside of the hollow portion ER35 surrounded by the multilayer insulating layer 151 is filled with the semiconductor material, thereby forming the semiconductor layer 17 in the hollow portion ER35 at each level.

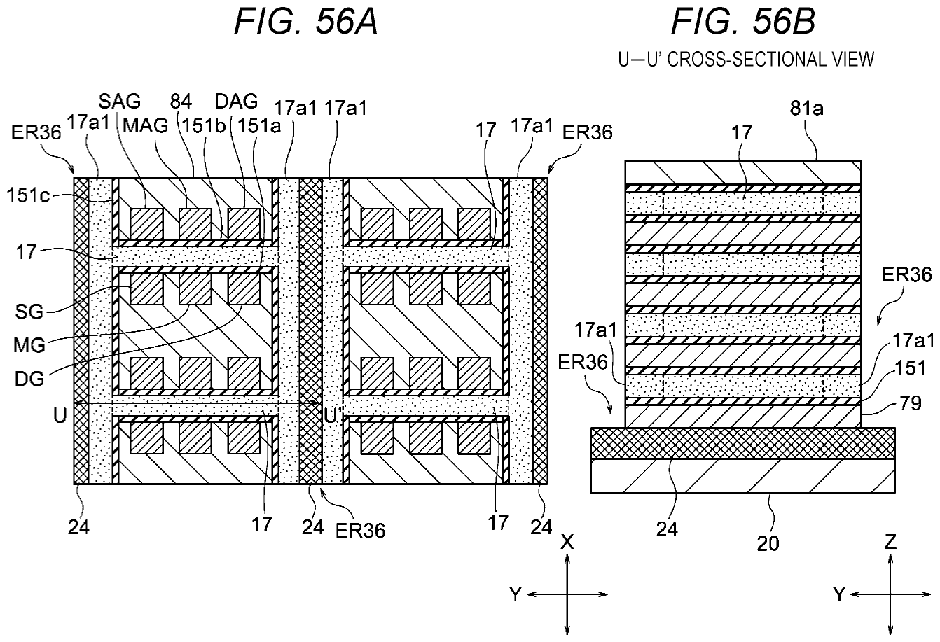

Next, the region of the semiconductor layer 17 between the intended formation position of the source diffusion layer 6 and the source line SL and the intended formation position of the drain diffusion layer 7 and the bit line BL is removed in the vertical direction Z using the patterned mask layer, thereby forming a hole ER36 extending in the column direction X where the surface of the insulating layer 24 is exposed, as illustrated in FIGS. 56A and 56B. FIG. 56A is a cross-sectional diagram illustrating a configuration in plan view at a height position of a T-T′ portion illustrated in FIG. 55B after the formation of the hole ER36, and FIG. 56B is a cross-sectional view of a cross-sectional configuration seen from a U-U′ portion in FIG. 56A. Thereafter, the uppermost mask layer used for forming the hole ER36 is removed. FIGS. 48 and 49 do not illustrate multilayer insulating layers 151c formed along the side surfaces extending in the column direction X of a semiconductor layer 17a1 illustrated in FIGS. 56A and 56B.

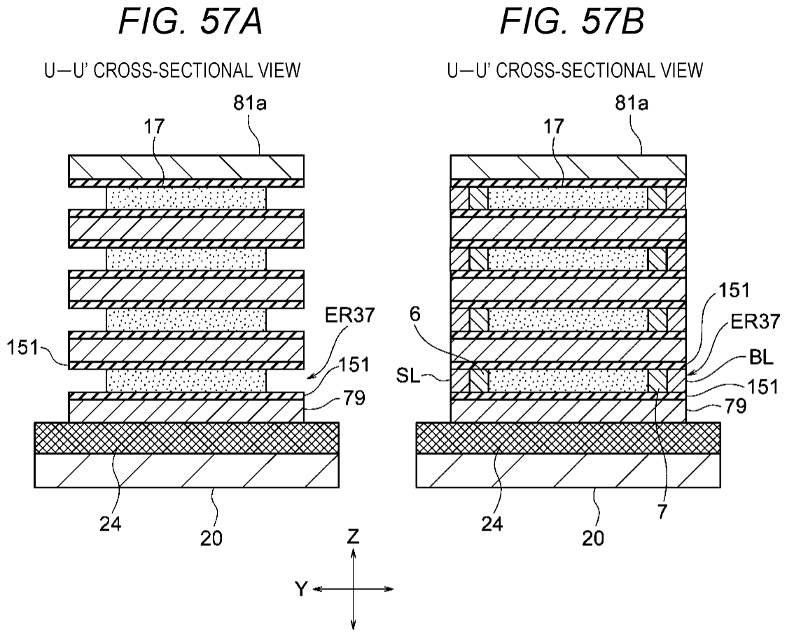

Next, as illustrated in FIG. 57A, out of the semiconductor layers 17 and 17al between the interlayer insulating layers 79, the semiconductor layer 17al is removed from the hole ER36 by side etching, thereby forming a hollow hole ER37 in the region where the semiconductor layer 17al was present while the semiconductor layer 17 is left between the interlayer insulating layers 79. Then, as illustrated in FIG. 57B, the source diffusion layer 6 or the drain diffusion layer 7 and the source line SL or the bit line BL are sequentially formed in the holes ER37 between the interlayer insulating layers 79 by a general semiconductor manufacturing process using a photolithography technique, a film forming technique such as CVD, an etching technique, an ion implantation method, and the like.

The source diffusion layer 6 and the drain diffusion layer 7 are electrically separated between levels by the interlayer insulating layers 79, and the source line SL and the bit line BL are also electrically separated between levels by the interlayer insulating layers 79.

Thereafter, contacts (not illustrated) electrically connected to the source-side select gate electrode SG, the memory gate electrode MG, the drain-side select gate electrode DG, the source-side assist gate electrode SAG, the memory-side assist gate electrode MAG, or the drain-side assist gate electrode DAG, and the source-side select gate line SGL, the word line WL, the drain-side select gate line BGL, the source-side assist gate line SAGL, the memory-side assist gate line MAGL, and the drain-side assist gate line DAGL are formed by a general semiconductor manufacturing process using a photolithography technique, a film forming technique such as CVD, an etching technique, an ion implantation method, and the like. In this manner, the memory array CAf according to the fourth embodiment can be manufactured.

### (4-4) Operations and Advantageous Effects

With the above-described configuration, also in the fourth embodiment, the memory cells Cf are three-dimensionally structured such that the memory transistor MT, the drain-side select transistor DT, and the source-side select transistor ST are connected in series. Since the memory cells Cf are three-dimensionally structured, the memory cells Cf can be integrated and downsized without being restricted by two-dimensional scaling.

In addition, since the memory cell Cf according to the fourth embodiment is provided with the source-side assist gate electrode SAG, the memory-side assist gate electrode MAG, and the drain-side assist gate electrode DAG, the potential of the semiconductor layer 17 can be determined by individually adjusting not only the potentials of the source diffusion layer 6, drain diffusion layer 7, source-side select gate electrode SG, memory gate electrode MG, and drain-side select gate electrode DG but also the potentials of the source-side assist gate electrode SAG, memory-side assist gate electrode MAG, and drain-side assist gate electrode DAG.

That is, in the fourth embodiment, similarly to the third embodiment, the potential of the semiconductor layer 17 around the source-side select gate structure 12c can be controlled by the source-side assist gate electrode SAG, the potential of the semiconductor layer 17 around the memory gate structure 10c can be controlled by the memory-side assist gate electrode MAG, and the potential of the semiconductor layer 17 around the drain-side select gate structure 11c can be controlled by the drain-side assist gate electrode DAG.

In the above-described embodiment, for simplification of the manufacturing step, the drain-side select gate multilayer insulating layer 142 having the same three-layer structure as the memory-side multilayer insulating layer 141 is provided as the drain-side select gate insulating layer, and the source-side select gate multilayer insulating layer 143 having the same three-layer structure as the memory-side multilayer insulating layer 141 is provided as the source-side select gate insulating layer. However, the present invention is not limited thereto. For example, while the memory-side multilayer insulating layer 141 is provided as a multilayer insulating layer by a general semiconductor manufacturing process using a photolithography technique, a film forming technique such as CVD, an etching technique, an ion implantation method, and the like, the drain-side select gate multilayer insulating layer 142 and the source-side select gate multilayer insulating layer 143 may be set as single drain-side select gate insulating layer and source-side select gate insulating layer.

In addition, the memory cell according to the present invention is not limited to the configuration described in each of the above embodiments, and may be a memory cell configured by appropriately combining the configurations of the respective memory cells C, Cb, Ch, Cc, Cd, Ce, and Cf of the above embodiments. For example, as another embodiment of the memory cells Cc and Cd according to the second embodiment, a plurality of memory transistors may be provided in series as in the memory cell Ch in the first embodiment described above, while assist gate electrodes AG and AGa are provided. In this case, in the memory cells Cc and Cd according to the other embodiments, a plurality of pillar-shaped memory gate electrodes MG is arranged in series between pillar-shaped drain-side select gate electrode DG and source-side select gate electrode SG, and pillar-shaped assist gate electrodes AG and AGa are provided so as to face the drain-side select gate electrode DG, the source-side select gate electrode SG, and the plurality of memory gate electrodes MG.

In addition, as another embodiment of the memory cells Ce and Cf according to the third and fourth embodiments, a plurality of memory transistors may be provided in series as in the memory cell Ch in the first embodiment described above while a drain-side assist gate electrode DAG, a memory-side assist gate electrode MAG, and a source-side assist gate electrode SAG are provided. In this case, a plurality of pillar-shaped memory gate electrodes MG may be arranged in series between a pillar-shaped drain-side select gate electrode DG and a source-side select gate electrode SG, and the pillar-shaped memory-side assist gate electrodes MAG may be individually provided corresponding to the memory gate electrodes MG of the memory transistors MT.

### REFERENCE SIGNS LIST

1, 1c: Non-volatile semiconductor memory device
6: Source diffusion layer
7: Drain diffusion layer
14a: Drain-side select gate insulating layer
14b: Source-side select gate insulating layer
15: Multilayer insulating layer
15a: First memory gate insulating layer
15b: Charge storage layer
15c: Second memory gate insulating layer
19: Insulating layer
20: Substrate
45, 45a, 46: Assist gate insulating layer
141: Memory-side multilayer insulating layer (multilayer insulating layer)
142: Drain-side select gate multilayer insulating layer (drain-side select gate insulating layer)
143: Source-side select gate multilayer insulating layer (source-side select gate insulating layer)
AGL: Assist gate line
AG: Assist gate electrode
BL: Bit line
CA, CAb, CAh, CAc, CAd, CAe, CAf: Memory array
C, Cb, Ch, Cc, Cd, Ce, Cf: Memory cell (non-volatile memory cell)
DAG: Drain-side assist gate electrode
DAGL: Drain-side assist gate line
DG: Drain-side select gate electrode
MAG: Memory-side assist gate electrode
MAGL: Memory-side assist gate line
MG: Memory gate electrode
SAG: Source-side assist gate electrode
SAGL: Source-side assist gate line
SL: Source line
SG: Source-side select gate electrode

What is claimed is:

1. A non-volatile memory cell comprising:
a drain diffusion layer that extends in a plane direction of a surface of a substrate and to which a bit line is electrically connected;
a source diffusion layer that extends in the plane direction in parallel with the drain diffusion layer and to which a source line is electrically connected;
one or a plurality of memory gate electrodes each having a pillar shape that is disposed on the substrate with an insulating layer interposed therebetween and is provided in a region between the drain diffusion layer and the source diffusion layer running in parallel;
a drain-side select gate electrode having a pillar shape, the drain-side select gate electrode being disposed on the substrate with an insulating layer interposed therebetween and provided in a region between the drain diffusion layer and the memory gate electrode;
a source-side select gate electrode having a pillar shape, the source-side select gate electrode being disposed on the substrate with an insulating layer interposed therebetween and provided in a region between the source diffusion layer and the memory gate electrode;
a multilayer insulating layer provided in contact with the memory gate electrode;
a drain-side select gate insulating layer provided in contact with the drain-side select gate electrode;
a source-side select gate insulating layer provided in contact with the source-side select gate electrode; and
a semiconductor layer that is provided in a region between the drain diffusion layer and the source diffusion layer running in parallel, and is in contact with each of the drain-side select gate insulating layer, the source-side select gate insulating layer, the multilayer insulating layer, the drain diffusion layer, and the source diffusion layer, wherein
the multilayer insulating layer includes:
a first memory gate insulating layer in contact with the memory gate electrode, a charge storage layer in contact with the first memory gate insulating layer, and a second memory gate insulating layer in contact with the charge storage layer and the semiconductor layer.

2. The non-volatile memory cell according to claim 1, wherein
the multilayer insulating layer is provided on a side surface of the memory gate electrode,
the drain-side select gate insulating layer is provided on a side surface of the drain-side select gate electrode, and
the source-side select gate insulating layer is provided on a side surface of the source-side select gate electrode,
the semiconductor layer is in contact with respective side surfaces of the drain-side select gate insulating layer, the source-side select gate insulating layer, the multilayer insulating layer, the drain diffusion layer, and the source diffusion layer, and
in the multilayer insulating layer, the first memory gate insulating layer is in contact with a side surface of the memory gate electrode, the charge storage layer is in contact with a side surface of the first memory gate insulating layer, and the second memory gate insulating layer is in contact with a side surface of the charge storage layer and a side surface of the semiconductor layer.

3. The non-volatile memory cell according to claim 2, wherein
the drain-side select gate insulating layer is provided on a side surface of the drain-side select gate electrode over an entire circumference along a circumferential direction,
the source-side select gate insulating layer is provided on a side surface of the source-side select gate electrode over an entire circumference along the circumferential direction, and
the multilayer insulating layer is provided on a side surface of the memory gate electrode over an entire circumference along the circumferential direction.

4. The non-volatile memory cell according to claim 3, wherein the semiconductor layer includes a drain-side peripheral region surrounding the side surface of the drain-side select gate insulating layer, a source-side peripheral region surrounding the side surface of the source-side select gate insulating layer, and a memory peripheral region surrounding the side surface of the multilayer insulating layer, wherein the drain-side peripheral region, the source-side peripheral region, and the memory peripheral region are connected together.

5. The non-volatile memory cell according to claim 4, wherein in plan view, a distance from the drain-side select gate insulating layer to an outer surface of the drain-side peripheral region, a distance from the source-side select gate insulating layer to an outer surface of the source-side peripheral region, and a distance from the multilayer insulating layer to an outer surface of the memory peripheral region are each less than 40 nm.

6. The non-volatile memory cell according to claim 5, wherein the semiconductor layer includes:
a memory/drain region connecting portion that connects the memory peripheral region and the drain-side peripheral region adjacent to each other; and
a memory/source region connecting portion that connects the memory peripheral region and the source-side peripheral region adjacent to each other.

7. The non-volatile memory cell according to claim 4, wherein
in the semiconductor layer, in plan view, a distance from the drain-side select gate insulating layer to the multilayer insulating layer adjacent to the drain-side select gate insulating layer is 25 nm or more and 100 nm or less, and
in plan view, a distance from the source-side select gate insulating layer to the multilayer insulating layer adjacent to the source-side select gate insulating layer is 25 nm or more and 100 nm or less.

8. The non-volatile memory cell according to claim 1, wherein
in the drain-side select gate electrode, the source-side select gate electrode, and the memory gate electrode, an enlarged diameter portion and a reduced diameter portion smaller in diameter than the enlarged diameter portion are alternately formed along an axial direction, and
the semiconductor layer is provided on a side surface of the enlarged diameter portion with the drain-side select gate insulating layer, the source-side select gate insulating layer, or the multilayer insulating layer interposed therebetween, and an interlayer insulating layer is provided on a side surface of the reduced diameter portion with the drain-side select gate insulating layer, the source-side select gate insulating layer, or the multilayer insulating layer interposed therebetween.

9. The non-volatile memory cell according to claim 1, wherein
an assist gate electrode having a pillar shape and disposed on the substrate with the insulating layer interposed therebetween; and
an assist gate insulating layer that is provided on a side surface of the assist gate electrode and electrically separates the assist gate electrode from the semiconductor layer, the drain diffusion layer, and the source diffusion layer, wherein
the assist gate electrode is arranged on respective side surfaces of the drain-side select gate electrode, the source-side select gate electrode, and the memory gate electrode with the drain-side select gate insulating layer, the source-side select gate insulating layer or the multilayer insulating layer, the semiconductor layer, and the assist gate insulating layer interposed therebetween.

10. The non-volatile memory cell according to claim 9, wherein
the assist gate electrode includes a drain-side assist gate electrode arranged so as to face the drain-side select gate electrode, a source-side assist gate electrode arranged so as to face the source-side select gate electrode, and a memory-side assist gate electrode arranged so as to face the memory gate electrode, and
the drain-side assist gate electrode, the source-side assist gate electrode, and the memory-side assist gate electrode are formed separately.

11. The non-volatile memory cell according to claim 1, wherein a plurality of pillar memory gate electrodes are provided between the drain-side select gate electrode and the source-side select gate electrode.

12. A non-volatile semiconductor memory device, wherein
a plurality of non-volatile memory cells arranged in a matrix in a plane direction of a surface of a substrate are hierarchically arranged along a vertical direction orthogonal to the plane direction, and
the non-volatile memory cells are the non-volatile memory cells according to claim 1.

13. The non-volatile semiconductor memory device according to claim 12, wherein
a semiconductor layer and an interlayer insulating layer are alternately stacked on the substrate along the vertical direction,
a plurality of holes including a first hole, a second hole, and a third hole are formed to penetrate the stacked semiconductor layer and interlayer insulating layer in the vertical direction,
a drain-side select gate electrode having a pillar shape and disposed on the substrate with an insulating layer interposed therebetween, and a drain-side select gate insulating layer provided on a side surface of the drain-side select gate electrode are provided in the first hole,
a source-side select gate electrode having a pillar shape and disposed on the substrate with an insulating layer interposed therebetween, and a source-side select gate insulating layer provided on a side surface of the source-side select gate electrode are provided in the second hole,
a memory gate electrode having a pillar shape and disposed on the substrate with an insulating layer interposed therebetween, and a multilayer insulating layer provided on a side surface of the memory gate electrode are provided in the third hole, and
the plurality of nonvolatile memory cells arranged at different levels in the vertical direction share the drain-side select gate electrode and the drain-side select gate insulating layer, the source-side select gate electrode and the source-side select gate insulating layer, and the memory gate electrode and the multilayer insulating layer.

14. The non-volatile semiconductor memory device according to claim 12, further comprising:
a plurality of drain-side select gate lines each provided in each row and connected to the drain-side select gate electrodes arranged in the same row including different levels;
a plurality of source-side select gate lines each provided in each row and connected to the source-side select gate electrodes arranged in the same row including different levels; and
a plurality of word lines each provided in each row and connected to the memory gate electrodes arranged in the same row including different levels.

15. The non-volatile semiconductor memory device according to claim 14, wherein
in the nonvolatile memory cells, a plurality of the memory gate electrodes are disposed between a pair of the drain-side select gate electrode and the source-side select gate electrode, and
the word line is provided at each of the memory gate electrodes that are arranged in the same row, the memory gate electrodes being provided in each row of the nonvolatile memory cells.

16. The non-volatile semiconductor memory device according to claim 12, further comprising:
a plurality of drain diffusion layers each extending in the column direction at each level and connected to the semiconductor layers of the nonvolatile memory cells in the same column;
a plurality of source diffusion layers each running in parallel with the drain diffusion layer and extending in the column direction at each level, and connected to the semiconductor layers of the nonvolatile memory cells in the same column; and
a plurality of bit lines each extending in the column direction at each level and connected to the drain diffusion layer in the same column; and
a plurality of source lines each running in parallel with the bit lines and extending in a column direction at each level, and connected to the source diffusion layer in the same column, wherein
a layer in which the semiconductor layer, the drain diffusion layer, the source diffusion layer, the bit line, and the source line are provided, and an interlayer insulating layer are alternately stacked along the vertical direction on the substrate.
